(19) United States
(12) Patent Application Publication
(10) Pub. No.: US 2023/0292507 A1
(43) Pub. Date: Sep. 14, 2023

(54) SEMICONDUCTOR MEMORY DEVICE AND MANUFACTURING METHOD OF SEMICONDUCTOR MEMORY DEVICE

(71) Applicant: SK hynix Inc., Icheon-si Gyeonggi-do (KR)

(72) Inventor: Kang Sik CHOI, Icheon-si Gyeonggi-do (KR)

(73) Assignee: SK hynix Inc., Icheon-si Gyeonggi-do (KR)

(21) Appl. No.: 17/941,274

(22) Filed: Sep. 9, 2022

(30) Foreign Application Priority Data
Mar. 10, 2022 (KR) 10-2022-0030306

(51) Int. Cl. H01L 27/11582; H01L 27/11573

(52) U.S. Cl. CPC H01L 27/11582; H01L 27/11573

(57) ABSTRACT

There are provided a semiconductor memory device and a manufacturing method of a semiconductor memory device. The semiconductor memory device includes a stack structure including a contact region with a stepped structure, a stepped groove having a sidewall formed of the stepped structure of the stack structure, a barrier insulating layer extending along a surface of the stepped structure, a filling insulating layer formed on the barrier insulating layer inside the stepped groove, and a conductive gate contact penetrating the stepped structure of the stack structure while penetrating the filling insulating layer and the barrier insulating layer.

### CROSS-REFERENCE TO RELATED APPLICATION

The present application claims priority under 35 U.S.C. § 119(a) to Korean patent application number 10-2022-0030306 filed on Mar. 10, 2022, in the Korean Intellectual Property Office, the entire disclosure of which is incorporated by reference herein.

### BACKGROUND

### 1. Technical Field

The present disclosure generally relates to a semiconductor memory device and a manufacturing method of a semiconductor memory device, and more particularly, to a three-dimensional semiconductor memory device and a manufacturing method of a three-dimensional semiconductor memory device.

### 2. Related Art

A semiconductor memory device includes memory cells capable of storing data. A three-dimensional semiconductor memory device may include a three-dimensional memory cell array.

In order to improve the degree of integration of the three-dimensional memory cell array, a stacked number of memory cells may be increased. The stability of a manufacturing process of the three-dimensional semiconductor memory device may be deteriorated as the stacked number of memory cells is increased.

### SUMMARY

In accordance with an embodiment of the present disclosure, there is provided a semiconductor memory device including: a stack structure including a cell array region and a contact region with a stepped structure, the contact region extending from the cell array region; a channel structure extending in the cell array region of the stack structure, a memory layer between the channel structure and the stack structure; a groove defined in the contact region of the stack structure, the groove including a first sidewall defined by the stepped structure of the stack structure, a second sidewall facing the first sidewall, and a third sidewall between the first sidewall and the second sidewall; a filling insulating layer inside the groove; a barrier insulating layer disposed between the filling insulating layer and the stack structure, the barrier insulating layer being formed of a material different from a material of the filling insulating layer, the barrier insulating layer extending along the first sidewall, the second sidewall, and the third sidewall of the groove and a bottom surface of the filling insulating layer; and at least one conductive gate contact penetrating the filling insulating layer, the barrier insulating layer, and the stepped structure of the stack structure.

In accordance with another embodiment of the present disclosure, there is provided a semiconductor memory device including: a lower stack structure including a plurality of first interlayer insulating layers and a plurality of first conductive patterns, which are alternately stacked in a first direction; a channel structure extending in the lower stack structure; a memory layer between the channel structure and the lower stack structure; a first stepped groove spaced apart from the channel structure, the first stepped groove penetrating the lower stack structure; a first barrier insulating layer covering a surface of the first stepped groove; a first filling insulating layer disposed inside the first stepped groove, the first filling insulating layer being formed on the first barrier insulating layer; an upper stack structure including a plurality of second conductive patterns and a plurality of second interlayer insulating layers, which are alternately stacked on the lower stack structure in the first direction, wherein the channel structure and the memory extend in the upper stack structure; a second stepped groove spaced apart from the channel structure, the second stepped groove penetrating the upper stack structure; a second barrier insulating layer covering a surface of the second stepped groove; a second filling insulating layer disposed inside the second stepped groove, the second filling insulating layer being formed on the second barrier insulating layer; a first conductive gate contact penetrating the second filling insulating layer, the second barrier layer, and the lower stack structure; and a second conductive gate contact penetrating the upper stack structure, the first filling insulating layer, and the first barrier insulating layer.

In accordance with still another embodiment of the present disclosure, there is provided a method of manufacturing a semiconductor memory device, the method including: forming a preliminary stack structure including a plurality of first material layers and a plurality of second material layers, which are alternately stacked in a first direction, the preliminary stack structure including a cell array region and a contact region extending from the cell array region; etching the contact region of the preliminary stack structure such that a groove is formed, wherein the groove includes a first sidewall with a stepped structure, a second sidewall facing the first sidewall, and third and fourth sidewalls which are disposed between the first sidewall and the second sidewall and face each other; forming a barrier insulating layer continuously extending along the first sidewall, the second sidewall, the third sidewall, and the fourth sidewall of the groove; forming a filling insulating layer inside the groove; and forming a slit, a channel hole, and a contact hole by using an etching material for etching the plurality of first material layers and the plurality of second material layers, wherein the slit penetrates the cell array region of the preliminary stack structure and extends to the contact region of the preliminary stack structure, the channel hole penetrates the cell array region of the preliminary stack structure, and the contact hole penetrates the filling insulating layer, the barrier insulating layer, and the stepped structure of the groove.

### BRIEF DESCRIPTION OF THE DRAWINGS

Examples of embodiment will now be described more fully hereinafter with reference to the accompanying drawings; however, they may be embodied in different forms and should not be construed as limited to the embodiments set forth herein.

In the drawing figures, dimensions may be exaggerated for clarity of illustration. It will be understood that when an element is referred to as being “between” two elements, it can be the only element between the two elements, or one or more intervening elements may also be present. Like reference numerals refer to like elements throughout. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

FIG. 1 is a block diagram illustrating a semiconductor memory device in accordance with an embodiment of the present disclosure.

FIGS. 2A and 2B are views schematically illustrating arrangements of a peripheral circuit structure, a memory cell array, a plurality of bit lines, and a source layer in accordance with embodiments of the present disclosure.

FIGS. 3A and 3B are plan views illustrating a portion of a semiconductor memory device in accordance with an embodiment of the present disclosure.

FIG. 4A illustrates, for example, a cross-section of a cell plug shown in FIG. 3A, and FIG. 4B illustrates, for example, a cross-section of a dummy plug shown in FIG. 3A.

FIG. 5 is a perspective view schematically illustrating a contact region of a stack structure shown in FIGS. 3A and 3B.

FIGS. 6A, 6B, 6C, 6D, and 6E are sectional views illustrating the semiconductor memory device shown in FIGS. 3A and 3B.

FIG. 7 is an enlarged sectional view of a boxed region shown in FIG. 6B.

FIG. 8 is a sectional view of a semiconductor memory device in accordance with an embodiment of the present disclosure.

FIGS. 9A and 9B are sectional views illustrating semiconductor memory devices in accordance with various embodiments of the present disclosure.

FIGS. 10A and 10B are plan views illustrating a portion of a semiconductor memory device in accordance with an embodiment of the present disclosure.

FIGS. 11A and 11B are views illustrating a first sidewall and a second sidewall, which are shown in FIGS. 10A and 10B.

FIGS. 12, 13A, and 13B are views illustrating processes of forming a first stepped groove, a first barrier insulating layer, and a first filling insulating layer.

FIGS. 14 and 15 are sectional views illustrating a process of replacing an etch stop layer shown in FIG. 12 with a second interposition insulating layer.

FIGS. 16, 17A, 17B, 17C, 17D, and 17E are views illustrating a process of forming lower sacrificial structures.

FIGS. 18, 19A, and 19B are views illustrating processes of forming a second stepped groove, a second barrier insulating layer, and a second filling insulating layer.

FIGS. 20, 21A, 21B, 21C, 21D, and 21E are views illustrating a process of forming upper sacrificial structures.

FIGS. 22A, 22B, 22C, 22D, and 22E are sectional views illustrating a process of removing some of a plurality of primary sacrificial structures.

FIGS. 23, 24, 25, and 26 are sectional views illustrating processes of forming a pad pattern and an insulating layer.

FIGS. 27A, 27B, 27C, 27D, and 27E are sectional views illustrating a process of forming a plurality of secondary sacrificial structures.

FIGS. 28A, 28B, 28C, 28D, 28E, 29A, 29B, 30A, 30B, 31A, 31B, 31C, 31D, and 31E are sectional views illustrating a process of forming a cell plug and a dummy plug.

FIGS. 32 and 33 are sectional views illustrating a process of replacing some of the plurality of primary sacrificial structures with a first isolation structure.

FIGS. 34A, 34B, 34C, 34D, 34E, 35A, 35B, 35C, 35D, and 35E are sectional views illustrating a process of replacing a plurality of lower second material layers, a plurality of upper second material layers, and the pad pattern with a conductor.

FIGS. 36A, 36B, 36C, 36D, and 36E are sectional views illustrating a process of removing some of the plurality of primary sacrificial structures.

FIGS. 37 and 38 are sectional views illustrating a process of exposing a second part of the conductor.

FIGS. 39, 40, 41, and 42 are sectional views illustrating a manufacturing method of a semiconductor memory device in accordance with an embodiment of the present disclosure.

FIG. 43 is a block diagram illustrating a configuration of a memory system in accordance with an embodiment of the present disclosure.

FIG. 44 is a block diagram illustrating a configuration of a computing system in accordance with an embodiment of the present disclosure.

### DETAILED DESCRIPTION

Explanation of the present disclosure is merely an embodiment for structural or functional explanation, so the scope of the present teachings should not be construed to be limited to the embodiments explained in the embodiment. Therefore, various changes and modifications that fall within the scope of the claims, or equivalents of such scope are therefore intended to be embraced by the appended claims.

While terms such as “first” and “second” may be used to describe various components, such components should not be understood as being limited to the above terms. The above terms are used only to distinguish one component from another.

Embodiments are directed to a semiconductor memory device and a manufacturing method of a semiconductor memory device, which may improve the stability of a manufacturing process.

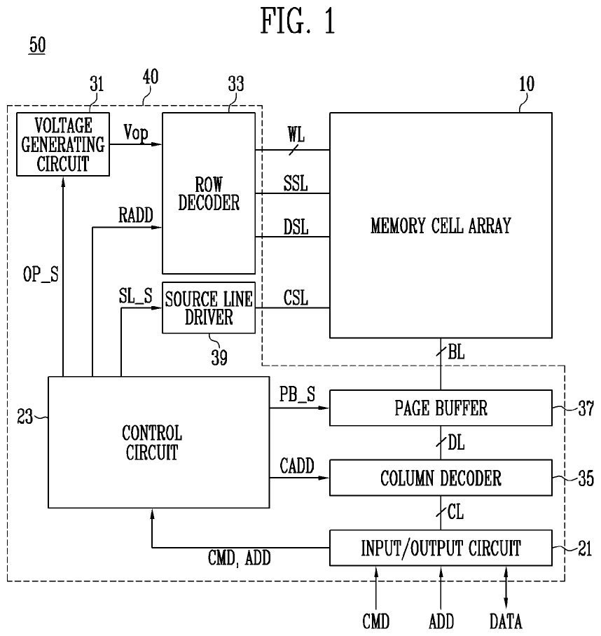

FIG. 1 is a block diagram illustrating a semiconductor memory device in accordance with an embodiment of the present disclosure.

Referring to FIG. 1, the semiconductor memory device 50 may include a peripheral circuit structure 40 and a memory cell array 10.

The peripheral circuit structure 40 may be configured to perform a program operation for storing data in the memory cell array 10, a read operation for outputting data stored in the memory cell array 10, and an erase operation for erase data stored in the memory cell array 10. In an embodiment, the peripheral circuit 40 may include an input/output circuit 21, a control circuit 23, a voltage generating circuit 31, a row decoder 33, a column decoder 35, a page buffer 37, and a source line driver 39.

The memory cell array 10 may include a plurality of memory cells in which data is stored. The memory cells may be three-dimensionally arranged. The memory cell array 10 may be connected to a drain select line DSL, a plurality of word lines WL, a source select line SSL, a plurality of bit lines BL, and a common source line CSL.

The input/output circuit 21 may transfer, to the control circuit 23, a command CMD and an address ADD, which are transferred from an external device (e.g., a memory controller) of the semiconductor memory device 50. The input/output circuit 21 may exchange data DATA with the external device and the column decoder 35.

The control logic 23 may output an operation signal OP_S, a row address RADD, a source line control signal SL_S, a page buffer control signal PB_S, and a column address CADD in response to the command CMD and the address ADD.

The voltage generating circuit 31 may generate various operating voltages Vop used for a program operation, a read operation, and an erase operation in response to the operation signal OP_S.

The row decoder 33 may transfer the operating voltages Vop to the drain select line DSL, the word lines WL, and the source select line SSL in response to the row address RADD.

The column decoder 35 may transmit data DATA input from the input/output circuit 21 to the page buffer 37 or transmit data DATA stored in the page buffer 37 to the input/output circuit 21, in response to the column address CADD. The column decoder 35 may exchange data DATA with the input/output circuit 21 through column lines CL. The column decoder 35 may exchange data DATA with the page buffer 37 through data lines DL.

The page buffer 37 may temporarily store data DATA received through the bit lines BL in response to the page buffer control signal PB_S. The page buffer 37 may sense a voltage or current of the bit lines BL in a read operation.

The source line driver 39 may control a voltage applied to the common source line CSL in response to the source line control signal SL_S.

In order to improve the degree of integration of the semiconductor memory device, the memory cell array 10 may overlap with the peripheral circuit structure 40.

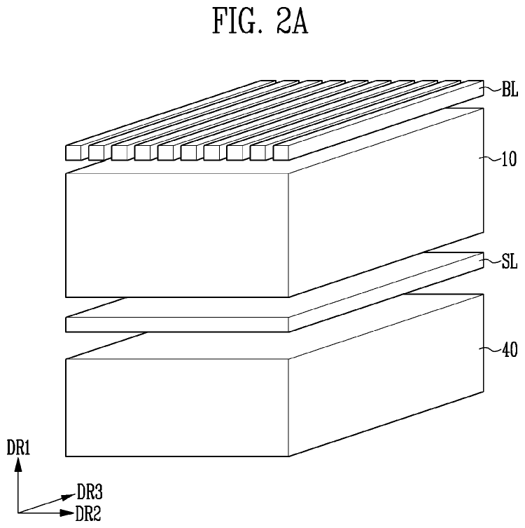

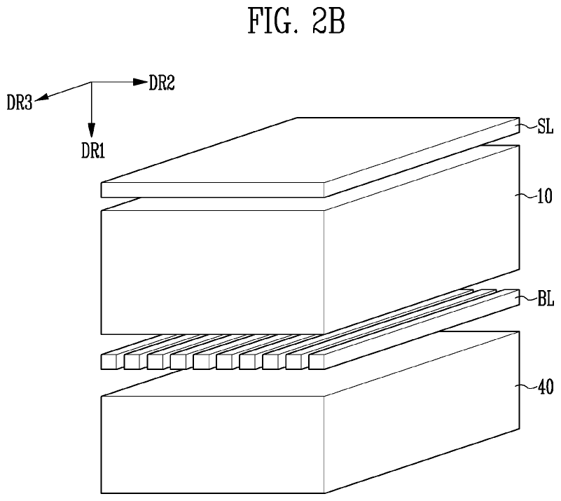

FIGS. 2A and 2B are views schematically illustrating arrangements of a peripheral circuit structure, a memory cell array, a plurality of bit lines, and a source layer in accordance with embodiments of the present disclosure.

Referring to FIGS. 2A and 2B, the peripheral circuit structure 40 may be disposed on a substrate. The memory cell array 10, the source layer SL, and the plurality of bit lines BL may overlap with the peripheral circuit structure 40. The memory cell array 10 may be disposed between the source layer SL and the plurality of bit lines BL.

The source layer SL and the plurality of bit lines BL may be connected to the memory cell array 10 through channel structures. In an embodiment, the source layer SL may be connected to the peripheral circuit structure 40 via the common source line CSL shown in FIG. 1. In another embodiment, the source layer SL may constitute the common source line CSL shown in FIG. 1.

The arrangement of the source layer SL, the plurality of bit lines BL, and the memory cell array may vary.

Referring to FIG. 2A, in an embodiment, the source layer SL may be disposed between the memory cell array 10 and the peripheral circuit structure 40. The plurality of bit lines BL may overlap with the source layer SL with the memory cell array 10 interposed therebetween. In other words, the source layer SL and the memory cell array 10 may be disposed between the peripheral circuit structure 40 and the plurality of bit lines BL.

Referring to FIG. 2B, in an embodiment, the plurality of bit lines BL may be disposed between the memory cell array 10 and the peripheral circuit structure 40. The source layer SL may overlap with the plurality of bit lines BL with the memory cell array 10 interposed therebetween. In other words, the plurality of bit lines BL and the memory cell array 10 may be disposed between the peripheral circuit structure 40 and the source layer SL.

Referring to FIGS. 2A and 2B, in an embodiment, processes for forming the source layer SL, the plurality of bit lines BL, and the memory cell array 10 may be performed on the peripheral circuit structure 40. In another embodiment, a process for forming the memory cell array 10 may be performed separately from a process for forming the peripheral circuit structure 40. The memory cell array 10 and the peripheral circuit structure 40 may be electrically connected to each other by bonding conductive bonding pads to each other.

The memory cell array 10 may include a plurality of cell strings. Each cell string may include a source select transistor, a plurality of memory cells, and a drain select transistor, which are stacked in a first direction DR1. A gate of the source select transistor, a plurality of gates of the plurality of memory cells, and a gate of the drain select transistor may be implemented by a plurality of conductive patterns stacked to be spaced apart from each other in the first direction DR1. Each conductive pattern may extend in a second direction DR2 and a third direction DR3. The first direction DR1, the second direction DR2, and the third direction DR3 may be defined as directions in which axes intersecting one another face. In an embodiment, the first direction DR1, the second direction DR2, and the third direction DR3 may respectively correspond to directions in which an X axis, a Y axis, and a Z axis of an XYZ coordinate system face. Hereinafter, a stack structure including the plurality of conductive patterns described above will be described.

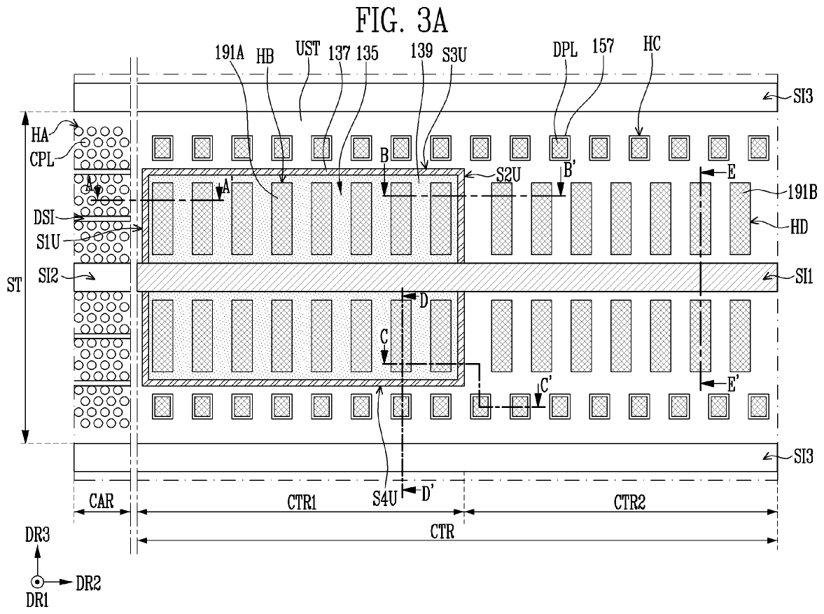

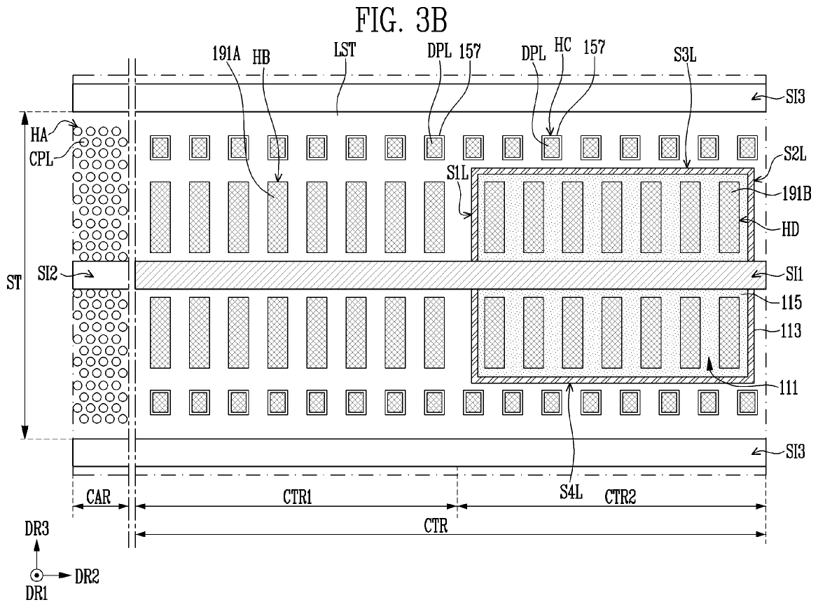

FIGS. 3A and 3B are plan views illustrating a portion of a semiconductor memory device in accordance with an embodiment of the present disclosure. A structure shown in FIG. 3A may overlap with a structure shown in FIG. 3B in the first direction DR1.

Referring to FIGS. 3A and 3B, the semiconductor memory device may include a stack structure ST. The stack structure ST may include a cell array region CAR and a contact region CTR extending from the cell array region CAR. In an embodiment, the stack structure ST may include an upper stack structure UST shown in FIG. 3A and a lower stack structure LST shown in FIG. 3B. The contact region CTR may be divided into a first contact region CTR1 occupied by a plurality of first conductive gate contacts 191A and a second contact region CTR2 occupied by a plurality of second conductive gate contacts 191B. The plurality of first conductive gate contacts 191A may be provided to supply an electrical signal to the upper stack structure UST, and the plurality of second conductive gate contacts 191B may be provided to supply an electrical signal to the lower stack structure LST. The second contact region CTR2 may extend from the first contact region CTR1. The first contact region CTR1 may be disposed between the cell array region CAR and the second contact region CTR2.

Each of the upper stack structure UST and the lower stack structure LST may be penetrated by a plurality of cell plugs CPL extending in the first direction DR1 in the cell array area CAR. The plurality of cell plugs CPL may be respectively disposed inside a plurality of channel holes HA penetrating the cell array region CAR of the stack structure ST. A cross-sectional shape of each cell plug CPL may vary, such as a circular shape, an elliptical shape, a polygonal shape, and a square shape.

The stack structure ST may be penetrated by a first slit SI1 and a second slit SI2, and be adjacent to another stack structure by using a third slit SI3 as a boundary. Each of the first slit SI1, the second slit SI2, and the third slit SI3 may extend in the second direction DR2. The first slit SI1 and the second slit SI2 may be adjacent to each other in the second direction DR2.

The first slit SI1 may extend across the first contact region CTR1 and the second contact region CTR2. The second slit SI2 may extend toward the first slit SI1 from the cell array region CAR. Although omitted in the drawings, the first slit SI1 and the second slit SI2 may be connected to each other in a connection region (not shown) between the cell array region CAR and the contact region CTR. The third slit SI3 may extend in parallel to the first slit SI1 and the second slit SI2. The third slit SI3 may be spaced apart from the first slit SI1 and the second slit SI2 in the third direction DR3.

The plurality of cell plugs CPL may be disposed between the second slit SI2 and the third slit SI3. A select isolation structure penetrating a portion of the upper stack structure UST may be disposed between the second slit SI2 and the third slit SI3. In an embodiment, a drain select isolation structure DSI isolating drain select lines may be disposed between the second slit SI2 and the third slit SI3.

Referring to FIG. 3B, a first stepped groove 111 may be formed inside the lower stack structure LST in the second contact region CTR2. The first stepped groove 111 may include a lower first sidewall S1L, a lower second sidewall S2L, a lower third sidewall S3L, and a lower fourth sidewall S4L. The lower first sidewall S1L may be defined as a sidewall adjacent to the cell plug CPL, and the lower second sidewall S2L may be defined as a sidewall facing the lower first sidewall S1L. The lower third sidewall S3L and the lower fourth sidewall S4L may be defined as sidewalls which are disposed between the lower first sidewall S1L and the lower second sidewall S2L and face each other.

A first filling insulating layer 115 may be disposed inside the first stepped groove 111. A first barrier insulating layer 113 may be disposed between the first filling insulating layer 115 and the lower stack structure LST. The first barrier insulating layer 113 may continuously extend along the lower first sidewall S1L, the lower second sidewall S2L, and the lower third sidewall S3L, or continuously extend along the lower first sidewall S1L, the lower second sidewall S2L, and the lower fourth sidewall S4L. The lower stack structure LST may extend to form a common plane with the lower first sidewall S1L, the lower second sidewall S2L, the lower third sidewall S3L, and the lower fourth sidewall S4L.

The first slit SI1 may be disposed between the lower third sidewall S3L and the lower fourth sidewall S4L, and be formed across the first stepped groove 111. The first slit SI1 may intersect the lower first sidewall S1L and the lower second sidewall S2L. Each of the first filling insulating layer 115 and the first barrier insulating layer 113 may be penetrated by the first slit SI1. Each of the first filling insulating layer 115 and the first barrier insulating layer 113 may be isolated into patterns disposed at both sides of the first slit SI1. The first slit SI1 may have a sidewall forming a common plane with the first filling insulating layer 115 and the first barrier insulating layer 113.

The first stepped groove 111 may be disposed at a position spaced apart from the second slit SI2 and the third slit SI3.

Referring to FIG. 3A, a second stepped groove 135 may be formed inside the upper stack structure UST in the first contact region CTR1. The second stepped groove 135 may include an upper first sidewall S1U, an upper second sidewall S2U, an upper third sidewall S3U, and an upper fourth sidewall S4U. The upper first sidewall S1U may be defined as a sidewall adjacent to the cell plug CPL, and the upper second sidewall S2U may be a sidewall facing the upper first sidewall S1U. The upper third sidewall S3U and the upper fourth sidewall S4U may be defined as sidewalls which are disposed between the upper first sidewall S1U and the upper second sidewall S2U and face each other. A second filling insulating layer 139 may be disposed inside the second stepped groove 135. A second barrier insulating layer 137 may be disposed between the second filling insulating layer 139 and the upper stack structure UST. The second barrier insulating layer 137 may continuously extend along the upper first sidewall S1U, the upper second sidewall S2U, and the upper third sidewall S3U, or continuously extend along the upper first sidewall S1U, the upper second sidewall S2U, and the upper fourth sidewall S4U. The upper stack structure UST may extend to form a common plane with the upper first sidewall S1U, the upper second sidewall S2U, the upper third sidewall S3U, and the upper fourth sidewall S4U of the second stepped groove 135. In an embodiment, the first stepped groove 111 and the second stepped groove 135 may be defined as a groove in the contact region CTR of the stack structure ST. In an embodiment, the first filling insulating layer 115 and the second filling insulating layer 139 may be defined as a filling insulating layer inside the groove. In an embodiment, the first barrier insulating layer 113 and the second barrier insulating layer 137 may be defined as a barrier insulating layer disposed between the filling insulating layer and the stack structure ST including the upper and lower stack structures UST and LST.

The first slit SI1 may be disposed between the upper third sidewall S3U and the upper fourth sidewall S4U, and be form across the second stepped groove 135. The first slit SI1 may intersect the upper first sidewall S1U and the upper second sidewall S2U. Each of the second filling insulating layer 139 and the second barrier insulating layer 137 may be penetrated by the first slit SI1. Each of the second filling insulating layer 139 and the second barrier insulating layer 137 may be isolated into patterns disposed at both the sides of the first slit SI1.

The second stepped groove 135 may be disposed at a position spaced apart from the second slit SI2 and the third slit SI3.

The drain select isolation structure DSI, the first slit SI1 and the second slit SI2 may be used as isolation structures which isolate a conductor of the upper stack structure UST, which is disposed at the same level, into a plurality of drain select lines.

Referring to FIGS. 3A and 3B, the plurality of first conductive gate contacts 191A may be respectively formed inside a plurality of first contact holes HB. The plurality of first contact holes HB may extend in the first direction DR1 to penetrate the second filling insulating layer 139 and the lower stack structure LST. From a planar viewpoint, the second stepped groove 135 and the plurality of first conductive gate contacts 191A may be disposed between the plurality of cell plugs CPL and the first stepped groove 111.

The plurality of second conductive gate contacts 191B may be respectively formed inside a plurality of second contact holes HD. The plurality of second contact holes HD may extend in the first direction DR1 to penetrate the upper stack structure UST and the first filling insulating layer 115.

Each first conductive gate contact 191A and each second conductive gate contact 191B may have various cross-sectional shapes such as a circular shape, an elliptical shape, a polygonal shape, and a square shape. The first conductive gate contact 191A and the second conductive gate contact 191B may have cross-sectional shapes equal to or different from each other at the substantially same level. Each of the first contact hole HB and the second contact hole HD may be formed to have an area wider than an area of the channel hole HA at the substantially same level.

The semiconductor memory device may further include a plurality of dummy plugs DPL penetrating the contact region CTR of the stack structure ST. In an embodiment, the plurality of dummy plugs DPL may penetrate the upper stack structure UST and the lower stack structure LST between the first stepped groove 111 and the third slit SI3 and between the second stepped groove 135 and the third slit SI3. The plurality of dummy plugs DPL may be arranged along the lower third sidewall S3L and the lower fourth sidewall S4L of the first stepped groove 111 and the upper third sidewall S3U and the upper fourth sidewall S3U of the second stepped groove 135.

The plurality of dummy plugs DPL may be respectively disposed inside a plurality of dummy holes HC penetrating the lower stack structure LST and the upper stack structure UST. An insulating layer 157 may be disposed between each dummy plug DPL and the stack structure ST. The insulating layer 157 may extend along a sidewall of a dummy hole HC corresponding thereto. A cross-sectional shape of the dummy hole HC may vary, such as a circular shape, an elliptical shape, a polygonal shape, and a square shape. The dummy hole HC may be formed to have an area wider than the area of the channel hole HA.

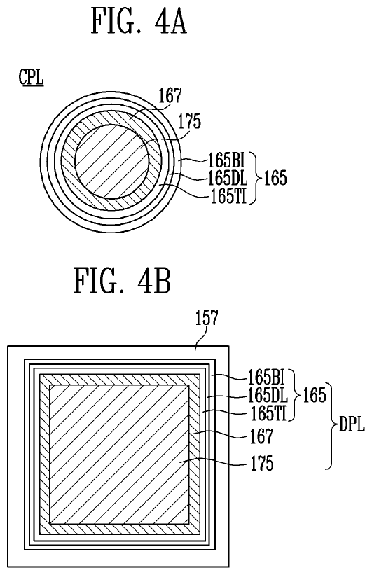

FIG. 4A illustrates, for example, a cross-section of the cell plug CPL shown in FIG. 3A, and FIG. 4B illustrates, for example, a cross-section of the dummy plug DPL shown in FIG. 3A.

Referring to FIGS. 4A and 4B, each of the cell plug CPL and the dummy plug DPL may include a capping pattern 175, a channel structure 167, and a memory layer 165. The channel structure 167 may surround a sidewall of the capping pattern 175. The memory layer 165 may surround a sidewall of the channel structure 167.

The memory layer 165 may include a tunnel insulating layer 165TI, a data storage layer 165DL, and a first blocking insulating layer 165BI. The tunnel insulating layer 165TI may extend along the sidewall of the channel structure 167, and include an insulating material in which charges can tunnel. The data storage layer 165DL may extend along a sidewall of the tunnel insulating layer 165TI. The data storage layer 165DL may include a material layer capable of storing data changed using Fowler-Nordheim tunneling. In an embodiment, the data storage layer 165DL may include a nitride layer in which charges can be trapped. However, the present disclosure is not limited thereto, and the data storage layer 165DL may include a phase change material, a nano dot, and the like. The first blocking insulating layer 165BI may extend along a sidewall of the data storage layer 165DL. The first blocking insulating layer 165BI may include an insulating material capable of blocking movement of charges.

A sidewall of the dummy plug DPL may be surrounded by the insulating layer 157.

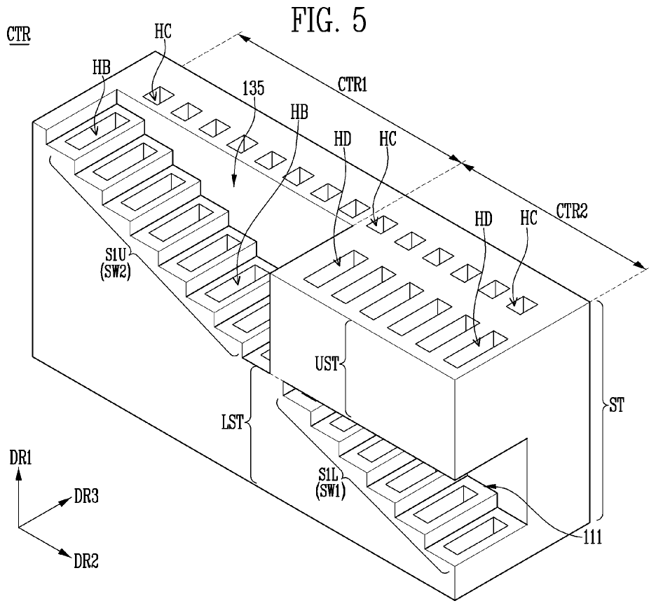

FIG. 5 is a perspective view schematically illustrating the contact region CTR of the stack structure ST shown in FIGS. 3A and 3B.

Referring to FIG. 5, the lower stack structure LST may continuously extend toward the second contact region CTR2 from the first contact region CTR1 in the contact region CTR. The first stepped groove 111 may be formed in the second contact region CTR2 of the lower stack structure LST. The lower first sidewall S1L of the first stepped groove 111 may be formed in a first stepped structure SW1.

The upper stack structure UST may continuously extend toward the second contact region CTR2 from the first contact region CTR1 in the contact region CTR. The upper stack structure UST may overlap with the first stepped groove 111 in the second contact region CTR2. The second stepped groove 135 may be formed in the first contact region CTR1 of the upper stack structure UST. The upper first sidewall S1U of the second stepped groove 135 may be formed in a second stepped structure SW2.

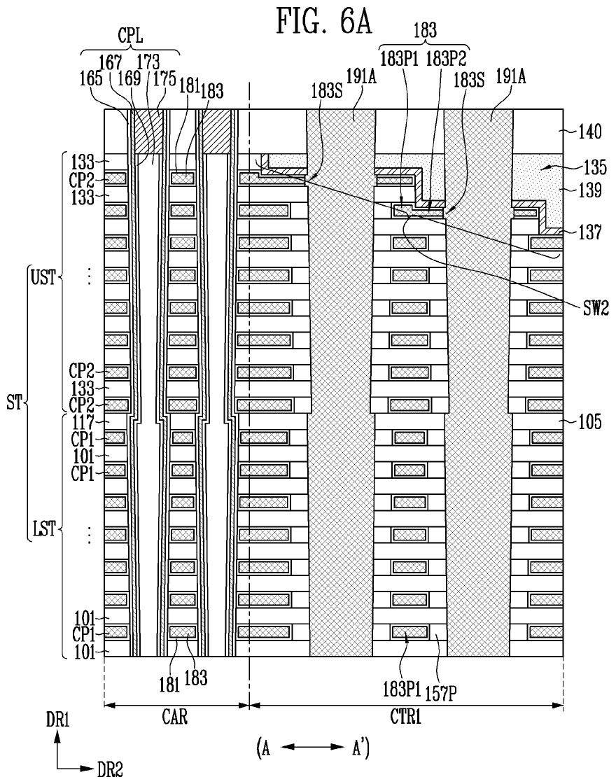

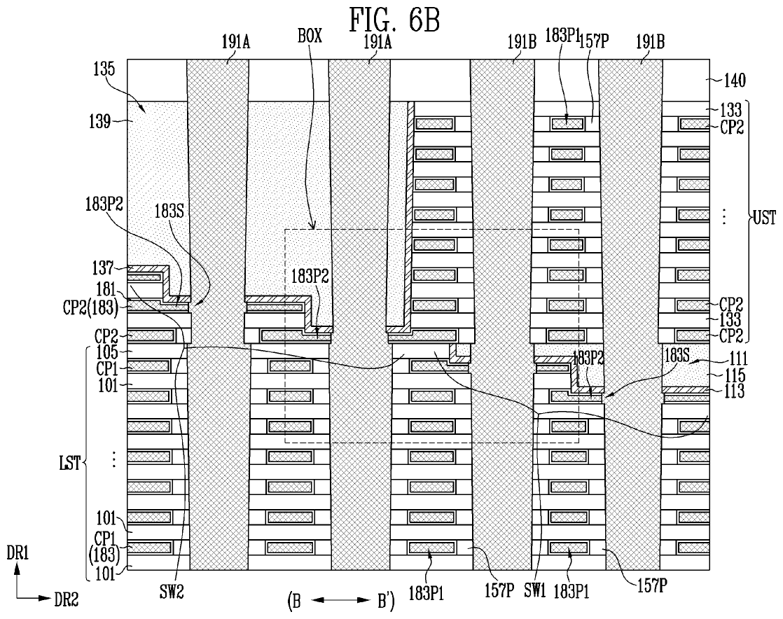

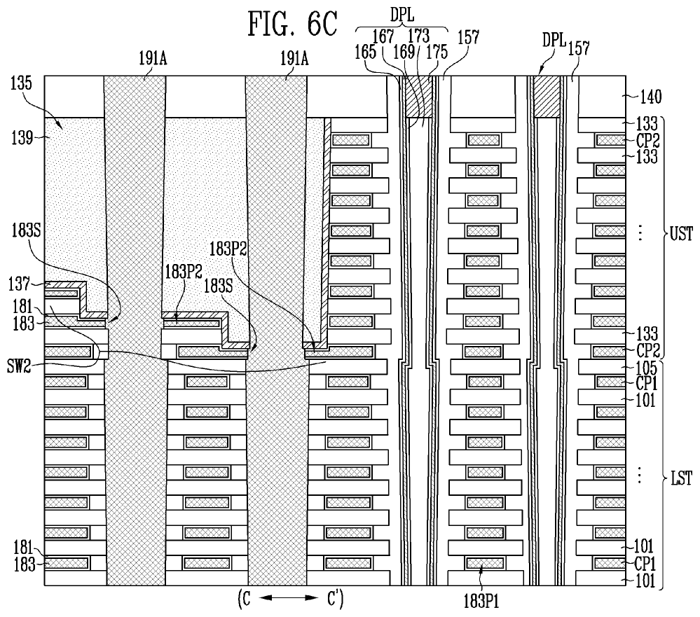

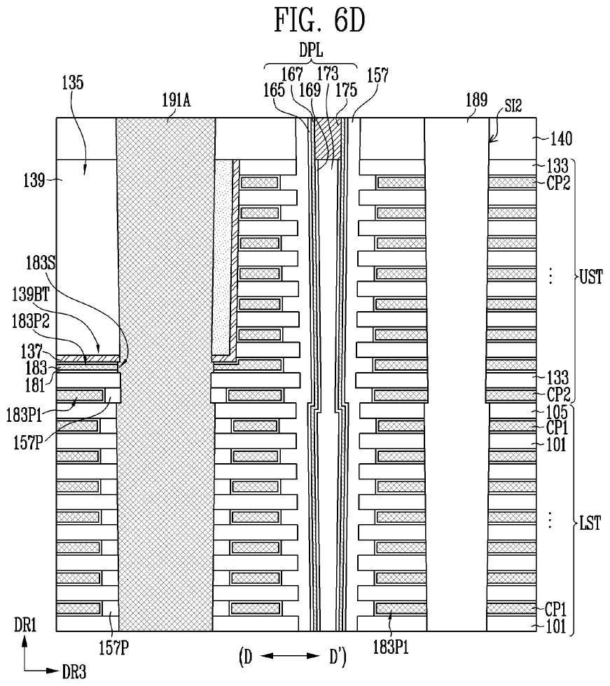

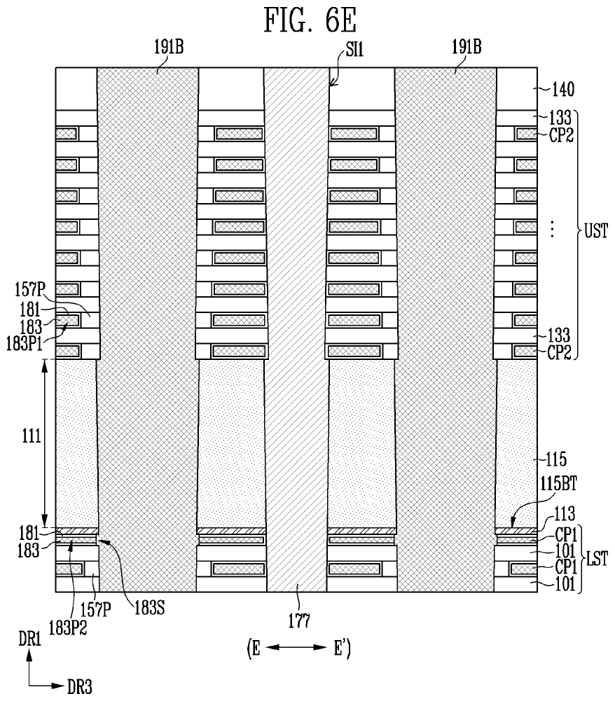

Each of the lower stack structure LST and the upper stack structure UST may include a plurality of conductive patterns and a plurality of interlayer insulating layers, which are alternately stacked in the first direction DR1. Components of each of the lower stack structure LST and the upper stack structure UST will be described later with reference to FIGS. 6A and 6B.

The lower stack structure LST and the upper stack structure UST in the contact region CTR may be penetrated by a plurality of first contact holes HB, a plurality of dummy holes HC, and a plurality of second contact holes HD.

FIGS. 6A, 6B, 6C, 6D, and 6E are sectional views illustrating the semiconductor memory device shown in FIGS. 3A and 3B. FIG. 6A illustrates a section of the cell array region CAR and the first contact region CTR1 of the stack structure ST, taken along line A-A′ shown in FIG. 3A. FIG. 6B illustrates a section of the first contact region CTR1 and the second contact region CTR2, taken along line B-B′ shown in FIG. 3A. FIG. 6C illustrates a section of the first contact region CTR1 and the second contact region CTR2, taken along line C-C′ shown in FIG. 3A. FIG. 6D illustrates a section of the second stepped groove 135 taken along line D-D′ shown in FIG. 3A. FIG. 6E illustrates a section of the first stepped groove 111 taken along line E-E′ shown in FIG. 3A.

Referring to FIG. 6A to 6E, the stack structure ST may include the lower stack structure LST and the upper stack structure UST, which are stacked in the first direction DR1. The lower stack structure LST may include a plurality of first interlayer insulating layers 101 and a plurality of first conductive patterns CP1, which are alternately stacked in the first direction DR1. The upper stack structure UST may be disposed on the lower stack structure LST, and include a plurality of second conductive patterns CP2 and a plurality of second interlayer insulating layers 133, which are alternately stacked in the first direction DR1. The lower stack structure LST may further include a first interposition insulating layer 105 and a second interposition insulating layer 117. The first interposition insulating layer 105 and the second interposition insulating layer 117 may be disposed between an uppermost first conductive pattern adjacent to the upper stack structure UST among the plurality of first conductive patterns CP1 and the upper stack structure UST. The first interposition insulating layer 105 may be disposed in the contact region. The second interposition insulating layer 117 may be disposed in the cell array region CAR, and surround a cell plug CPL at a level at which the first interposition insulating layer 105 is disposed. The first interposition insulating layer 105 and the second interposition insulating layer 117 may be formed of the same insulating material as the plurality of first interlayer insulating layers 101.

The plurality of first conductive patterns CP1 and the plurality of first interlayer insulating layers 101 may surround the cell plug CPL as shown in FIG. 6A. The plurality of first conductive patterns CP1 and the plurality of first interlayer insulating layers 101 may extend toward the contact region to form the first stepped structure SW1 of the first stepped hole 111 as shown in FIG. 6B. A surface of the first stepped groove 111 may be covered by the first barrier insulating layer 113 as shown in each of FIGS. 6B and 6E. The first filling insulating layer 115 may be disposed inside the first stepped groove 111 and be disposed on the first barrier insulating layer 113 as shown in each of FIGS. 6B and 6E. The first barrier insulating layer 113 may extend along a bottom surface 115BT of the first filling insulating layer 115 as shown in FIG. 6E. The first filling insulating layer 115 and the first barrier layer 113 may be covered by the upper stack structure UST as shown in each of FIGS. 6B and 6E.

The plurality of second conductive patterns CP2 and the plurality of second interlayer insulating layers 133 may surround the cell plug CPL as shown in FIG. 6A. The plurality of second conductive patterns CP2 and the plurality of second interlayer insulating layers 133 may extend toward the contact region to form the second stepped structure SW2 of the second stepped groove 135 as shown in each of FIGS. 6A, 6B, and 6C. A surface of the second stepped groove 135 may be covered by the second barrier insulating layer 137 as shown in each of FIGS. 6A, 6B, and 6C. The second filling insulating layer 139 may be disposed inside the second stepped groove 135 and be disposed on the second barrier layer 137 as shown in each of FIGS. 6A, 6B, and 6C. The second barrier insulating layer 137 may extend along a bottom surface 139BT of the second filling insulating layer 139 as shown in FIG. 6D. The upper stack structure UST, the second filling insulating layer 139, and the second barrier insulating layer 137 may be covered by a first horizontal insulating layer 140. In an embodiment, the bottom surface 115BT of the first filling insulating layer 115 and the bottom surface 139BT of the second filling insulating layer 139 may be defined as a bottom surface of the filling insulating layer. In an embodiment, the barrier insulating layer may extend along the bottom surface of the filling insulating layer.

Each of the cell plugs CPL and a dummy plug DPL may penetrate the first horizontal insulating layer 140. Each of the cell plug CPL and the dummy plug DPL might not only include the memory layer 165, the channel structure 167, and the capping pattern 175 but also further include a core insulating layer 173. The channel structure 167 may be formed of a semiconductor material such as silicon. The capping pattern 175 may include a doped semiconductor layer including at least one of an n-type impurity and a p-type impurity. The channel structure 167 may be formed in a tubular shape have a central region filled with the core insulating layer 173 and a capping pattern 175. The channel structure 167 may extend along the first direction DR1 in the stack structure ST. In other words, the channel structure 167 may extend in the lower stack structure LST and extend in the upper stack structure UST. The memory layer 165 may be formed between the channel structure 167 and the stack structure ST. In other words, the memory layer 165 may be formed between the channel structure 167 and the lower stack structure LST and may extend in the upper stack structure UST. The first direction DR1 may be defined as a length direction of the channel structure 167. Each of the cell plug CPL and the dummy plug DPL may further include a buffer insulating layer 169 disposed between the channel structure 167 and the core insulating layer 173 as shown in each of FIGS. 6A and 6C.

The channel structure 167 of the cell plug CPL may be used as a channel of a cell string. The memory layer 165 of the cell plug CPL may be used as a data storage region and a gate insulating layer. The capping pattern 175 of the cell plug CPL may be used as a junction of the cell string.

The memory layer 165, the channel structure 167, the capping pattern 175, and the core insulating layer 173 of the dummy plug DPL may be used as a support structure in a manufacturing process of the semiconductor memory device. The insulating layer 157 is interposed between the stack structure ST and the dummy plug DPL as shown in FIG. 6C, so that an insulating characteristic between each of the plurality of first conductive patterns CP1 and the plurality of second conductive patterns CP2 and the channel structure 167 of the dummy plug DPL may be improved. The insulating layer 157 may protrude to a space between an upper insulating layer and a lower insulating layer, which are adjacent to each other in the first direction DR1, among the plurality of first interlayer insulating layers 101, the plurality of second interlayer insulating layers 133, the first interposition insulating layer 105, and the second interposition insulating layer 117. In an embodiment, the plurality of first interlayer insulating layers 101, the plurality of second interlayer insulating layers 133, the plurality of first conductive patterns CP1 and the plurality of second conductive patterns CP2 may be referred to as a plurality of interlayer insulating layers and a plurality of conductive patterns. In an embodiment, the plurality of interlayer insulating layers and the plurality of conductive patterns may be alternately stacked in a length direction of the channel structure 167.

The plurality of conductive patterns CP1 and the plurality of conductive patterns CP2 may be used as the source select line SSL, the plurality of word line, and the drain select line DSL, which are shown in FIG. 1. In an embodiment, at least one second conductive pattern from an uppermost layer among the plurality of second conductive patterns CP2 may be used as the drain select line DSL shown in FIG. 1, at least one first conductive pattern from a lowermost layer among the plurality of first conductive patterns CP1 may be used as the source select line SSL shown in FIG. 1, and each of the other first conductive patterns and the other second conductive patterns may be used as the word line WL shown in FIG. 1.

A conductor 183 of each of the first conductive patterns CP1 and the plurality of second conductive patterns CP2 may include a first part 183P1 and a second part 183P2. The first part 183P1 of the conductor 183 may surround the cell plug CPL and extend toward the contact region. The first part 183P1 of the conductor 183 may be disposed between lower and upper insulating layers which are adjacent to each other in the first direction DR1. The plurality of first interlayer insulating layers 101, the plurality of second interlayer insulating layers 133, the first interposition insulating layer 105, and the second interposition insulating layer 117 may be divided into the upper insulating layer and the lower insulating layer, which are adjacent to each other in the first direction DR1, with respect to the first part 183P1 of the conductor 183. The second part 183P2 of the conductor 183 may extend from the first part 183P1 to constitute the first stepped structure SW1 or the second stepped structure SW2.

The plurality of first conductive gate contacts 191A may penetrate the second filling insulating layer 139 and the second barrier insulating layer 137 as shown in each of FIGS. 6A, 6B, 6C, and 6D. The plurality of first conductive gate contacts 191A may penetrate the second stepped structure SW2 of the upper stack structure UST and the lower stack structure LST. Each first conductive gate contact 191A may penetrate a second part 183P2 of a conductor 183 corresponding thereto.

The plurality of second conductive gate contacts 191B may penetrate the first filling insulating layer 115 and the first barrier insulating layer 113 as shown in each of FIGS. 6B and 6E. The plurality of second conductive gate contacts 191B may penetrate the upper stack structure UST, and penetrate the first stepped structure SW1 of the lower stack structure LST. Each second conductive gate contact 191B may penetrate a second part 183P2 of a conductor 183 corresponding thereto.

Each of the plurality of first conductive gate contacts 191A and the plurality of second conductive gate contacts 191B may be in contact with a second part 183P2 of a conductor 183 corresponding thereto. The second part 183P2 of the conductor 183 may have a sidewall 183S in contact with a conductive gate contact corresponding thereto among the plurality of first conductive gate contacts 191A and the plurality of second conductive gate contacts 191B.

The first part 183P1 of the conductor 183 may be penetrated by at least one of the plurality of first conductive gate contacts 191A and the plurality of second conductive gate contacts 191B. Each of the plurality of first conductive gate contacts 191A and the plurality of second conductive gate contacts 191B may be spaced apart from the first part 183P1 of the conductor 183. Each of the plurality of first conductive gate contacts 191A and the plurality of second conductive gate contacts 191B may be insulated from the first part 183P1 of the conductor 183 by a contact insulating pattern 157P. The contact insulating pattern 157P may surround a sidewall of each of the plurality of first conductive gate contacts 191A and the plurality of second conductive gate contacts 191B. The contact insulating pattern 157P may be interposed between an upper insulating layer and a lower insulating layer adjacent to each other in the first direction DR1. The plurality of first interlayer insulating layers 101, the plurality of second interlayer insulating layers 133, the first interposition insulating layer 105, and the second interposition insulating layer 117 may be divided into the upper insulating layer and the lower insulating layer with respect to the contact insulating pattern 157P.

The plurality of first conductive gate contacts 191A and the plurality of second conductive gate contacts 191B may penetrate the first horizontal insulating layer 140. In some embodiments, a first conductive gate contact 191A may be defined as a conductive gate contact, and in other embodiments, a second conductive gate contact 191B may be defined as the conductive gate contact.

The first horizontal insulating layer 140, the upper stack structure UST, the first filling insulating layer 115, the first barrier insulating layer 113, and the lower stack structure LST may be penetrated by the first slit SI1 as shown in FIG. 6E. The first slit SI1 may extend to penetrate the second filling insulating layer 139 and the second barrier insulating layer 137 as shown in FIG. 3A.

In an embodiment, the first slit SI1 may be filled with a first vertical structure 177. The first vertical structure 177 may be formed of an insulating material. Although not shown in the drawings, in another embodiment, the first vertical structure 177 may include a support structure and a sidewall insulating layer. The support structure may be disposed in a central region of the first slit SI1, be formed of the same material layers as the dummy plug DPL shown in FIG. 6C, and be simultaneously formed with the dummy plug DPL. A section of the support structure, taken in a direction intersecting the first slit SI1, may be substantially same to a section of the dummy plug DPL shown in FIG. 6D. The sidewall insulating layer may be disposed between the support structure and the stack structure ST, and be formed of the same material as the insulating layer 157 shown in FIG. 6C. The sidewall insulating layer may be simultaneously formed with the insulating layer 157. Similarly to the insulating layer 157, the sidewall insulating layer may protrude between plurality of first interlayer insulating layers 101, a plurality of second interlayer insulating layers 133, and the first interposition insulating layer 105, which are adjacent to one another in the first direction DR1.

The first horizontal insulating layer 140, the upper stack structure UST, and the lower stack structure LST may be penetrated by the third slit SI3 and the second slit SI2 shown in FIGS. 3A and 3B as shown in FIG. 6D. As shown in FIG. 6D, the third slit SI3 may be filled with a second vertical structure 189. The second vertical structure 189 may include an insulating material filling the third slit SI3, or include a vertical insulating layer disposed inside the third slit SI3 and a conductive vertical contact penetrating the vertical insulating layer. Materials same to materials of the second vertical structure 189 may be disposed inside the second slit SI2 shown in FIGS. 3A and 3B.

The semiconductor memory device may further include a second blocking insulating layer 181 extending along a surface of the conductor 183 of each of the plurality of conductive patterns CP1 and the plurality of second conductive patterns CP2. The second blocking insulating layer 181 may include an insulating material having a dielectric constant higher than a dielectric constant of the first blocking insulating layer 165BI of the memory layer 165 shown in FIGS. 4A and 4B. In an embodiment, the first blocking insulating layer 165BI may include silicon oxide, and the second blocking insulating layer 181 may include metal oxide such as aluminum oxide.

The second blocking insulating layer 181 may be disposed between the conductor 183 and the memory layer 165 of the cell plug CPL. The second blocking insulating layer 181 may extend between the conductor 183 and each of a plurality of first interlayer insulating layers 101, a plurality of second interlayer insulating layers 133, the first interposition insulating layer 105, and the second interposition insulating layer 117. The second blocking insulating layer 181 may extend between the conductor 183 and each of the first barrier insulating layer 113 and the second barrier insulating layer 137. The second blocking insulating layer 181 may extend between the contact insulating pattern 157P and the conductor 183. The second blocking insulating layer 181 may extend between the first vertical structure 177 and the conductor 183. The second blocking insulating layer 181 may extend between the first interlayer insulating layer 115 and the conductor 183.

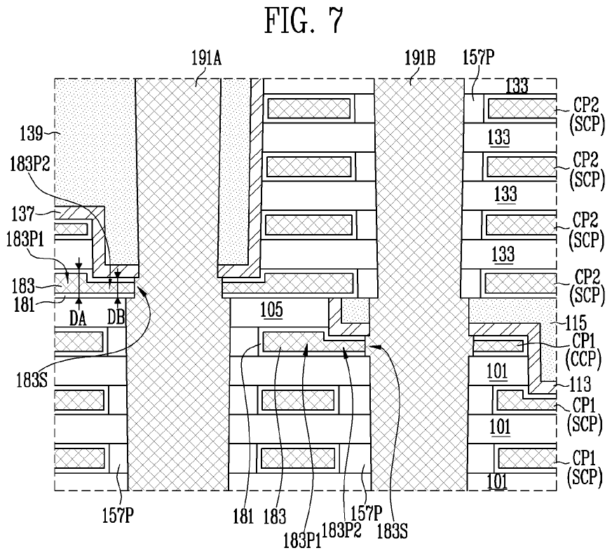

FIG. 7 is an enlarged sectional view of a boxed region BOX shown in FIG. 6B.

Referring to FIG. 7, with respect to a first conductive gate contact 191A and a second conductive gate contact 191B, a plurality of first conductive patterns CP1 and a plurality of second conductive patterns CP may be divided into a contact-conductive pattern and a separation-conductive pattern.

For example, with respect to the second conductive gate contact 191B, the plurality of first conductive patterns CP1 and the plurality of second conductive patterns CP2 may be divided into a contact-conductive pattern CCP and a plurality of separation-conductive patterns SCP. A second part 183P2 of a conductor 183 for the contact-conductive pattern CCP may have a sidewall 183S in contact with the second conductive gate contact 191B, and be electrically connected to the second conductive gate contact 191B. Each separation-conductive pattern SCP may be disposed at at least one level among levels upper and lower than the contact-conductive pattern CCP. For example, some of the plurality of separation-conductive patterns SCP may be located at levels lower than the contact-conductive patterns CCP. The others of the plurality of separation-conductive patterns SCP may be disposed at levels upper than the contact-conductive pattern CCP. A plurality of contact insulating patterns 157P may be disposed between the plurality of separation-conductive patterns SCP and the second conductive gate contact 191B.

With respect to the first conductive gate contact 191A, division of the separation-conductive patterns SCP and the contact-conductive pattern CCP may be different from the example shown in FIG. 7.

The first part 183P1 and the second part 183P2 of the conductor 183 may have different thicknesses. In the embodiment of the present disclosure, a case where a thickness DB of the second part 183P2 is smaller than a thickness DA of the first part 183P1 is illustrated for example. However, the present disclosure is not limited thereto. For example, the thickness of the second part 183P2 may be greater than the thickness of the first part 183P1.

The second blocking insulating layer 181 may be excluded between each of the first conductive gate contact 191A and the second conductive gate contact 191B and a second part 183P2 of a conductor 183 corresponding thereto. Accordingly, each of the first conductive gate contact 191A and the second conductive gate contact 191B may be directly in contact with a sidewall 183S of a second part 183P2 corresponding thereto.

The first filling insulating layer 115 and the second filling insulating layer 139 may be formed of a material different from materials for the first interlayer insulating layer 101, a first interposition insulating layer 105, the second interlayer insulating layer 133, the first barrier insulating layer 113, and the second barrier layer 137.

In an embodiment, the first filling insulating layer 115 and the second filling insulating layer 139 may include a high content of nitrogen or silicon, as compared with the first barrier insulating layer 113 and the second barrier insulating layer 137, and include a high content of nitrogen or silicon, as compared with the first interlayer insulating layer 101, the first interposition insulating layer 105, and the second interlayer insulating layer 133. The first interlayer insulating layer 101, the first interposition insulating layer 105, the second interlayer insulating layer 133, the first barrier insulating layer 113, and the second barrier insulating layer 137 may include a high content of oxygen, as compared with the first filling insulating layer 115 and the second filling insulating layer 139. For example, the first filling insulating layer 115 and the second filling insulating layer 139 may be formed of a SiOₓN_{y} (x=0 or x<y) or a SiₓO_{y} (x>y).

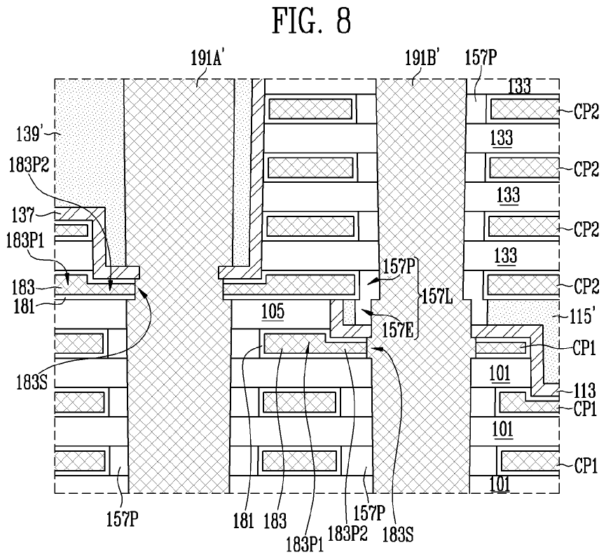

FIG. 8 is a sectional view of a semiconductor memory device in accordance with an embodiment of the present disclosure. FIG. 8 may correspond to the boxed region BOX shown in FIG. 6B. Hereinafter, overlapping descriptions components identical to those shown in FIG. 7 will be omitted.

Referring to FIG. 8, a first conductive gate contact 191A′ may further protrude toward a second filling insulating layer 139′ as compared with the first conductive gate contact 191A shown in FIG. 7. A second conductive gate contact 191B′ may further protrude toward a first filling insulating layer 115′ as compared with the second conductive gate contact 191B shown in FIG. 7. Such a structure may be provided as the first filling insulating layer 115′ and the second filling insulating layer 139′ are additionally etched in a process of manufacturing the semiconductor memory device. When the first filling insulating layer 115′ and the second filling insulating layer 139′ are additionally etched, the first barrier insulating layer 113 may remain in a state in which the first barrier insulating layer 113 further protrudes toward the second conductive gate contact 191B′ as compared with the first filling insulating layer 115′. In addition, the second barrier insulating layer 137 may remain in a state in which the second barrier insulating layer 137 further protrudes toward the first conductive gate contact 191A′ as compared with the second filling insulating layer 139′.

Some of a plurality of contact insulating patterns 157P disposed between a plurality of first interlayer insulating layers 101, the first interposition layer 105, and a plurality of second interlayer insulating layers 133 may be connected to an insulating pattern extension part 157E between the first filling insulating layer 115′ and the second conductive gate contact 191B′. The contact insulating pattern 157P and the insulating pattern extension part 157E may be integrated to form a connection pattern 157L. The connection pattern 157L may have an inflection point between a first conductive pattern CP1 and a second conductive pattern CP2, which are adjacent to each other.

A conductor 183 of each of the first conductive pattern CP1 and the second conductive pattern CP2 may include a first part 183P1 and a second part 183P2 as described with reference to FIG. 7. Each of the first conductive gate contact 191A′ and the second conductive gate contact 191B′ may penetrate the second blocking insulating layer 181 extending along a surface of the conductor 183. Accordingly, each of the first conductive gate contact 191A′ and the second conductive gate contact 191B′ may be in contact with a sidewall 183S of a second part 183P2 of a conductor 183 corresponding thereto.

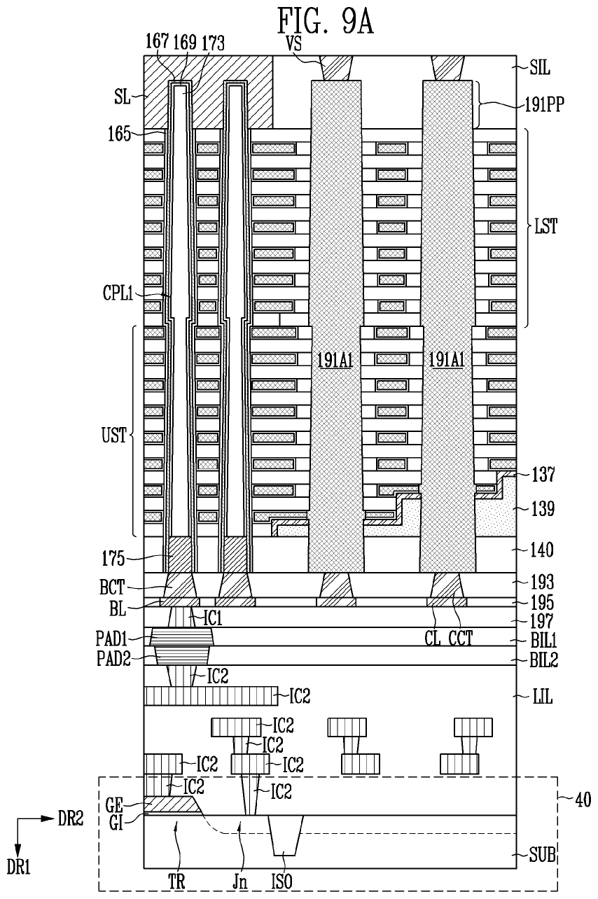

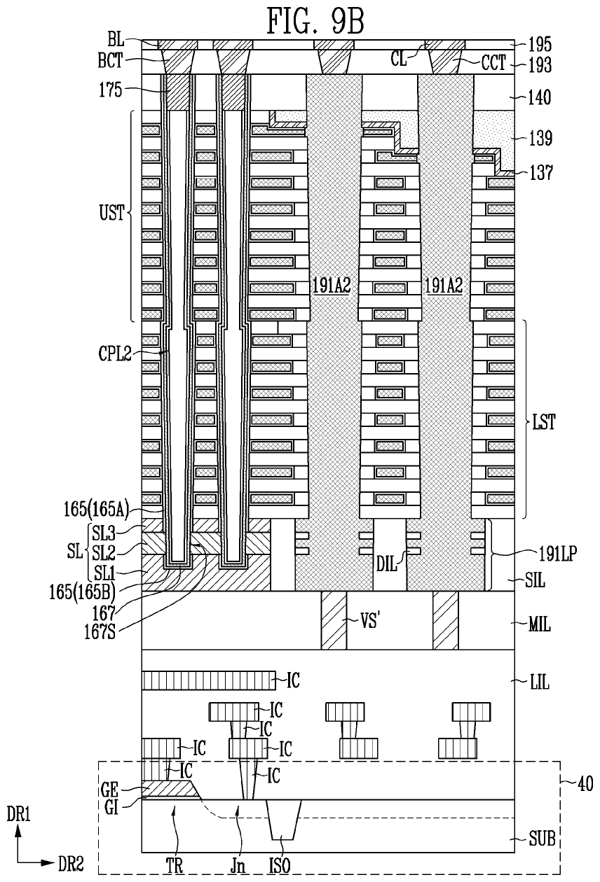

FIGS. 9A and 9B are sectional views illustrating semiconductor memory devices in accordance with various embodiments of the present disclosure.

Referring to FIGS. 9A and 9B, the structure in accordance with the embodiments described with reference to FIGS. 3A, 3B, 4A, 4B, 5, 6A to 6E, 7, and 8 may be disposed on a peripheral circuit structure 40.

The peripheral circuit structure 40 may be formed on a semiconductor substrate SUB. The peripheral circuit structure 40 may include a plurality of transistors TR. Each transistor TR may be disposed in an active region of the semiconductor substrate SUB, which is partitioned by an isolation layer ISO. The transistor TR may include a gate insulating layer GI and a gate electrode GE, which are stacked on the active region of the semiconductor substrate SUB, and junctions in formed inside portions of the active region of the semiconductor substrate SUB at both sides of the gate electrode GE. The transistor TR of the peripheral circuit structure 40 may be covered by a lower insulating structure LIL. A plurality of interconnections IC2 or IC may be buried in the lower insulating structure LIL. The plurality of interconnections IC2 or IC may be configured as a plurality of conductive patterns connected to the peripheral circuit structure 40.

A channel structure 167 of a cell plug CPL1 or CPL2 may be electrically connected to a bit line and a source layer SL.

The bit line BL may be connected to the channel structure 167 via a bit line contact BCT. The bit line contact BCT may penetrate a second horizontal insulating layer 193 disposed between a first horizontal insulating layer 140 and the bit line BL. The bit line contact BCT may penetrate the second horizontal insulating layer 193, and extend toward the bit line BL from a capping pattern 175.

The bit line BL may penetrate a third horizontal insulating layer 195. The third horizontal insulating layer 195 may extend along the second horizontal insulating layer 193. The third horizontal insulating layer 195 may be penetrated by a conductive line CL. The conductive line CL may be connected to a conductive gate contact 191A1 or 191A2 corresponding thereto via a connection contact CCT. The connection contact CCT may penetrate the second horizontal insulating layer 193, and extend toward the conductive line CL from the conductive gate contact 191A1 or 191A2.

A lower stack structure LST and an upper stack structure UST may be disposed between the bit line BL and the source layer SL. The lower stack structure LST may include a first surface. The first surface may be defined as a surface facing in the opposite direction of the first direction DR1 in which the lower stack structure LST faces the upper stack structure UST. The source layer SL may extend along the first surface of the lower stack structure LST. The source layer SL may be connected to the channel structure 167 of the cell plug CPL1 or CPL2 in various manners.

In an embodiment, as shown in FIG. 9A, the channel structure 167 may penetrate a memory layer 165, and be in contact with the source layer SL. The channel structure 167 of the cell plug CPL1 may protrude to the inside of the source layer SL.

In another embodiment, as shown in FIG. 9B, the source layer SL may be in direct contact with a sidewall 167S of the channel structure 167 by penetrating the memory layer 165 of the cell plug CPL2. In an embodiment, the source layer SL may include a first source layer SL1, a second source layer SL2, and a third source layer SL3. The third source layer SL3 may be disposed between the lower stack structure LST and the second source layer SL2. The second source layer SL2 may be disposed between the first source layer SL1 and the third source layer SL3, and surround the sidewall 167S of the channel structure 167. The memory layer 165 of the cell plug CPL2 may be isolated into a first memory pattern 165A and a second memory pattern 165B by the second source layer SL2. The first memory pattern 165A may be disposed between the channel structure 167 and each of the upper stack structure UST and the lower stack structure LST, and extend between the channel structure 167 and the third source layer SL3. The second memory pattern 165B may be disposed between the first source layer SL1 and the channel structure 167.

Referring to FIGS. 9A and 9B, a source insulating layer SIL may be disposed at a level at which the source layer SL is disposed. The conductive gate contact 191A1 or 191A2 may extend to the inside of the source insulating layer SIL.

In an embodiment, as shown in FIG. 9A, the conductive gate contact 191A1 may include a protrusion part 191PP further protruding to the inside of the source insulating layer SIL than the lower stack structure LST in the opposite direction of the first direction DR1. The protrusion part 191PP may be covered by the source insulating layer SIL. A portion of the source insulating layer SIL, which overlaps with the protrusion part 191PP, may be penetrated by a conductive via structure VS. The conductive via structure VS may be in contact with the protrusion part 191PP.

In another embodiment, as shown in FIG. 9B, the conductive gate contact 191A2 may include a lower pattern 191LP penetrating the source insulating layer SIL. A groove may be formed at a sidewall of the lower contact 191LP. The groove may be filled with a dummy insulating layer DIL.

Referring to FIGS. 9A and 9B, a cell-side structure including the lower stack structure LST, the upper stack structure UST, the cell plug CPL1 or CPL2, and the conductive gate contact 191A1 or 191A2 may be arranged over the peripheral circuit structure 40 in various manners. Components disposed between the peripheral circuit structure 40 and the cell-side structure may be variously designed.

Referring to FIG. 9A, the cell-side structure may be disposed on the peripheral circuit structure 40 such that the upper stack structure UST faces the peripheral circuit structure 40. The bit line BL, the conductive line CL, the bit line contact BCT, the connection contact CCT, the second horizontal insulating layer 193, and the third horizontal insulating layer 195 may be disposed between the first horizontal insulating layer 140 and the lower insulating structure LIL.

The cell-side structure may be coupled to the peripheral circuit structure 40 through bonding between a first conductive bonding pad PAD1 and a second bonding pad PAD2. The first conductive bonding pad PAD1 may be connected to the cell-side structure via a first interconnection IC1. In an embodiment, the first conductive bonding pad PAD1 may be connected to the bit line BL via the first interconnection IC1.

The first conductive bonding pad PAD1 may penetrate a first bonding insulating layer BIL1 disposed between the lower insulating layer LIL and the third horizontal insulating layer 195. The first interconnection IC1 may penetrate a fourth horizontal insulating layer 197 between the first bonding insulating layer BIL1 and the third horizontal insulating layer 195.

The second conductive bonding pad PAD2 may be disposed between the first bonding insulating layer BIL1 and the lower insulating layer LIL. The second conductive bonding pad PAD2 may penetrate a second bonding insulating layer BIL2. The second conductive bonding pad PAD2 may be connected to at least one of a plurality of second interconnections IC2. The plurality of second interconnections IC2 may be buried in the lower insulating layer LIL between the second bonding insulating layer BIL2 and the peripheral circuit structure 40.

The first bonding insulating layer BIL1 and the second bonding insulating layer BIL2 may be bonded to each other.

Referring to FIG. 9B, the cell-side structure may be disposed on the peripheral circuit structure 40 such that the lower stack structure LST faces the peripheral circuit structure 40. The first horizontal insulating layer 140, the second horizontal insulating layer 193, and the third horizontal insulating layer 195 may be disposed over a top surface of the upper stack structure UST. The top surface of the upper stack structure UST may be a surface of the upper stack structure UST, which faces in the opposite direction (e.g., the first direction DR1) of a direction in which the upper stack structure UST faces the peripheral circuit structure 40.

A plurality of interconnections IC connected to the peripheral circuit structure 40 may be buried in the lower insulating structure LIL between the lower stack structure LST and the peripheral circuit structure 40. A middle insulating layer MIL may be disposed between the lower insulating structure LIL and the source layer SL. The middle insulating layer MIL may extend between the lower insulating layer LIL and the source insulating layer SIL. The conductive gate contact 191A2 may be connected to a conductive via structure VS' penetrating the middle insulating layer MIL.

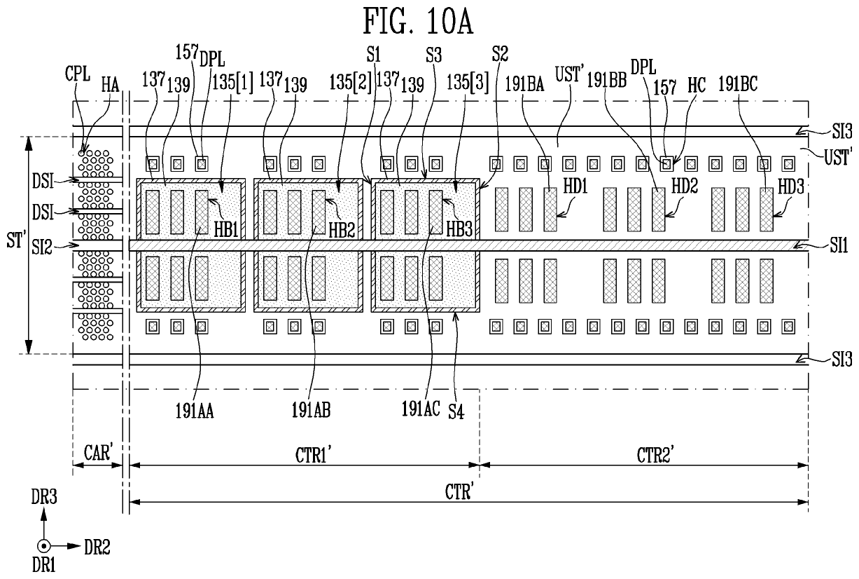

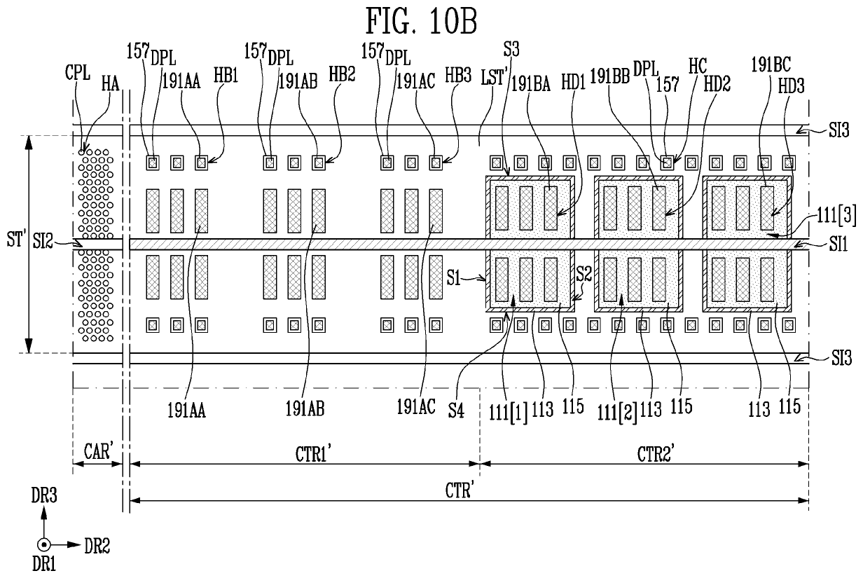

FIGS. 10A and 10B are plan views illustrating a portion of a semiconductor memory device in accordance with an embodiment of the present disclosure. A structure shown in FIG. 10A may overlap with a structure shown in FIG. 10B in the first direction DR1. Hereinafter, overlapping descriptions of components identical to those shown in FIGS. 3A and 3B will be omitted.

Referring to FIGS. 10A and 10B, a stack structure ST′ of the semiconductor memory device may be penetrated by a first slit SI1 and a second slit SI2, and be adjacent to another stack structure by using a third slit SI3 as a boundary. A drain select isolation structure DSI drain lines may be disposed between the second slit SI2 and the third slit SI3. The stack structure ST′ may include an upper stack structure UST′ shown in FIG. 10A and a lower stack structure LST′ shown in FIG. 10B.

The stack structure ST′ may include a cell array region CAR′ and a contact region CTR′ extending from the cell array region CAR′. Each of the upper stack structure UST′ and the lower stack structure LST′ in the cell array region CAR′ may be penetrated by a channel hole HA extending in the first direction DR1. A cell plug CPL may be disposed inside the channel hole HA.

The contact region CTR′ may be divided into a plurality of first contact region CTR1′ occupied by first conductive gate contacts 191AA, 191AB, and 191AC and a second contact region CTR2′ occupied by a plurality of second conductive gate contacts 191BA, 191BB, and 191BC.

The plurality of first conductive gate contacts 191AA, 191AB, and 191AC may be provided to supply an electrical signal to the upper stack structure UST, and be divided into a plurality of groups. In an embodiment, the plurality of first conductive gate contacts 191AA, 191AB, and 191AC may include a first conductive gate contact 191AA of a first group, a first conductive gate contact 191AB of a second group, and a first conductive gate contact 191AC of a third group.

The plurality of second conductive gate contacts 191BA, 191BB, and 191BC may be provided to supply an electrical signal to the lower stack structure LST, and be divided into a plurality of groups. In an embodiment, the plurality of second conductive gate contacts 191BA, 191BB, and 191BC may include a second conductive gate contact 191BA of a first group, a second conductive gate contact 191BB of a second group, and a second conductive gate contact 191BC of a third group.

Referring to FIG. 10B, a plurality of first stepped grooves 111[1], 111[2], and 111[3] may be spaced apart from each other inside the lower stack structure LST′ in the second contact region CTR2′. The second conductive gate contact 191BA of the first group, the second conductive gate contact 191BB of the second group, and the second conductive gate contact 191BC of the third group may be respectively disposed inside the plurality of first stepped grooves 111[1], 111[2], and 111[3]. For example, the plurality of first stepped grooves 111[1], 111[2], and 111[3] may include a first stepped groove 111[1] of a first type, a first stepped groove 111[2] of a second type, and a first stepped groove 111[3] of a third type. The second conductive gate contact 191BA of the first group may be disposed inside the first stepped groove 111[1] of the first type, the second conductive gate contact 191BB of the second group may be disposed inside the first stepped groove 111[2] of the second type, and the second conductive gate contact 191BC of the third group may be disposed inside the first stepped groove 111[3] of the third type.

A first filling insulating layer 115 may be disposed inside each of the plurality of first stepped grooves 111[1], 111[2], and 111[3]. A first barrier insulating layer 113 may be disposed between the first filling insulating layer 115 and the lower stack structure LST′.

Referring to FIG. 10A, a plurality of second stepped grooves 135[1], 135[2], and 135[3] may be spaced apart from each other inside the upper stack structure UST′ in the first contact region CTR1′. The first conductive gate contact 191AA of the first group, the first conductive gate contact 191AB of the second group, and the first conductive gate contact 191AC of the third group may be respectively disposed inside the plurality of second stepped grooves 135[1], 135[2], and 135[3]. For example, the plurality of second stepped grooves 135[1], 135[2], and 135[3] may include a second stepped groove 135[1] of a first type, a second stepped groove 135[2] of a second type, and a second stepped groove 135[3] of a third type. The first conductive gate contact 191AA of the first group may be disposed inside the second stepped groove 135[1] of the first type, the first conductive gate contact 191AB of the second group may be disposed inside the second stepped groove 135[2] of the second type, and the first conductive gate contact 191AC of the third group may be disposed inside the second stepped groove 135[3] of the third type.

A second filling insulating layer 139 may be disposed inside each of the plurality of second stepped grooves 135[1], 135[2], and 135[3]. A second barrier insulating layer 137 may be disposed between the second filling insulating layer 139 and the upper stack structure UST′.

Referring to FIGS. 10A and 10B, the plurality of first conductive gate contacts 191AA, 191AB, and 191AC may be respectively disposed inside a plurality of first contact holes HB1, HB2, and HB3. In an embodiment, the plurality of first contact holes HB1, HB2, and HB3 may include a first contact hole HB1 of a first group, a first contact hole HB2 of a second group, and a first contact hole HB3 of a third group. The first conductive gate contact 191AA of the first group may be disposed inside the first contact hole HB1 of the first group, the first conductive gate contact 191AB of the second group may be disposed inside the first contact hole HB2 of the second group, and the first conductive gate contact 191AC of the third group may be disposed inside the first contact hole HB3 of the third group. The plurality of first contact holes HB1, HB2, and HB3 may extend in the first direction DR1 to penetrate the second filling insulating layer 139 and the lower stack structure LST′.

The plurality of second conductive gate contacts 191BA, 191BB, and 191BC may be respectively disposed inside a plurality of second contact holes HD1, HD2, and HD3. In an embodiment, the plurality of second contact holes HD1, HD2, and HD3 may include a second contact hole HD1 of a first group, a second contact hole HD2 of a second group, and a third contact hole HD3 of a third group. The second conductive gate contact 191BA of the first group may be disposed inside the second contact hole HD1 of the first group, the second conductive gate contact 191BB of the second group may be disposed inside the second contact hole HD2 of the second group, and the second conductive gate contact 191BC of the third group may be disposed inside the second contact hole HD3 of the third group. The plurality of second contact holes HD1, HD2, and HD3 may extend in the first direction DR1 to penetrate the upper stack structure UST′ and the first filling insulating layer 115.

The upper stack structure UST′ and the lower stack structure LST′ in the contact region CTR′ may be penetrated by a plurality of dummy holes HC. A dummy plug DPL may be disposed inside each dummy hole HC. The dummy plug DPL may be surrounded by an insulating layer 157. The insulating layer 157 may extend along a sidewall of the dummy hole HC.

Each of the plurality of first stepped grooves 111[1], 111[2], and 111[3] and each of the plurality of second stepped grooves 135[1], 135[2], and 135[3] may include a first sidewall S1, a second sidewall S2, a third sidewall S3, and a fourth sidewall S4. The first sidewall S1 may be defined as a sidewall adjacent to the cell plug CPL, and the second sidewall S2 may be defined as sidewall facing the first sidewall S1. The third sidewall S3 and the fourth sidewall S4 may be defined as sidewalls which are disposed between the first sidewall S1 and the second sidewall S2 and face each other. The first sidewall S1 may have a stepped structure penetrated by a contact hole corresponding thereto among the plurality of first contact holes HB1, HB2, and HB3 and the plurality of second contact holes HD1, HD2, and HD3. In other words, the first sidewall S1 may have a stepped structure penetrated by a conductive gate contact corresponding thereto among the plurality of first conductive gate contacts 191AA, 191AB, and 191AC and the plurality of second conductive gate contacts 191BA, 191BB, and 191BC.

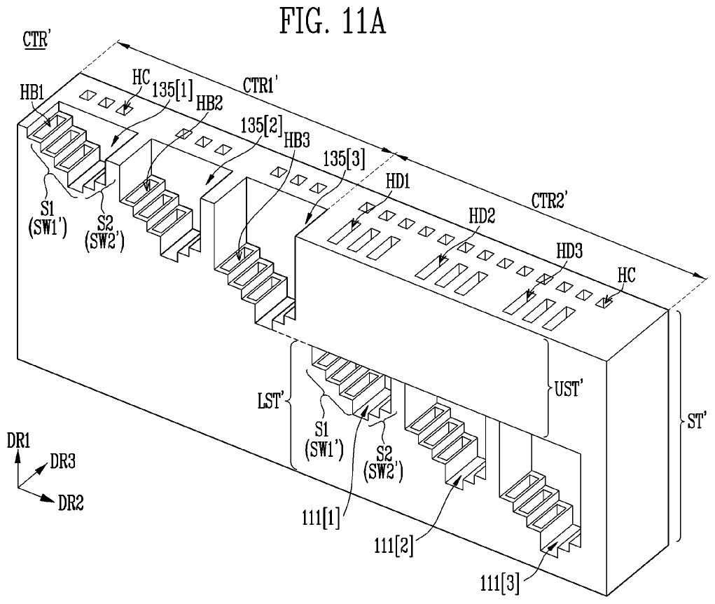

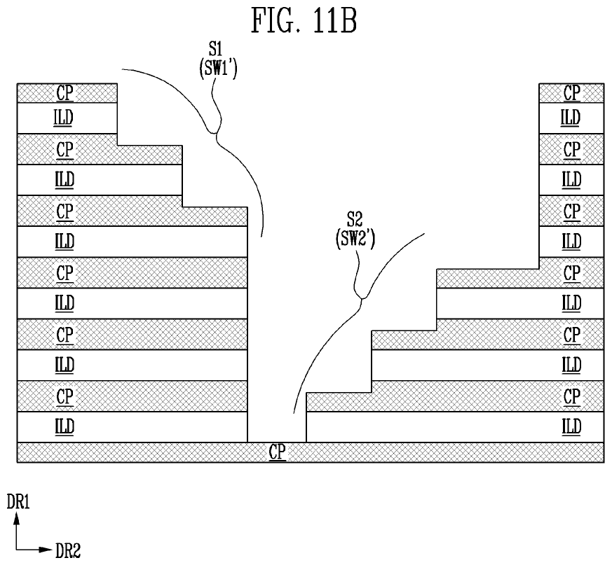

FIGS. 11A and 11B are views illustrating the first sidewall S1 and the second sidewall S2, which are shown in FIGS. 10A and 10B. FIG. 11A is a perspective view schematically illustrating the contact region CTR′ of the stack structure ST′ shown in FIGS. 10A and 10B, and FIG. 11B is a sectional view of a first stepped structure SW1′ and a second stepped structure SW2′, which are shown in FIG. 11A.

Referring to FIG. 11A, the lower stack structure LST′ may continuously extend toward the second contact region CTR2′ from the first contact region CTR1′ of the contact region CTR′. The plurality of first stepped grooves 111[1], 111[2], and 111[3] may be disposed inside the lower stack structure LST′ to have different depths in the second contact region CTR2′.

The upper stack structure UST′ may continuously extend toward the second contact region CTR2′ from the first contact region CTR1′ of the contact region CTR′. The upper stack structure UST′ may overlap with the plurality of first stepped grooves 111[1], 111[2], and 111[3] in the second contact region CTR2′. The plurality of second stepped grooves 135[1], 135[2], and 135[3] may be disposed inside the upper stack structure UST′ to have different depths in the first contact region CTR1′.

The lower stack structure LST′ and the upper stack structure UST′ in the contact region CTR′ may be penetrated by the plurality of first contact holes HB1, HB2, and HB3, the plurality of dummy holes HC, and the plurality of second contact holes HD1, HD2, and HD3. Each of the plurality of first contact holes HB1, HB2, and HB3 and the plurality of second contact holes HD1, HD2, and HD3 may penetrate a first stepped structure SW1′ of a first sidewall S1 corresponding thereto.

The second sidewall S2 of each of the plurality of first stepped grooves 111[1], 111[2], and 111[3] and the plurality of second stepped grooves 135[1], 135[2], and 135[3] may have a second stepped structure SW2′.

Referring to FIG. 11B, each of the plurality of first stepped grooves 111[1], 111[2], and 111[3] and the plurality of second stepped grooves 135[1], 135[2], and 135[3], which are shown in FIG. 11A, may be defined inside a plurality of conductive patterns CP and a plurality of interlayer insulating layers ILD. The second stepped structure SW2′ may be formed in a structure asymmetrical to the first stepped structure SW1′. In an embodiment, the first sidewall S1 defined along the first stepped structure SW1′ may be disposed at a level high in the first direction DR1 as compared with the second sidewall S2 defined along the second stepped structure SW2′. However, the embodiment of the present disclosure is not limited thereto. For example, the second stepped structure SW2′ may be symmetrical to the first stepped structure SW1, and be disposed at the substantially same level as the first stepped structure SW1′. Although FIGS. 10A and 11A are illustrated based on an embodiment in which the first stepped structure SW1′ is penetrated by a conductive gate contact, the embodiment of the present disclosure is not limited thereto. For example, the semiconductor memory device may further include a conductive gate contact penetrating the second stepped structure SW2′.

Although the above-described embodiments have been described based on the semiconductor memory device including a double stack structure of the upper stack structure UST and the lower stack structure LST, the embodiment of the present disclosure is not limited thereto. For example, the semiconductor memory device may include a single stack structure or triple or more stack structures.

Hereinafter, a manufacturing method of a semiconductor memory device in accordance with an embodiment of the present disclosure will be described. Overlapping descriptions of components identical to those shown in FIGS. 3A, 3B, 4A, 4B, 5, and 6A to 6E will be omitted.

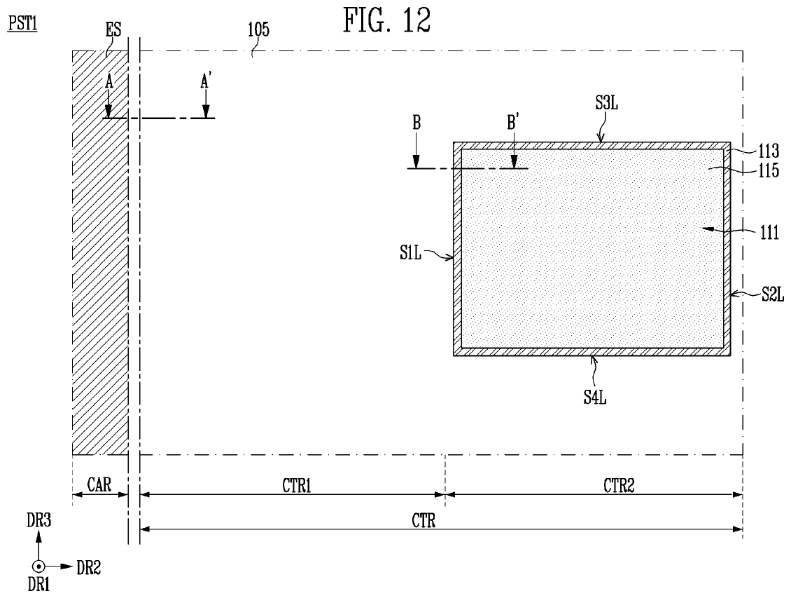

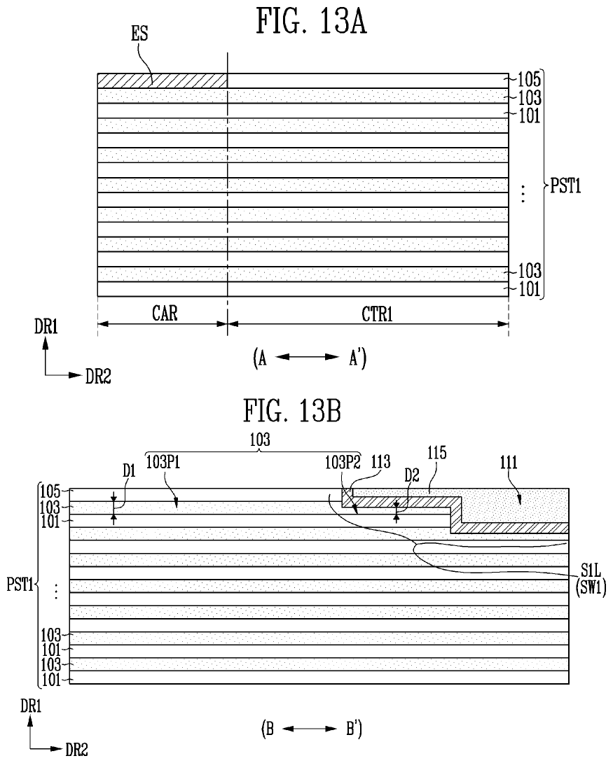

FIGS. 12, 13A, and 13B are views illustrating processes of forming a first stepped groove, a first barrier insulating layer, and a first filling insulating layer. FIG. 12 is a plan view illustrating a first preliminary stack structure PST1. FIG. 13A is a sectional view taken along line A-A′ shown in FIG. 12, and FIG. 13B is a sectional view taken along line B-B′ shown in FIG. 12.

Referring to FIGS. 12, 13A, and 13B, a first stepped groove 111 may be formed inside the first preliminary stack structure PST1. The first preliminary stack structure PST1 may include a plurality of lower first material layers and a plurality of lower second material layers 103, which are alternately stacked in the first direction DR1. In an embodiment, the lower first material layers may form a first interlayer insulating layer 101 and a first interposition insulating layer 105. Each lower second material layer 103 may be formed of a material having an etch selectivity with respect to the first interlayer insulating layer 101 and the first interposition insulating layer 105.

In an embodiment, by considering an etch selectivity, the lower first material layers for the first interlayer insulating layer 101 and the first interposition insulating layer 105 may include a high content of oxygen as compared with the lower second material layer 103. In an embodiment, by considering an etch selectivity, the lower second material layer 103 may include a high content of nitrogen or silicon as compared with the lower first material layers. In an embodiment, the lower first material layer may be formed of silicon oxide, and the lower second material layer 103 may be formed of silicon nitride. In another embodiment, the lower first material layer may be formed of silicon oxide, and the lower second material layer 103 may be formed of silicon such as doped silicon or undoped silicon.

The first preliminary stack structure PST1 may include a cell array region CAR and a contact region CTR extending from the cell array region CAR. In an embodiment, the contact region CTR may include a first contact region CTR1 extending from the cell array region CAR and a second contact region CTR2 extending from the first contact region CTR1.

The first interposition insulating layer 105 may be disposed at the substantially same level as an etch stop layer ES. In an embodiment, the etch stop layer ES may overlap with the cell array region CAR of the first preliminary stack structure PST1, and the first interposition insulating layer 105 may form an uppermost layer of the first preliminary stack structure PST1 in the contact region CTR of the first preliminary stack structure PST1.

The etch stop layer ES may be formed of a material having an etch selectivity with respect to the plurality of lower first material layers and the plurality of lower second material layers 103. In an embodiment, the etch stop layer ES may be formed of poly-silicon. Hereinafter, although the manufacturing method is described based on an embodiment in which the first interposition insulating layer 105 and the etch stop layer ES are disposed at the substantially same level, the embodiment of the present disclosure is not limited thereto. For example, the etch stop layer ES may be excluded, and the first interposition insulating layer 105 may extend to the contact region CTR from the cell array region CAR.

The first stepped groove 111 may be formed by etching the second contact region CTR2 of the first preliminary stack structure PST1. The first stepped groove 111 may include a lower first sidewall S1L, a lower second sidewall S2L, a lower third sidewall S3L, and a lower fourth sidewall S4L. The lower first sidewall S1L and the lower second sidewall S2L may be defined as sidewalls facing each other. The lower third sidewall S3L and the lower fourth sidewall S4L may be defined as sidewalls which are disposed between the lower first sidewall S1L and the lower second sidewall S2L and face each other.

A process of forming the first stepped groove 111 may be performed such that a first stepped structure SW1 is formed at the lower first sidewall S1L. The process of forming the first stepped groove 111 may include a process of repeatedly performing an etching process of the first preliminary stack structure PST1, using a photoresist pattern (not shown) as an etch barrier and a process of reducing the size of the photoresist pattern until the first stepped structure SW1 is formed. While the first preliminary stack structure PST1 is etched, at least one of the lower second sidewall S2L, the lower third sidewall S3L, and the lower fourth sidewall S4L may be protected by a mask pattern (not shown). A sidewall of a region protected by the mask pattern may extend in a substantially straight type. In an embodiment, the lower third sidewall S3L and the lower fourth sidewall S4L may be formed in a straight type extending along the first direction DR1. A region opened by the mask pattern and the photoresist pattern is controlled, so that a stepped structure symmetrical to the first stepped structure SW1 may be formed at the lower second sidewall S2L. However, the present disclosure is not limited thereto, and the shape of the lower second sidewall S2L may be variously changed by controlling the area opened by the mask pattern and the photoresist pattern.

The etching process of the first preliminary stack structure PST1, using the photoresist pattern and the mask pattern, which are described above, as an etch barrier may be variously designed according to the shape of a stepped groove as a target. For example, the etching process of the first preliminary stack structure PST1, using the photoresist pattern and the mask pattern as the etch barrier, may be designed to fit the shapes of the plurality of first stepped grooves 111[1], 111[2], and 111[3] shown in FIGS. 10B, 11A, and 11B.

A portion of each of the plurality of lower second material layers 103 may be exposed by the first stepped groove 111 through the etching process of the first preliminary stack structure PST1. The portion of each of the plurality of lower second material layers 103, which is exposed by the first stepped groove 111, may have a thickness different from a thickness of the other portion. In an embodiment, the plurality of lower second material layers 103 may include a plurality of first parts 103P1 in the cell array region CAR of the first preliminary stack structure PST1 and a plurality of second part 103P2 respectively extending from the plurality of first parts 103P1 to form the first stepped structure SW1. Each first part 103P1 may be defined as a part disposed between lower first material layers which are spaced apart from each other in the first direction DR1 to be adjacent to each other, and each second part 103P2 may be defined as a part exposed by the first stepped groove 111. A thickness D2 of the second part 103P2 may be different from a thickness D1 of the first part 103P1. In an embodiment, the thickness D2 of the second part 103P2 may be smaller than the thickness D1 of the first part 103P1. However, the embodiment of the present disclosure is not limited thereto. In an embodiment, a pad layer formed of the same material as the lower second material layer may be additionally deposited on the second part 103P2. A total thickness of the lower second material layer 103 and the pad layer, which are disposed in a region exposed by the first stepped groove 111, may be greater than the thickness D1 of the first part 103P1.

Subsequently, a first barrier insulating layer 113 may be formed, which continuously extends along the lower first sidewall S1L, the lower second sidewall 52L, the lower third sidewall 53L, and the lower fourth sidewall S4L of the first stepped groove 111. The first barrier insulating layer 113 may include the same element as a lower first material layer for the plurality of first interlayer insulating layers 101 and the first interposition insulating layer 105. In an embodiment, the first barrier insulating layer 113 may include oxygen. In an embodiment, the first barrier insulating layer 113 may be formed of the same silicon oxide as the lower first material layer.

Subsequently, a first filling insulating layer 115 may be formed inside the first stepped groove 111. The first filling insulating layer 115 may be disposed on the first barrier insulating layer 113. The first filling insulating layer 115 may include the same element as the lower second material layer 103. In an embodiment, the first filling insulating layer 115 may include a high content of nitrogen or silicon as compared with the lower first material layer for each of the first interlayer insulating layer 101 and the first interposition insulating layer 105 and the first barrier insulating layer 113. The property of the first filling insulating layer 115 may be controlled such that a content of oxygen in the lower first material layer and the first barrier insulating layer 113 is higher than a content of oxygen in the first filling insulating layer 115. In an embodiment, the first filling insulating layer 115 may be formed of a SiOₓN_{y} (x=0 or x<y) or a SiₓO_{y} (x>y). In an embodiment, the first filling insulating layer 115 and the lower second material layer 102 may be formed of the same silicon nitride. In another embodiment, a content of nitrogen in the first filling insulating layer 115 may be different from a content of nitrogen in the lower second material layer 103. In still another embodiment, the lower second material layer 103 may be formed of silicon, and the first filling insulating layer 115 may be formed of silicon rich oxide.

Subsequently, a portion of each of the first filling insulating layer 115 and the first barrier insulating layer 113, which are formed in the cell array region CAR, may be removed such that the first filling insulating layer 115 and the first barrier insulating layer 113 remain inside the first stepped groove 111. In addition, surfaces of the first filling insulating layer 115 and the first barrier insulating layer 113 may be planarized through chemical mechanical polishing (CMP) or the like such that the etch stop layer ES is exposed.

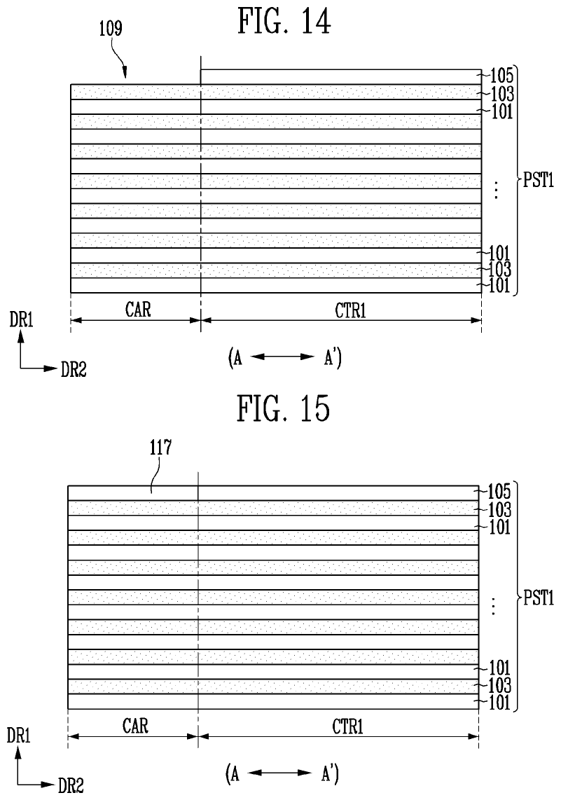

FIGS. 14 and 15 are sectional views illustrating a process of replacing the etch stop layer shown in FIG. 12 with a second interposition insulating layer. FIGS. 14 and 15 illustrate, for example, subsequent processes with respect to the region shown in FIG. 13A.

Referring to FIG. 14, a groove 109 may be defined at a surface of the first preliminary stack structure PST1 by removing the etch stop layer ES shown in FIG. 12.

Referring to FIG. 15, the groove 109 shown in FIG. 14 may be filled with a second interposition insulating layer 117. The second interposition insulating layer 117 may be formed of the same material as the lower first insulating layer for each of the first interlayer insulating layer 101 and the first interposition insulating layer 105.

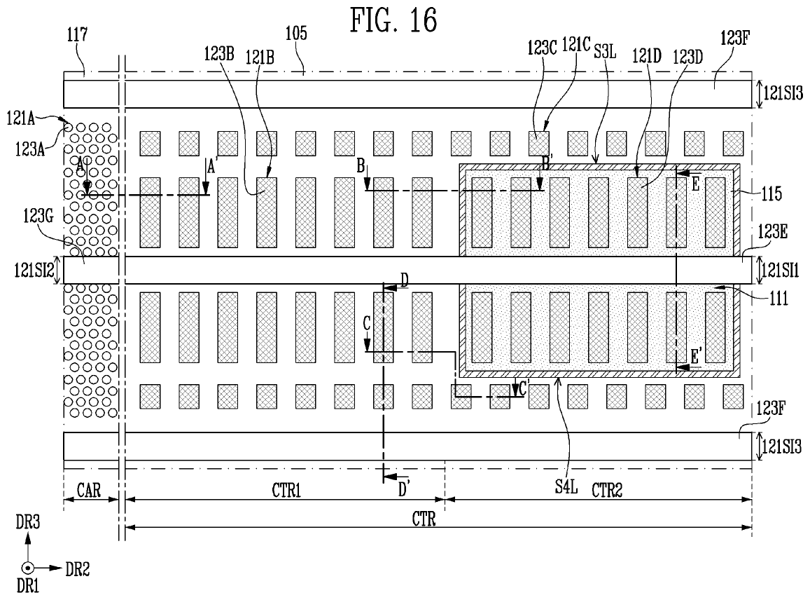

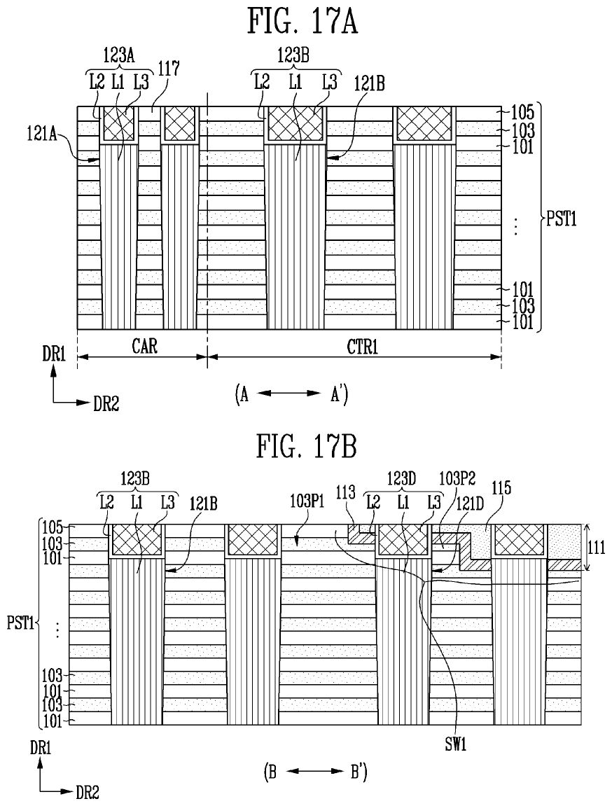

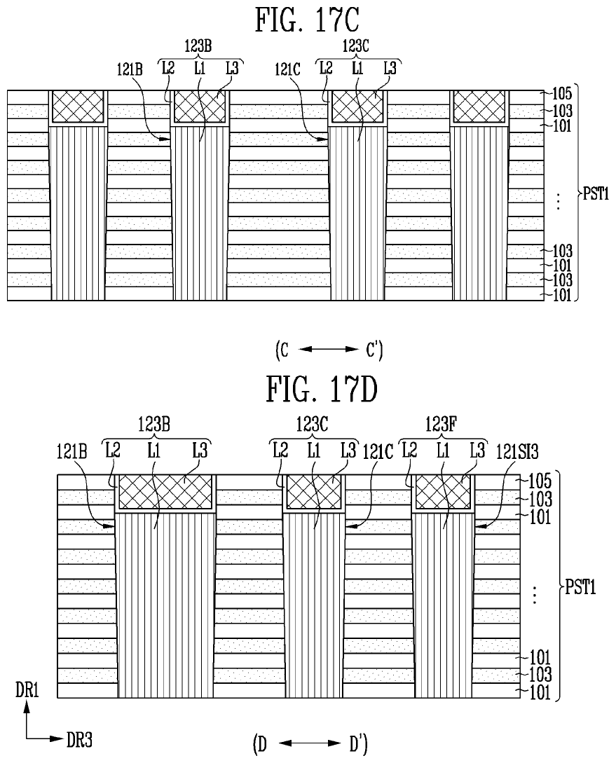

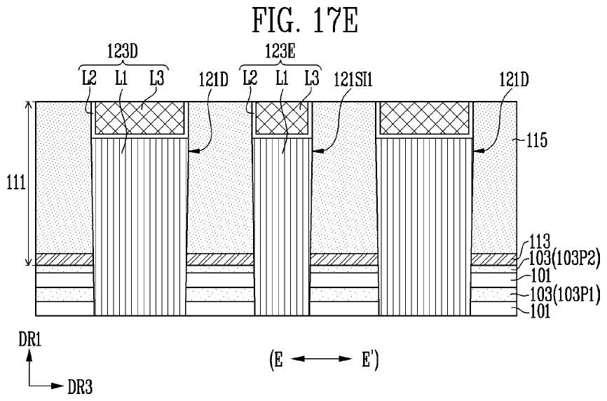

FIGS. 16, 17A, 17B, 17C, 17D, and 17E are views illustrating a process of forming lower sacrificial structures. FIG. 17A illustrates a section of the first preliminary stack structure PST1 taken along line A-A′ shown in FIG. 16. FIG. 17B illustrates a section of the first preliminary stack structure PST1 taken along line B-B′ shown in FIG. 16. FIG. 17C illustrates a section of the first preliminary stack structure PST1 taken along line C-C′ shown in FIG. 16. FIG. 17D illustrates a section of the first preliminary stack structure PST1 taken along line D-D′ shown in FIG. 16. FIG. 17E illustrates a section of the first preliminary stack structure PST1 taken along line E-E′ shown in FIG. 16.

Referring to FIGS. 16 and 17A to 17E, the plurality of lower first material layers and the plurality of lower second material layers 103 may be etched. In other words, the first interlayer insulating layer 101, the first interposition insulating layer 105, the second interposition insulating layer 117 and the plurality of lower second material layers 103 may be etched. The first filling insulating layer 115 and the first barrier insulating layer 113 may be etched by an etching material for etching the lower first material layer and the lower second material layer 103.

A lower channel hole 121A, a first lower contact hole 121B, a lower dummy hole 171C, a second lower contact hole 121D, a first lower slit 121S11, a second lower slit 121S12, and a third lower slit 121S13 may be formed through the above-described etching process.

The first lower slit 121S11 may be formed across the first stepped groove 111. The first lower slit 121S11 may penetrate the first filling insulating layer 115 and the first barrier insulating layer 113, and a portion of the first preliminary stack structure PST1, which overlaps therewith. The first lower slit 121S11 may extend to the first contact region CTR1 of the first preliminary stack structure PST1.

The second lower slit 121S12 may penetrate the cell array region CAR of the first preliminary stack structure PST1. Although not shown in the drawings, the first lower slit 121S11 and the second lower slit 121S12 may be connected to each other in a connection region between the cell array region CAR and the contact region CTR.

The third lower slit 121S13 may penetrate the second contact region CTR2 of the preliminary stack structure ST1 to face each of the lower third sidewall S3L and the lower fourth sidewall S4L of the first stepped groove 111. The third lower slit 121S13 may extend to penetrate the cell array area CAR of the first preliminary stack structure PST1. The third lower slit 121S13 may be spaced apart from the first stepped groove 111.

The lower channel hole 121A may be disposed between the second lower slit 121S12 and the third lower slit 121S13. The lower channel hole 121A may penetrate the cell array region CAR of the first preliminary stack structure PST1. The lower channel hole 121A may penetrate the first part 103P1 of each of the plurality of lower second material layers 103.

The first lower contact hole 121B may penetrate the first contact region CTR1 of the first preliminary stack structure PST1. The first lower contact hole 121B may penetrate the first part 103P1 of each of the plurality of lower second material layers 103.

The lower dummy hole 121C may be disposed at the outside of the first stepped groove 111. The lower dummy hole 121C may penetrate the first contact region CTR1 and the second contact region CTR2 of the first preliminary stack structure PST1, which are adjacent to the third lower slit 121S13. The lower dummy hole 121C may penetrate the first part 103P1 of each of the plurality of lower second material layers 103.

The second lower contact hole 121D may penetrate the first filling insulating layer 115, the first barrier insulating layer 113, and the first stepped structure SW1 of the first preliminary stack structure PST1. The second lower contact hole 121D may penetrate the second part 103P2 of the lower second material layer 103 constituting the first stepped structure SW1.

From a planar viewpoint, an area of each of the first lower contact hole 121B, the lower dummy hole 121C, and the second lower contact hole 121D may be formed wider than an area of the lower channel hole 121A. From a planar viewpoint, the first lower contact hole 121B, the lower dummy hole 121C, and the second lower contact hole 121D may have different areas or have the same area.

In accordance with an embodiment of the present disclosure, the first barrier insulating layer 113 inside the first stepped groove 111 may include the same element (e.g., oxygen) as the lower first material layer for each of the first interlayer insulating layer 101, the first interposition insulating layer 105, and the second interposition insulating layer 117. The first filling insulating layer 115 may include the same element (e.g., nitrogen) as the lower second material layer 103. Accordingly, a difference between an etching amount at the outside of the first stepped groove 111 and an etching amount inside the first stepped groove 111 may be decreased, and thus a process defect due to the difference between the etching amount at the outside of the first stepped groove 111 and the etching amount inside the first stepped groove 111 may be reduced.

Subsequently, a plurality of lower sacrificial structures 123A, 123B, 123C, 123D, 123E, 123F, and 123G may be formed inside the lower channel hole 121A, the first lower contact hole 121B, the lower dummy hole 121C, the second lower contact hole 121D, the first lower slit 121S11, the second lower slit 121S12, and the third lower slit 121S13. Each of the plurality of lower sacrificial structures 123A, 123B, 123C, 123D, 123E, 123F, and 123G may be formed of various materials. In an embodiment, each of the plurality of lower sacrificial structures 123A, 123B, 123C, 123D, 123E, 123F, and 123G may include an amorphous carbon layer L1, a titanium nitride layer L2, and a tungsten layer L3.

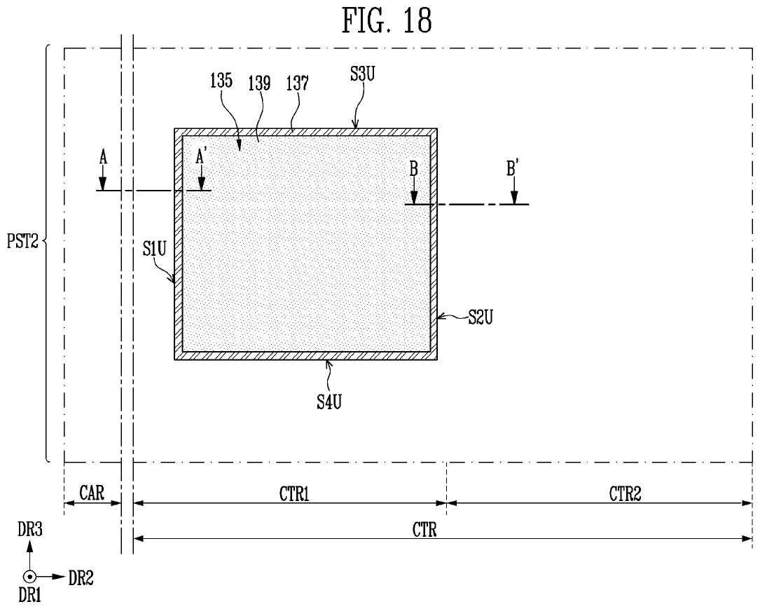

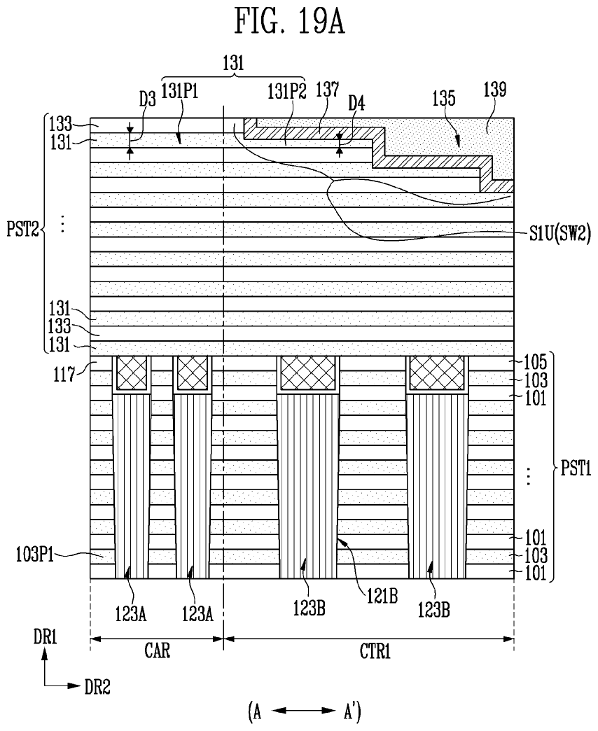

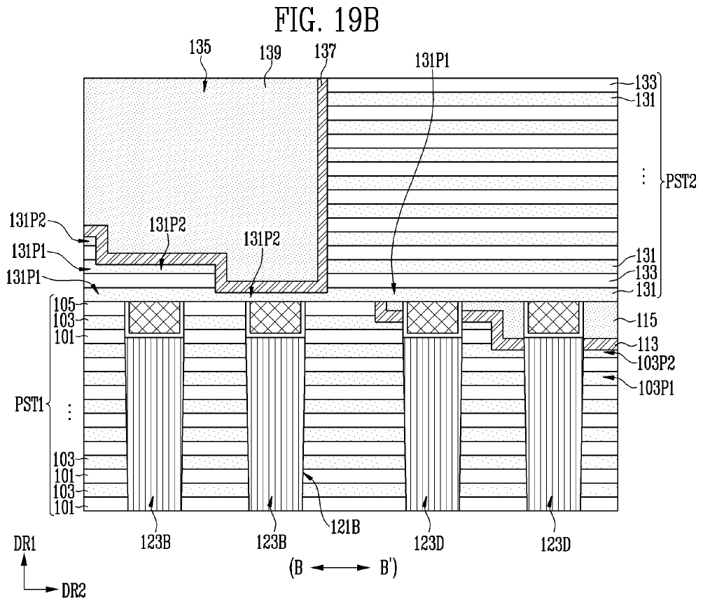

FIGS. 18, 19A, and 19B are views illustrating processes of forming a second stepped groove, a second barrier insulating layer, and a second filling insulating layer. FIG. 18 is a plan view illustrating a second preliminary stack structure PST2. FIG. 19A is a sectional view taken along line A-A′ shown in FIG. 18, and FIG. 19B is a sectional view taken along line B-B′ shown in FIG. 18.

Referring to FIGS. 18, 19A, and 19B, a second stepped groove 135 may be formed inside the second preliminary stack structure PST2. The second preliminary stack structure PST2 may include a plurality of upper first material layers and a plurality of upper second material layers 131, which are alternately stacked in the first direction DR1. In an embodiment, each upper first material layer may be formed of an insulating material for a second interlayer insulating layer 133, and each upper second material layer 131 may be formed of a material having an etch selectivity with respect to the second interlayer insulating layer 133. The upper first material layer may be formed of the same material as the lower first material layer described with reference to FIGS. 12, 13A, and 13B. The upper second material layer 131 may be formed of the same material as the lower second material layer 103 described with reference to FIGS. 12, 13A, and 13B.

Like the first preliminary stack structure PST1, the second preliminary stack structure PST2 may include a cell array region CAR and a contact region CTR. Like the first preliminary stack structure PST1, the contact region CTR of the second preliminary stack structure PST2 may include a first contact region CTR1 and a second contact region CTR2.

The second stepped groove 135 may be formed by etching the first contact region CTR1 of the second preliminary stack structure PST2. The second stepped groove 135 may include an upper first sidewall S1U, an upper second sidewall S2U, an upper third sidewall S3U, and an upper fourth sidewall S4U. The upper first sidewall S1U and the upper second sidewall S2U may be defined as sidewalls facing each other. The upper third sidewall S3U and the upper fourth sidewall S4U may be defined as sidewalls which are disposed between the upper first sidewall S1U and the upper second sidewall S2U and face each other.

A process of forming the second stepped groove 135 may be performed such that a second stepped structure SW2 is formed at the upper first sidewall S1U. Like the process of forming the first stepped groove 111, which is described with reference to FIGS. 12, 13A, and 13B, the process of forming the second stepped groove 135 may include a process of repeatedly performing an etching process of the second preliminary stack structure PST2, using a photoresist pattern (not shown) and a mask pattern (not shown) as an etch barrier and a process of reducing the size of the photoresist pattern until the second stepped structure SW2 is formed.

A portion of each of the plurality of upper second material layers 131 may be exposed by the second stepped groove 135 formed through the etching process of the second preliminary stack structure PST2. The portion of each of the plurality of upper second material layers 131, which is exposed by the second stepped groove 135, may have a thickness different from a thickness of the other portion. In an embodiment, the plurality of upper second material layers 131 may include a plurality of first parts 131P1 in the cell array region CAR of the second preliminary stack structure PST2 and second parts 131P2 respectively extending from the plurality of first parts 131P1 to form the second stepped structure SW2. Each first part 131P1 may be defined as a part maintaining a thickness between layers which are spaced apart from each other in the first direction DR1 to be adjacent to each other. Each second part 131P2 may be defined as a part exposed by the second stepped groove 135. A thickness D4 of the second part 131P2 may be different from a thickness D3 of the first part 131P1. However, the embodiment of the present disclosure is not limited thereto. In an embodiment, a pad layer formed of the same material as the upper second material layer 131 may be additionally deposited on the second part 131P2. A total thickness of the upper second material 131 and the pad layer, which are disposed in a region exposed by the second stepped groove 135, may be greater than the thickness D3 of the first part 131P1.

The first part 131P1 of the upper second material layer 131 may be formed to have the substantially same thickness as the first part 103P1 of the lower second material layer 103, and the second part 131P2 of the upper second material layer 131 may be formed to have the substantially same thickness as the second part 103P2 of the lower second material layer 103. The second part 131P2 of the upper second material layer 131 may overlap with a lower sacrificial structure 123B inside the first lower contact hole 121B among the plurality of lower sacrificial structures 123A, 123B, 123C, 123D, 123E, 123F, and 123G.

Subsequently, a second barrier insulating layer 137 may be formed, which continuously extends along the upper first sidewall S1U, the upper second sidewall S2U, the upper third sidewall S3U, and the upper fourth sidewall S4U of the second stepped groove 135. The second barrier insulating layer 137 may include the same element as the upper first material layer constituting the second interlayer insulating layer 133. In an embodiment, the second barrier insulating layer 137 may include oxygen. In an embodiment, the second barrier insulating layer 137 may be formed of the same silicon oxide as the upper first material layer.

Subsequently, a second filling insulating layer 139 may be formed inside the second stepped groove 135. The second filling insulating layer 139 may be disposed on the second barrier insulating layer 137. The second filling insulating layer 139 may include the same element as the upper second material layer 131. In an embodiment, the second filling insulating layer 139 may include a high content of nitrogen or silicon as compared with the upper first material layer for the second interlayer insulating layer 133 and the second barrier insulating layer 137. The property of the second filling insulating layer 139 may be controlled such that a content of oxygen in the upper first material layer and the second barrier insulating layer 137 is higher than a content of oxygen in the second filling insulating layer 139. In an embodiment, the second filling insulating layer 139 may be formed of a SiOₓN_{y} (x=0 or x<y) or a SiₓO_{y} (x>y). In an embodiment, the second filling insulating layer 139 and the upper second material layer 131 may be formed of the same silicon nitride. In another embodiment, a content of nitrogen in the second filling insulating layer 139 may be different from a content of nitrogen in the upper second material layer 131. In still another embodiment, the upper second material layer 131 may be formed of silicon, and the second filling insulating layer 139 may be formed of silicon rich oxide. The second filling insulating layer 139 and the second barrier insulating layer 137 may be removed at the outside of the second stepped groove 135.

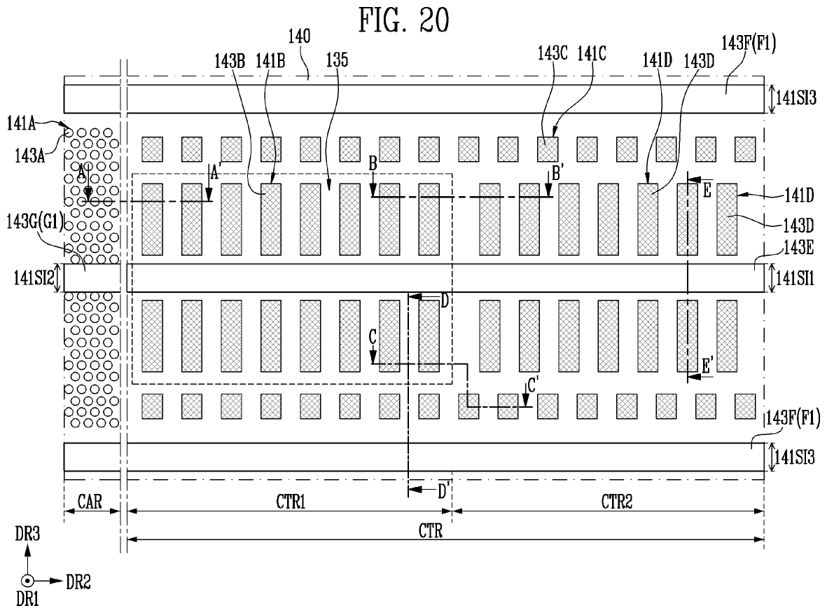

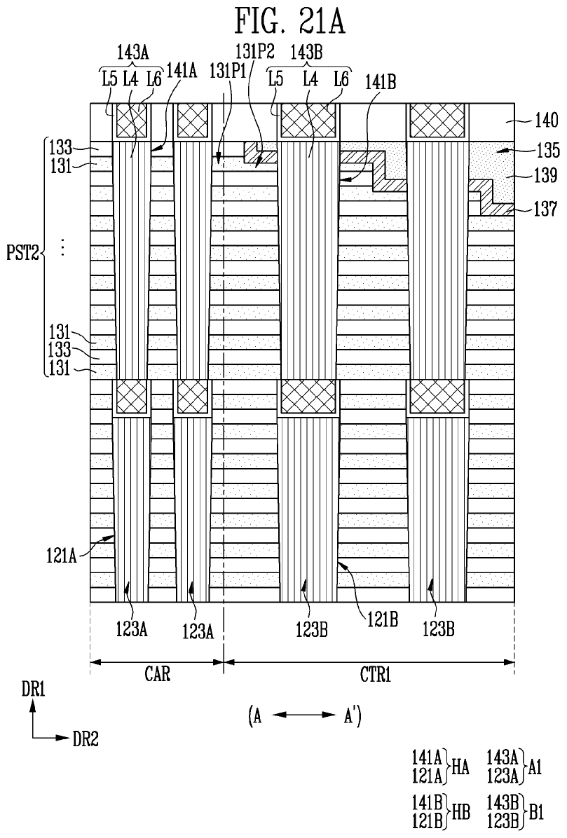

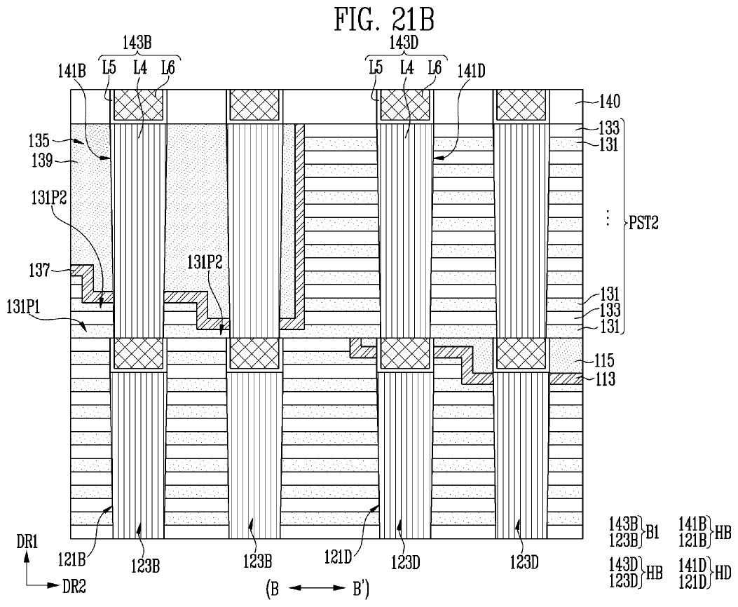

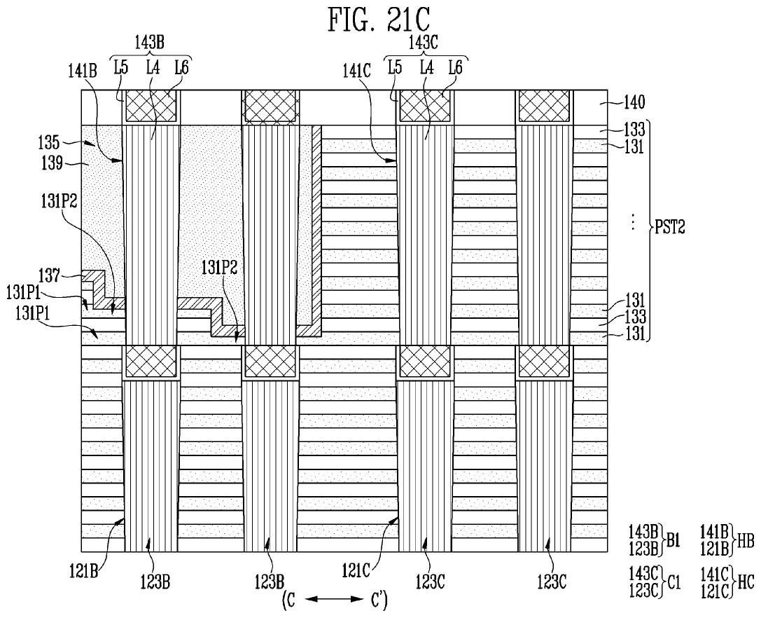

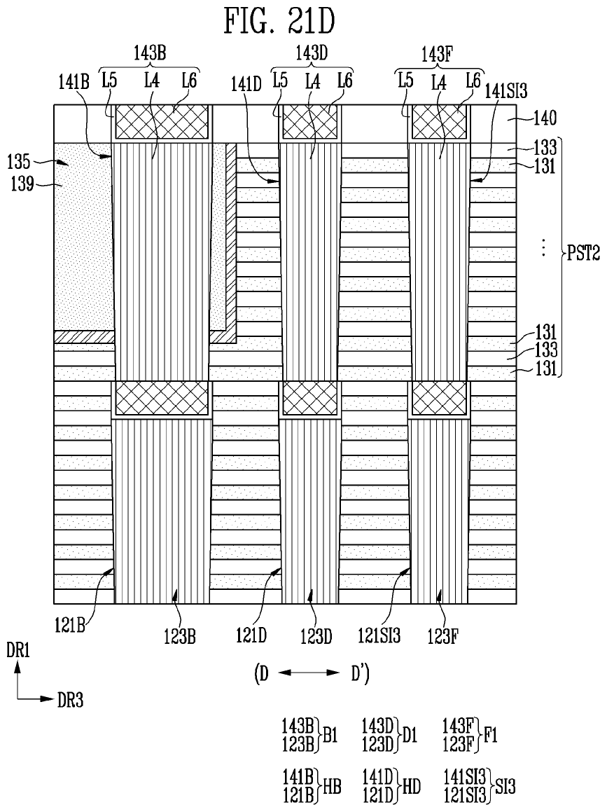

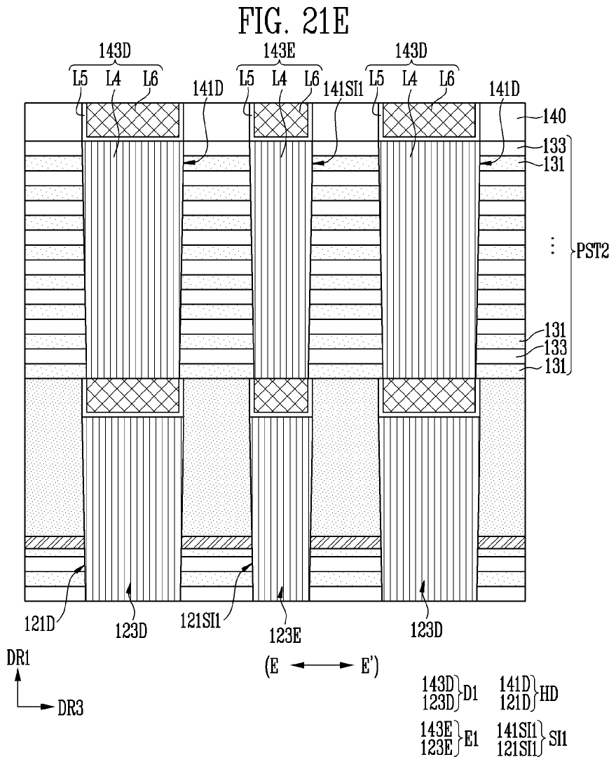

FIGS. 20, 21A, 21B, 21C, 21D, and 21E are views illustrating a process of forming upper sacrificial structures. FIG. 21A illustrates a section of the second preliminary stack structure PST2 taken along line A-A′ shown in FIG. 20. FIG. 21B illustrates a section of the second preliminary stack structure PST2 taken along line B-B′ shown in FIG. 20. FIG. 21C illustrates a section of the second preliminary stack structure PST2 taken along line C-C′ shown in FIG. 20. FIG. 21D illustrates a section of the second preliminary stack structure PST2 taken along line D-D′ shown in FIG. 20. FIG. 21E illustrates a section of the second preliminary stack structure PST2 taken along line E-E′ shown in FIG. 20. In the following description, reference numeral “121S12” corresponds to the second lower slit 121S12 shown in FIG. 16, and reference numeral “123G” corresponds to a lower sacrificial structure 123G inside the second lower slit 121S12 shown in FIG. 16.

Referring to FIGS. 20 and 21A to 21E, a first horizontal insulating layer 140 may be formed on the second preliminary stack structure PST2. The first horizontal insulating layer 140 may extend to cover the second interlayer insulating layer 139 and the second barrier insulating layer 137.

Subsequently, the first horizontal insulating layer 140, the plurality of upper first material layers constituting the plurality of second interlayer insulating layers 133, and the plurality of upper second material layers 131 may be etched. The second filling insulating layer 139 and the second barrier insulating layer 137 may be etched by an etching material for etching the upper first material layer and the upper second material layer 131.

An upper channel hole 141A, a first upper contact hole 141B, an upper dummy hole 141C, a second upper contact hole 141D, a first upper slit 141S11, a second upper slit 141S12, and a third upper slit 141S13 may be formed through the above-described etching process.

The first upper slit 141A11 may penetrate a portion of each of the second preliminary stack structure PST2 and the first horizontal insulating layer 140 in the second contact region CTR2. The first upper slit 141S11 may penetrate the second part 131P2 of each of the plurality of upper second material layers 131. The first upper slit 141S11 may extend to the first contact region CTR1 across the second stepped groove 135. The first upper slit 141S11 may penetrate a portion of each of the second preliminary stack structure PST2, the second filling insulating layer 139, the second barrier insulating layer 137, and the first horizontal insulating layer 140 in the first contact region CTR1. The first upper slit 141S11 may overlap with a lower sacrificial structure 123E inside the first lower slit 121S11 among the plurality of lower sacrificial structures 123A, 123B, 123C, 123D, 123E, 123F, and 123G. The first upper slit 141S11 may be connected to the first lower slit 121S11. Hereinafter, a connection structure of the first upper slit 141S11 and the first lower slit 121S11 is designated as a first slit SI1.

The second upper slit 141S12 may penetrate the cell array region CAR of the second preliminary stack structure PST2. The second upper slit 141S12 may overlap with the lower sacrificial structure 123G inside the second lower slit 121S12 shown in FIG. 16 among the plurality of lower sacrificial structures 123A, 123B, 123C, 123D, 123E, 123F, and 123G. The second upper slit 141S12 may be connected to the second lower slit 121S12. Hereinafter, a connection structure of the second upper slit 141S12 and the second lower slit 121S12 is designated as a second slit. Although not shown in the drawings, the second upper slit 141S12 may be connected to the first upper slit 141S11 in a connection region between the cell array region CAR and the contact region CTR.

The third upper slit 141S13 may penetrate a portion of each of the second preliminary stack structure PST2 and the first horizontal insulating layer 140. The third upper slit 141S13 may be formed across of the cell array region CAR, the first contact region CTR1, and the second contact region CTR2 of the second preliminary stack structure PST2. The third upper slit 141S13 may overlap with a lower sacrificial structure 123F inside the third lower slit 121S13 shown in FIG. 16 among the plurality of lower sacrificial structures 123A, 123B, 123C, 123D, 123E, 123F, and 123G. The third upper slit 141S13 may be connected to the third lower slit 121S13 shown in FIG. 16. Hereinafter, a connection structure of the third upper slit 141S13 and the third lower slit 121S13 shown in FIG. 16 is designated as a third slit SI3. The third upper slit 141S13 may be spaced apart from the second stepped groove 135.

The upper channel hole 141A may penetrate the cell array region CAR of the second preliminary stack structure PST2. The upper channel hole 141A may penetrate a portion of each of the second preliminary stack structure PST2 and the first horizontal insulating layer 140. The upper channel hole 141A may overlap with a lower sacrificial structure 123A inside the lower channel hole 121A among the plurality of lower sacrificial structures 123A, 123B, 123C, 123D, 123E, 123F, and 123G. The upper channel hole 141A may be connected to the lower channel hole 121A. Hereinafter, a connection structure of the upper channel hole 141A and the lower channel hole 121A is designated as a channel hole HA.

The first upper contact hole 141B may penetrate a portion of the first horizontal insulating layer 140 overlapping with the second filling insulating layer 139, the second filling insulating layer, the second barrier insulating layer 137, and the second stepped structure SW2 of the second preliminary stack structure PST2. The first upper contact hole 141B may penetrate the second part 131P2 of the upper second material layer 131 constituting the second stepped structure SW2. The first upper contact hole 141B may be connected to the first lower contact hole 121B. Hereinafter, a connection structure of the first upper contact hole 141B and the first lower contact hole 121B is designated as a first contact hole HB.

The upper dummy hole 141C may penetrate a portion of each of the second preliminary stack structure PST2 and the first horizontal insulating layer 140. The upper dummy hole 141C may overlap with a lower sacrificial structure 123C inside the lower dummy hole 121C among the plurality of lower sacrificial structures 123A, 123B, 123C, 123D, 123E, 123F, and 123G. The upper dummy hole 141C may be connected to the lower dummy hole 121C. Hereinafter, a connection structure of the upper dummy hole 141C and the lower dummy hole 121C is designated as a dummy hole HC.

The second upper contact hole 141D may penetrate a portion of each of the second preliminary stack structure PST2 and the first horizontal insulating layer 140. The second upper contact hole 141D may overlap with a lower sacrificial structure 123D inside the second lower contact hole 121D among the plurality of lower sacrificial structures 123A, 123B, 123C, 123D, 123E, 123F, and 123G. The second upper contact hole 141D may be connected to the second lower contact hole 121D. Hereinafter, a connection structure of the second upper contact hole 141D and the second lower contact hole 121D is designated as a second contact hole HD.

From a planar viewpoint, an area of each of the first upper contact hole 141B, the upper dummy hole 141C, and the second upper contact hole 141D may be formed wider than an area of the upper channel hole 141A. From a planar viewpoint, the first upper contact hole 141B, the upper dummy hole 141C, and the second upper contact hole 141D may have different areas or have the same area.

In accordance with the embodiment of the present disclosure, properties of the second filling insulating layer 139 and the second barrier insulating layer 137 are controlled by considering the upper first material layer constituting the second interlayer insulating layer 133 and the upper second material layer 131, so that a difference between an etching amount at the outside of the second stepped groove 135 and an etching amount inside the second stepped groove 135 may be reduced.

Subsequently, a plurality of upper sacrificial structures 143A, 143B, 143C, 143D, 143E, 143F, and 143G may be respectively formed inside the upper channel hole 141A, the first upper contact hole 141B, the upper dummy hole 141C, the second upper contact hole 141D, the first upper slit 141S11, the second upper slit 141S12, and the third upper slit 141S13. Each of the plurality of upper sacrificial structures 143A, 143B, 143C, 143D, 143E, 143F, and 143G may be formed of various materials. In an embodiment, each of the plurality of upper sacrificial structures 143A, 143B, 143C, 143D, 143E, 143F, and 143G may include an amorphous carbon layer L4, a titanium nitride layer L5, and a tungsten layer L6.

The plurality of upper sacrificial structures 143A, 143B, 143C, 143D, 143E, 143F, and 143G are respective connected to the plurality of upper sacrificial structures 123A, 123B, 123C, 123D, 123E, 123F, and 123G, thereby defining a plurality of primary sacrificial structures A1, B1, C1, D1, E1, F1, and G1.

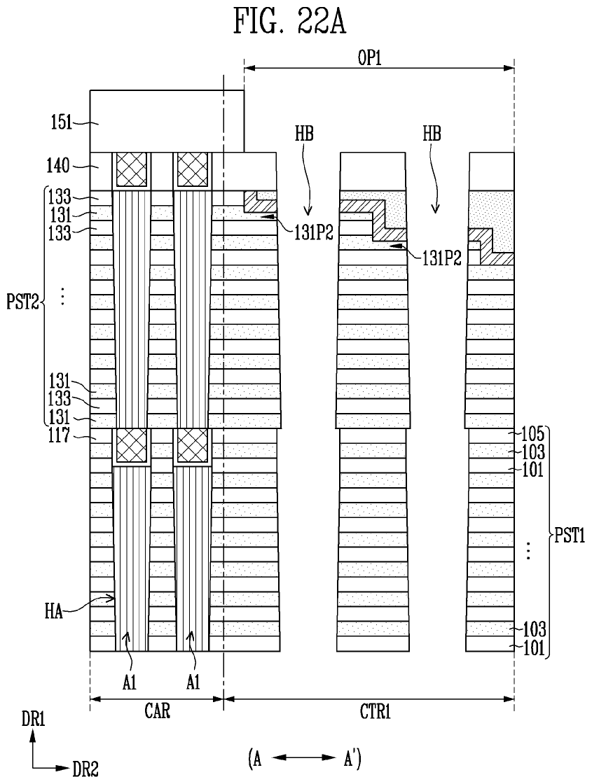

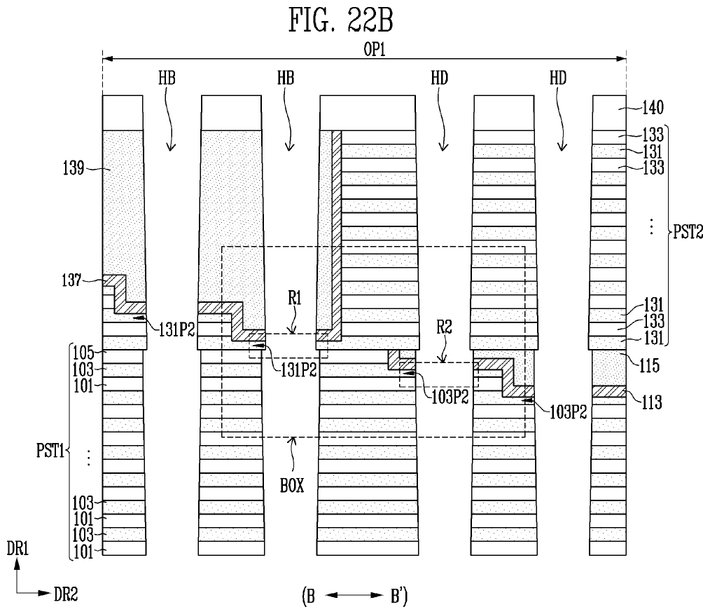

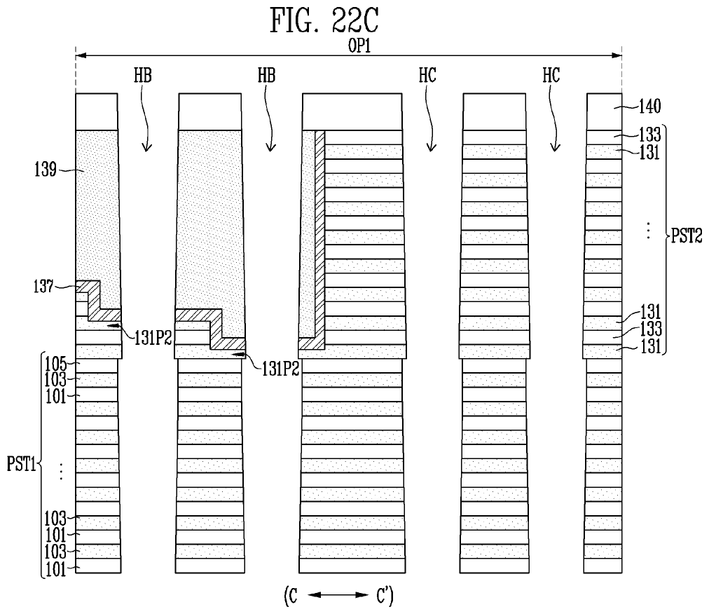

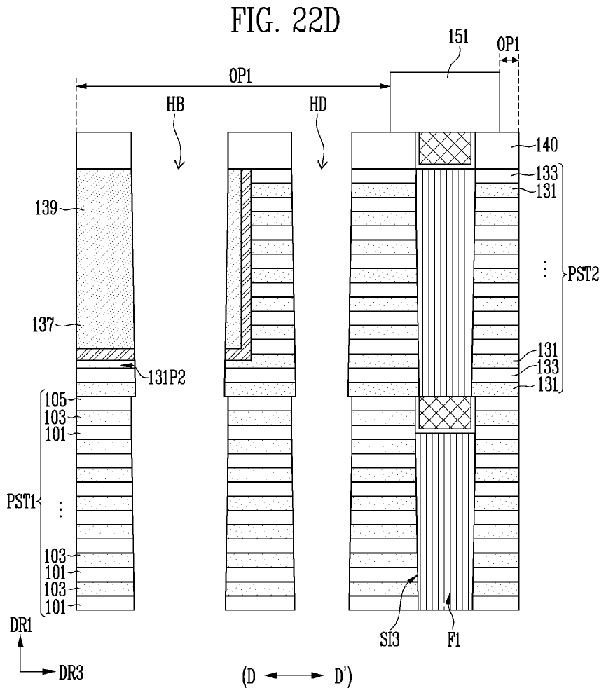

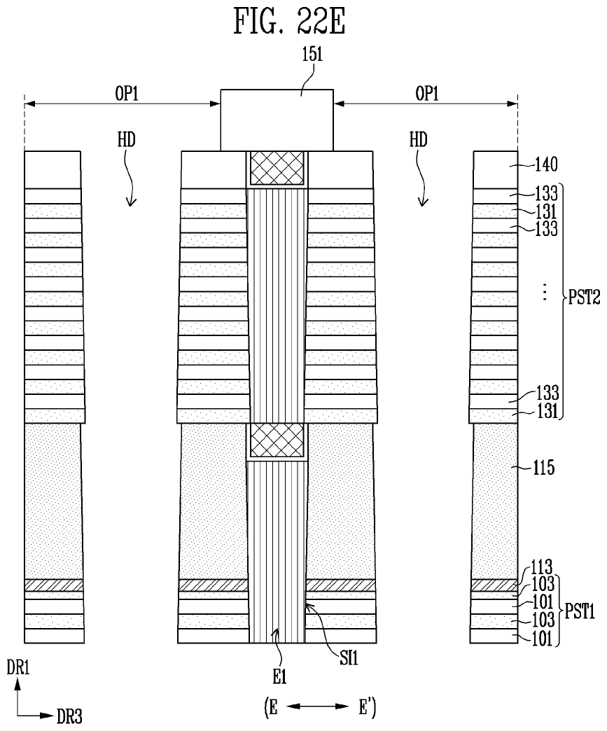

FIGS. 22A, 22B, 22C, 22D, and 22E are sectional views illustrating a process of removing some of the plurality of primary sacrificial structures.

Referring to FIGS. 22A to 22E, a first mask pattern 151 having a first opening OP1 may be formed on the first horizontal insulating layer 141. Sacrificial structures A1, E1, F1, and G1 inside the channel hole HA, the first slit SI1, the second slit, and the third slit SI3 among the plurality of primary sacrificial structures A1, B1, C1, D1, E1, F1, and G1 shown in FIGS. 20 and 21A to 21E may be blocked, and sacrificial structures B1, C1, and D1 inside the first contact hole HB, the dummy hole HC, and the second contact hole HD among the plurality of primary sacrificial structures A1, B1, C1, D1, E1, F1, and G1 shown in FIGS. 20 and 21A to 21E may be exposed by the first opening OP1.

Subsequently, the first contact hole HB, the dummy hole HC, and the second contact hole HD may be opened by removing the sacrificial structures B1, C1, and D1 exposed through the first opening OP1. Accordingly, the plurality of upper second material layers 131 and the plurality of lower second material layers 103 may be exposed.

The plurality of upper second material layers 131 may be divided into an upper second material layer of a target layer disposed at an intersection portion (e.g., R1) of the first contact hole HB and the second stepped structure SW2 shown in FIG. 19A and the other upper second material layer. A second part 131P2 of the upper second material layer of the target layer and a first part 131P1 of the other upper second material layer may be exposed by the first contact hole HB. The plurality of lower second material layers 103 may be divided into a lower second material layer of a target layer disposed at an intersection portion (e.g., R2) of the second contact hole HD and the first stepped structure SW1 shown in FIG. 13B and the other lower second material layer. A second part 103P2 of the lower second material layer of the target layer and a first part 103P1 of the other lower second material layer may be exposed by the second contact hole HD.

The first part 131P of each of the plurality of upper second material layers 131 and the first part 103P1 of each of the plurality of lower second material layers 103 may be exposed by the dummy hole HC.

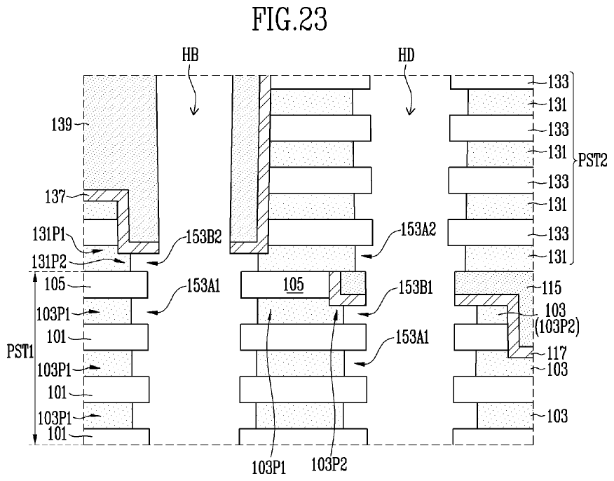

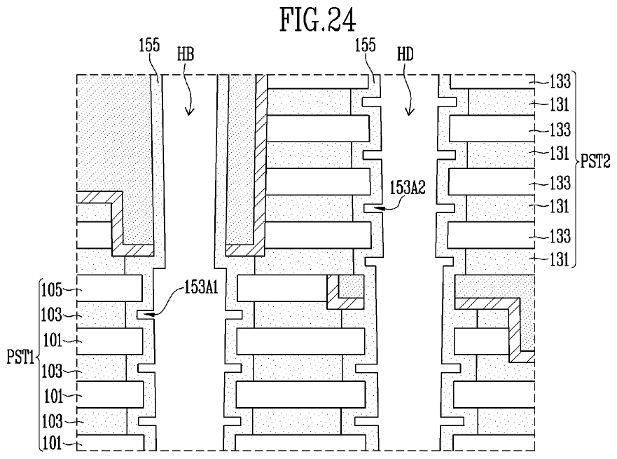

FIGS. 23, 24, 25, and 26 are sectional views illustrating processes of forming a pad pattern and an insulating layer. FIGS. 23, 24, 25, and 26 are enlarged sectional views of a boxed region BOX shown in FIG. 22B.

Referring to FIG. 23, a portion of the plurality of upper second material layers 131 and the plurality of lower second material layers 103 may be removed through the first contact hole HB, the second contact hole HD, and the dummy hole HC shown in FIG. 22C. Accordingly, first to fourth recess regions 153A1, 153B1, 153A2, and 153B2 may be defined. The first recess region 153A1 may be defined in a region in which the first part 103P1 of the lower second material layer 103 is removed, and the second recess region 153B1 may be defined in a region in which the second part 103P2 of the lower second material layer 103. The third recess region 153A2 may be defined in a region in which the first part 131P1 of the upper second material layer 131 is removed, and the fourth recess region 153B2 may be defined in a region in which the second part 131P2 of the upper second material layer 131 is removed. Each of the second recess region 153B1 and the fourth recess region 153B2 may be formed narrower in the first direction DR1 than each of the first recess region 153A1 and the third recess region 153A2.

Referring to FIG. 24, a pad layer 155 may be formed along a sidewall of each of the first contact hole HB, the second contact hole HD, and the dummy hole HC shown in FIG. 22C. The pad layer 155 completely fills the second recess region 153B1 and the fourth recess region 153B2, which are shown in FIG. 23, and may be formed to have a thickness capable of opening a central region of each of the first recess region 153A1 and the third recess region 153A2. The pad layer 155 may be formed of the same material as the upper second material layer 131 and the lower second material layer 103.

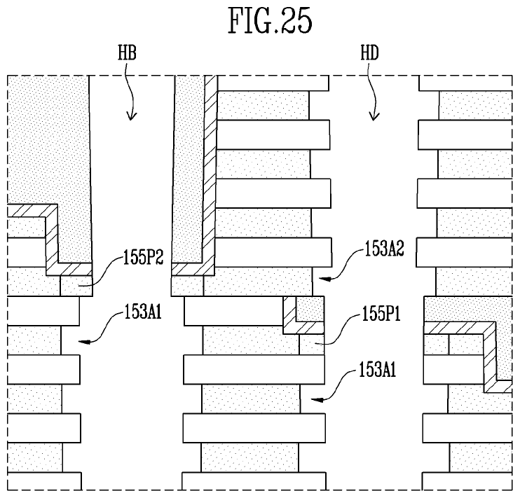

Referring to FIG. 25, the pad layer 155 shown in FIG. 24 may be etched to be isolated into a plurality of pad patterns 155P1 and 155P2. The plurality of pad patterns 155P1 and 155P2 may include a first pad pattern 155P1 remaining inside the second recess region 153B1 shown in FIG. 23 and a second pad pattern 155P2 remaining inside the fourth recess region 153B2 shown in FIG. 23.

The first recess region 153A1 and the third recess region 153A2 may be opened through an etching process of the pad layer 155.

According to the process described above with reference to FIGS. 23 to 25, the second part 103P2 of the lower second material layer 103 and the second part 131P2 of the upper second material layer 131 may be replaced with the first pad pattern 155P1 and the second pad pattern 155P2.

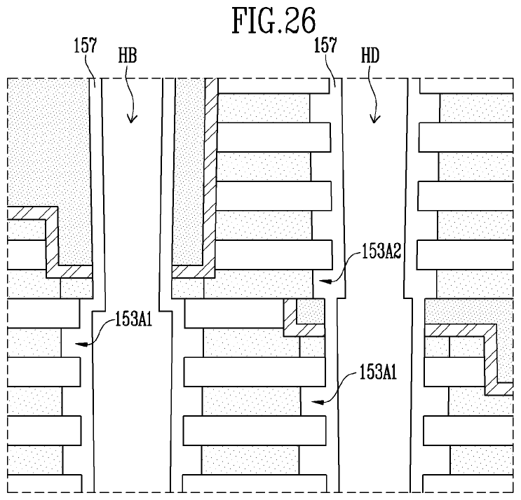

Referring to FIG. 26, an insulating layer 157 may be formed along the sidewall of each of the first contact hole HB, the second contact hole HD, and the dummy hole HC shown in FIG. 22C. The insulating layer 157 may be formed to fill the first recess region 153A1 and the third recess region 153A2. A central region of each of the first contact hole HB, the second contact hole HD, and the dummy hole HC shown in FIG. 22C is not filled with the insulating layer 157 but may be opened.

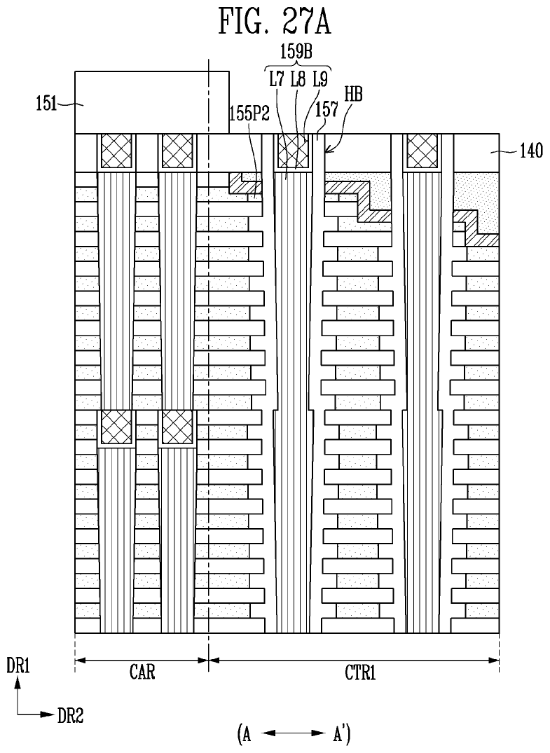

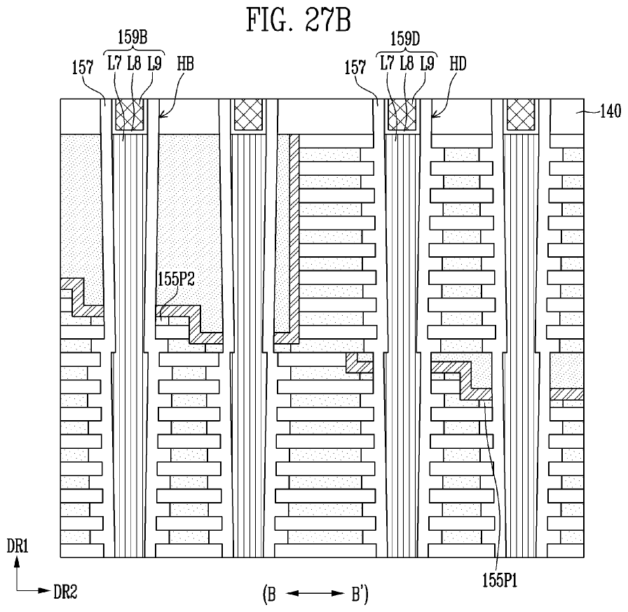

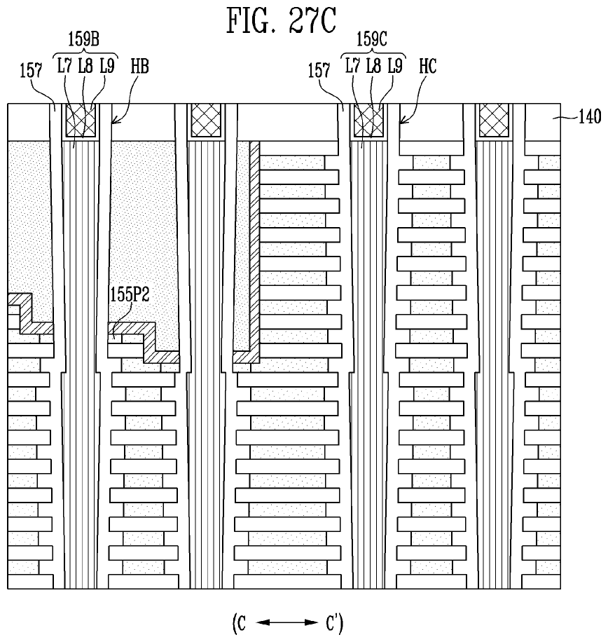

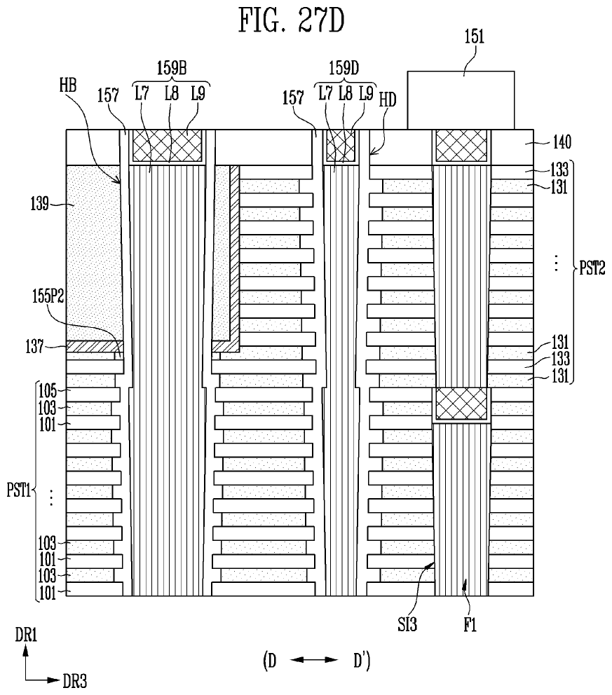

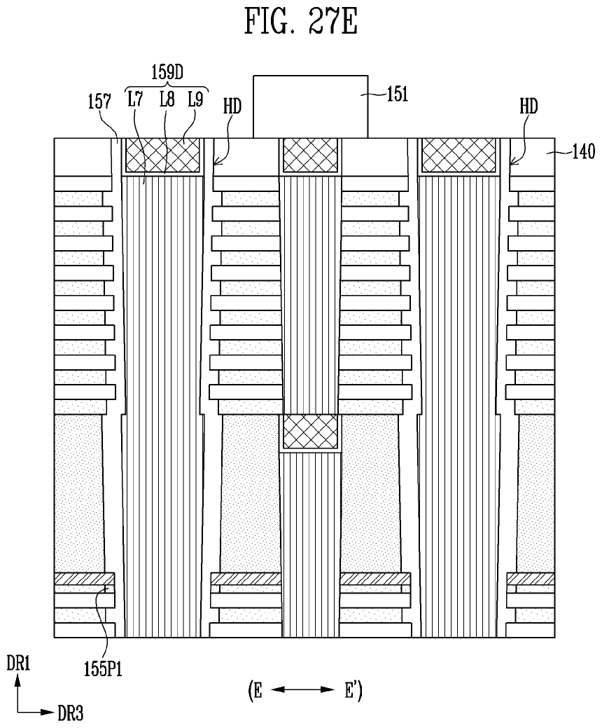

FIGS. 27A, 27B, 27C, 27D, and 27E are sectional views illustrating a process of forming a plurality of secondary sacrificial structures.

Referring to FIGS. 27A to 27E, the central region of each of the first contact hole HB, the dummy hole HC, and the second contact hole HD may be opened after the processes described with reference to FIGS. 23 to 26 are performed. A plurality of secondary sacrificial structure 159B, 159D, and 159C may be respectively formed in the central regions of the first contact hole HB, the dummy hole HC, and the second contact hole HD. Each of the plurality of secondary sacrificial structure 159B, 159D, and 159C may be formed of various materials. In an embodiment, each of the plurality of secondary sacrificial structure 159B, 159D, and 159C may include an amorphous carbon layer L7, a titanium nitride layer L8, and a tungsten layer L9.

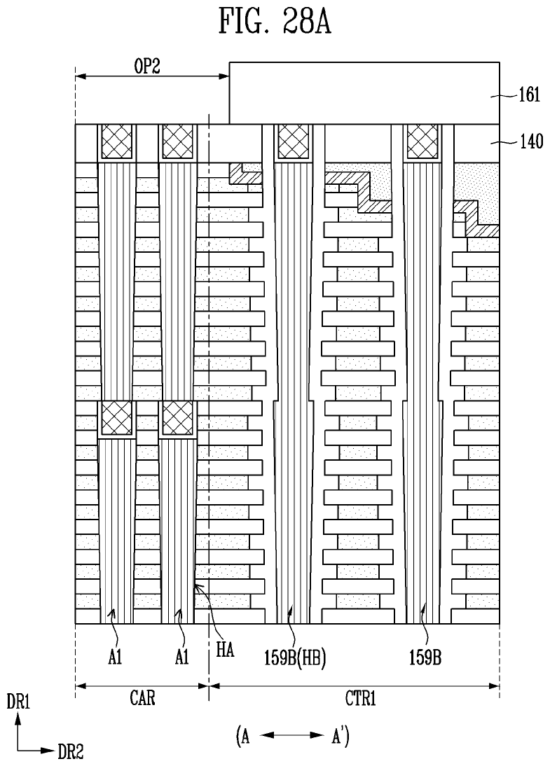

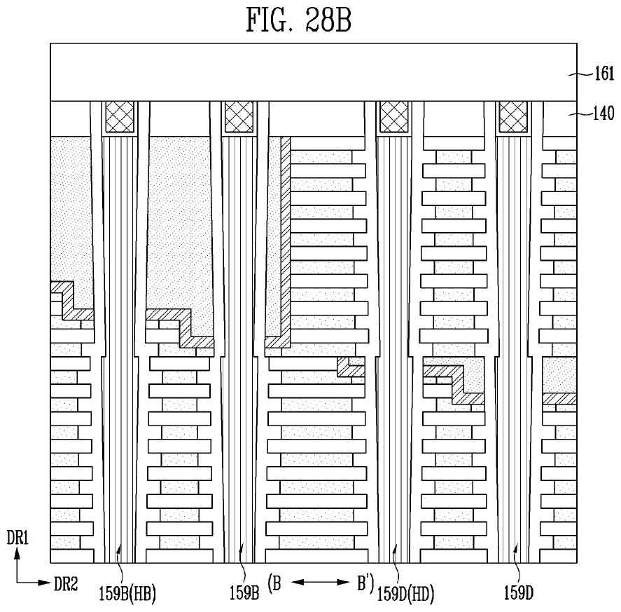

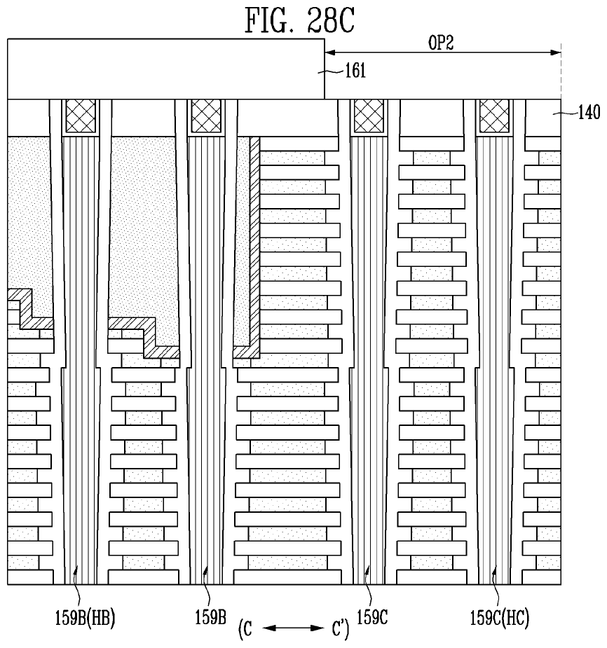

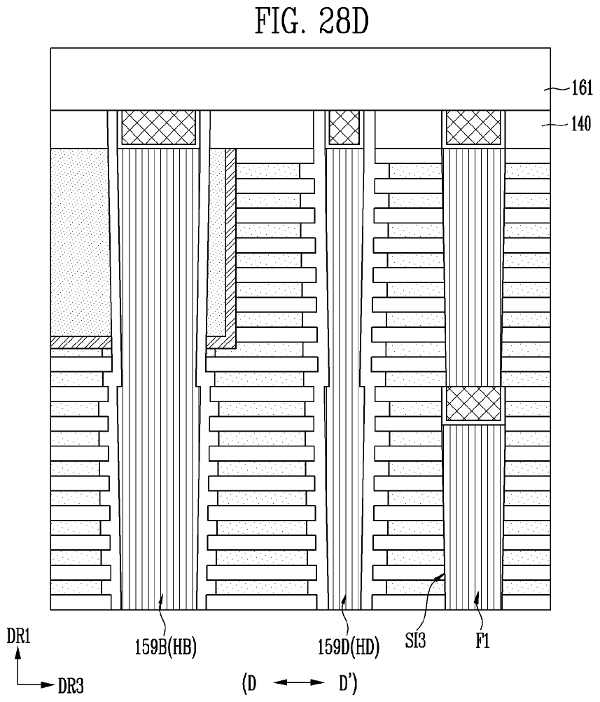

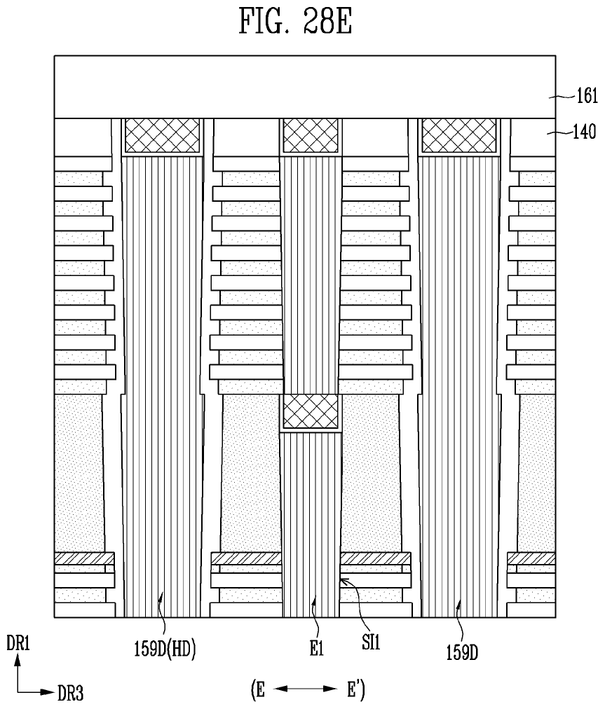

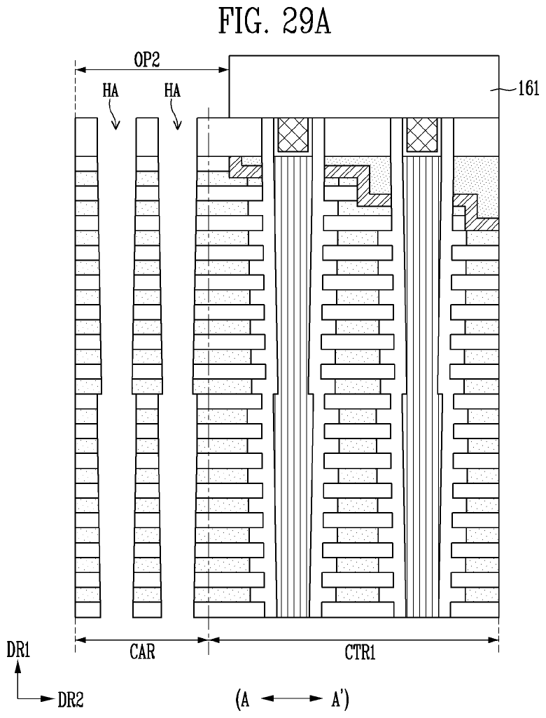

FIGS. 28A, 28B, 28C, 28D, 28E, 29A, 29B, 30A, 30B, 31A, 31B, 31C, 31D, and 31E are sectional views illustrating a process of forming a cell plug and a dummy pug.

Referring to FIGS. 28A to 28E, the first mask pattern 151 shown in FIGS. 27A to 27E may be removed. Subsequently, a second mask pattern 161 having a second opening OP2 may be formed on the first horizontal insulating layer 140.

A sacrificial structure A1 inside the channel hole HA among the plurality of primary sacrificial structures A1, B1, C1, D1, E1, F1, and G1 shown in FIGS. 20 and 21A to 21D may be exposed by the second opening OP2. Sacrificial structures E1, F1, and G1 inside the first slit SI1, the second slit, and the third slit SI3 among the plurality of primary sacrificial structures A1, B1, C1, D1, E1, F1, and G1 shown in FIGS. 20 and 21A to 21D may be blocked by the second mask pattern 161.

A sacrificial structure 159C inside the dummy hole HC among the plurality of secondary sacrificial structures 159B, 159D, and 159C may be exposed by the second opening OP2. Sacrificial structures 159B and 159D inside the first contact hole HB and the second contact hole HD among the plurality of secondary sacrificial structures 159B, 159D, and 159C may be blocked by the second mask pattern 161.

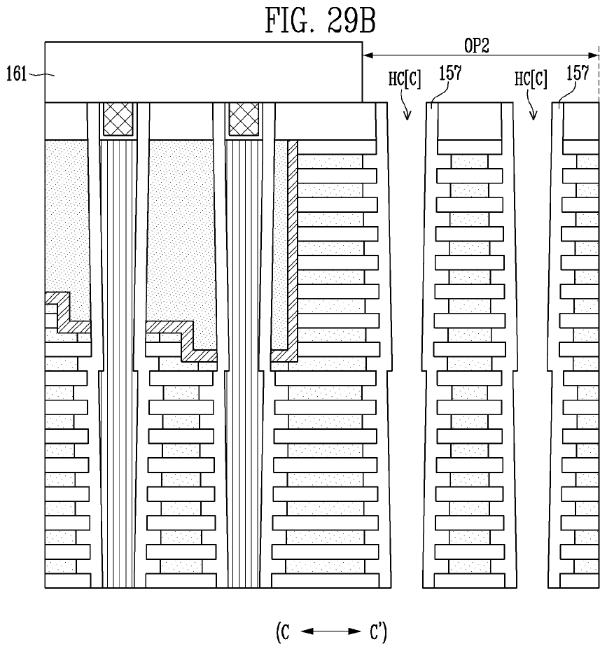

Referring to FIGS. 29A and 29B, the sacrificial structure A1 inside the channel hole HA shown in FIG. 28A and the sacrificial structure 159C inside the dummy hole HC shown in FIG. 28C may be removed through the second opening OP2. Accordingly, the channel hole HA may be opened, and a central region HC[C] of the dummy hole may be opened.

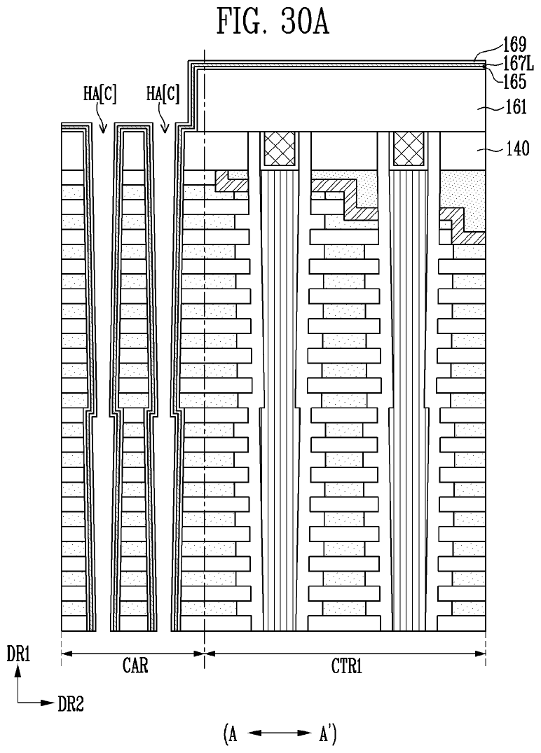

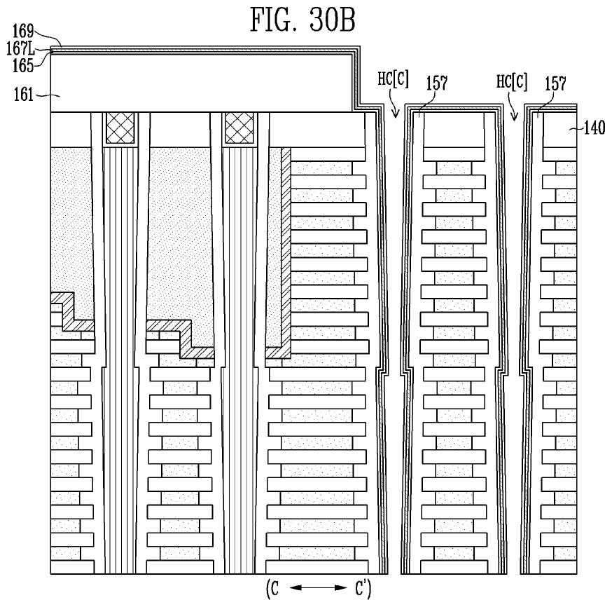

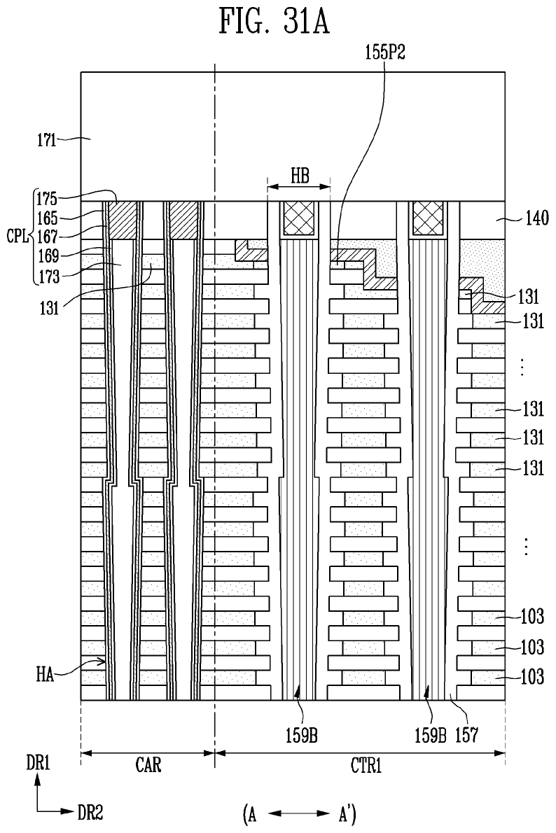

Referring to FIGS. 30A and 30B, a memory layer 165 may be formed along a surface of the channel hole HA shown in FIG. 29A and a surface of the insulating layer 157 exposed by the central region HC[C] of the dummy hole. Subsequently, a channel layer 167L may be formed on a surface of the memory layer 165. A surface of the channel layer 167L may be covered by a buffer insulating layer 169. A portion of each of a central region HA[C] of the channel hole and the central region HC[C] of the dummy hole is not filled with the memory layer 165, the channel layer 167L, and the buffer insulating layer 169 but may be opened.

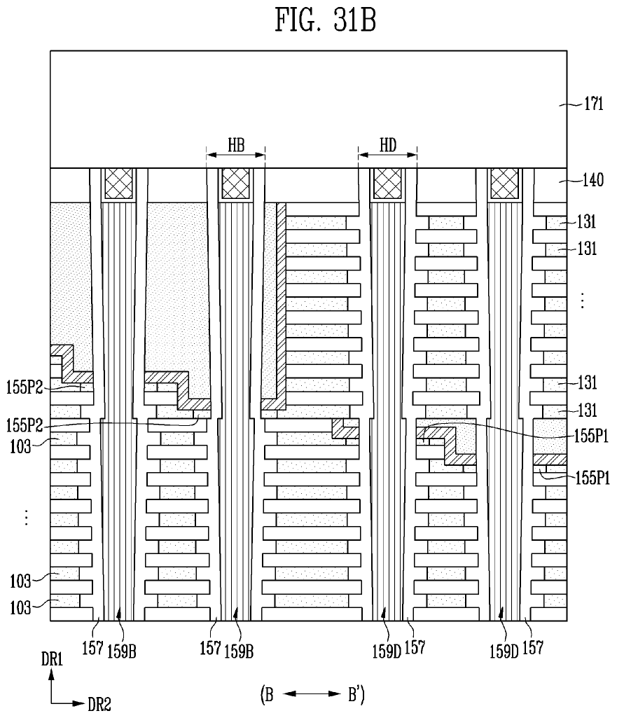

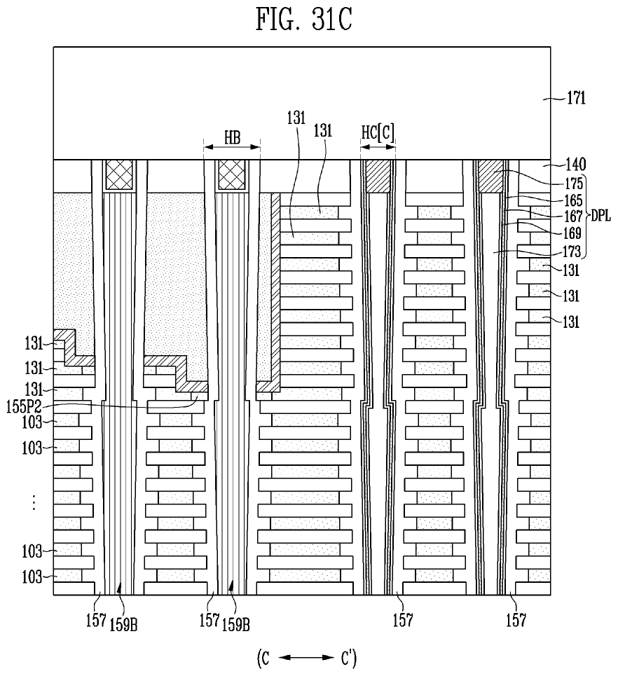

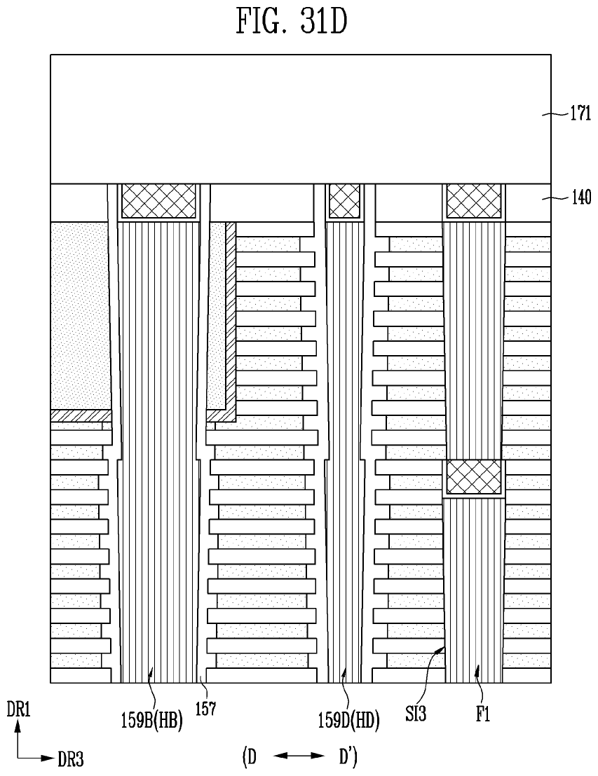

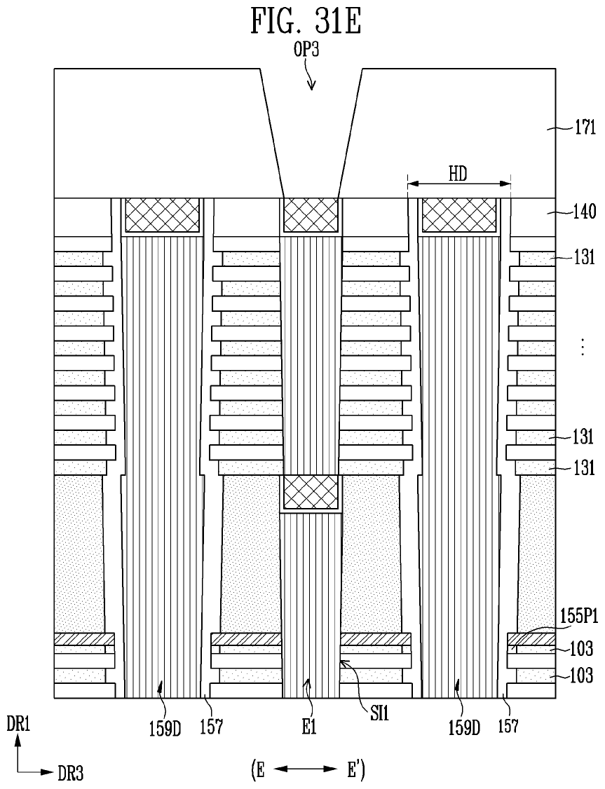

Referring to FIGS. 31A to 31E, after a core insulating layer 173 is formed at a portion of each of the central region HA[C] of the channel hole and the central region HC[C] of the dummy hole, which are shown in FIGS. 30A and 30B, a capping pattern 175 may be formed on the core insulating layer 173. Subsequently, a portion of each of the memory layer 165, the channel layer 167L, and the buffer insulating layer 169, which are shown in FIGS. 30A and 30B, and the second mask pattern 161 may be removed such that the first horizontal insulating layer 140. Accordingly, a cell plug CPL may be formed inside the channel hole HA, and a dummy plug DPL may be formed in the central region HC[C] of the dummy hole.

The channel layer 167L shown in FIGS. 30A and 30B may be isolated into a channel structure 167 of the cell plug CPL and a channel structure 167 of the dummy plug DPL. The channel structure 167 of each of the cell plug CPL and the dummy plug DPL may have a sidewall surrounded by the memory layer 165. The channel structure 167 of each of the cell plug CPL and the dummy plug DPL may be formed in a tubular shape having a central region filled with a buffer insulating layer 169, the core insulating layer 173, and the capping pattern 175.

Subsequently, a third mask pattern 171 having a third opening OP3 may be formed on the first horizontal insulating layer 140. The third mask pattern 171 may block the sacrificial structures 159B and 159D inside the first contact hole HB and the second contact hole HD among the plurality of secondary sacrificial structures 159B, 159D, and 159C, the cell plug CPL, and the dummy plug DPL. A sacrificial structure E1 inside the first slit SI1 among the plurality of primary sacrificial structures A1, B1, C1, D1, E1, F1, and G1 shown in FIGS. 20 and 21A to 21E may be exposed by the third opening OP3.

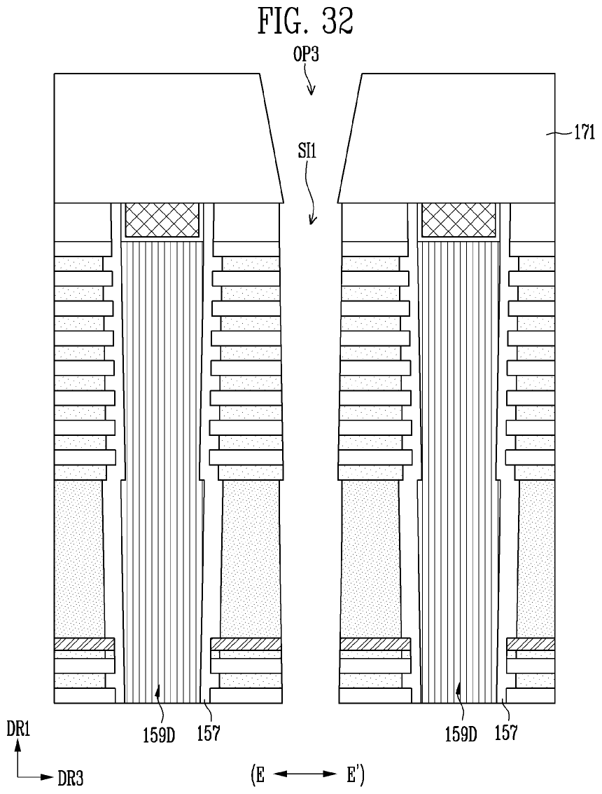

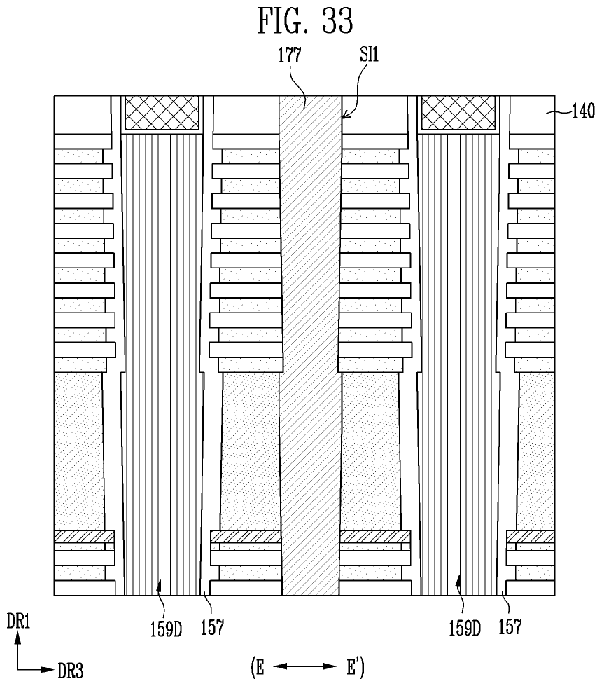

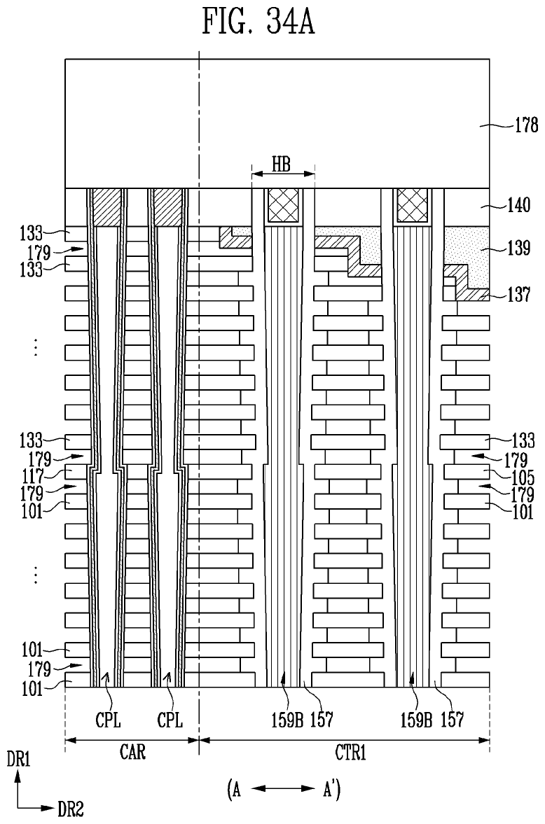

FIGS. 32 and 33 are sectional views illustrating a process of replacing some of the plurality of primary sacrificial structures with a first isolation structure. FIGS. 32 and 33 illustrates subsequent processes with respect to a region shown in FIG. 31E.

Referring to FIG. 32, the first slit SI1 may be opened by removing the sacrificial structure E1 shown in FIG. 31E through the third opening OP3.

Referring to FIG. 33, a first vertical structure 177 may be formed inside the opened first slit SI1. The first vertical structure 177 may be formed of an insulating material. Subsequently, the third mask pattern 171 shown in FIG. 32 may be removed.

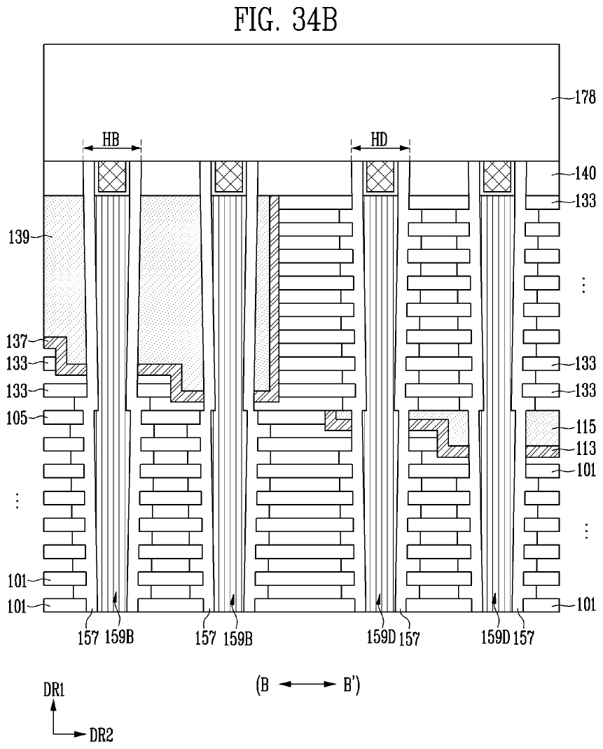

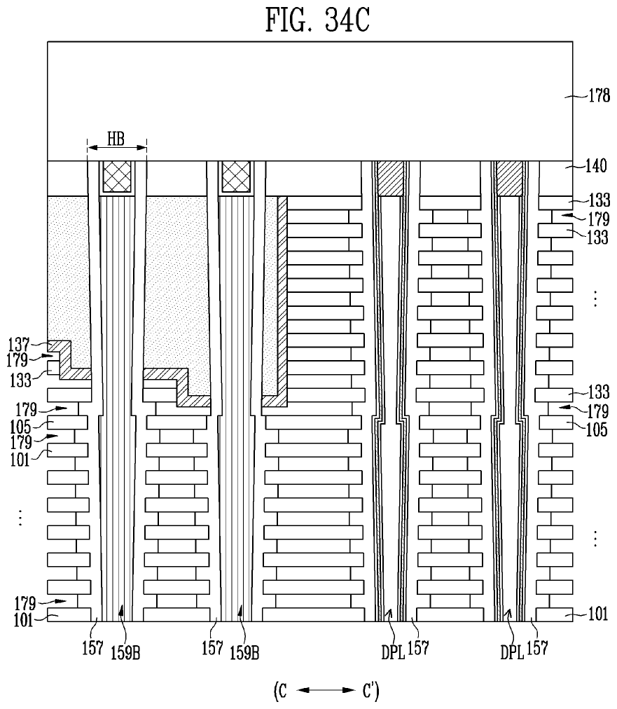

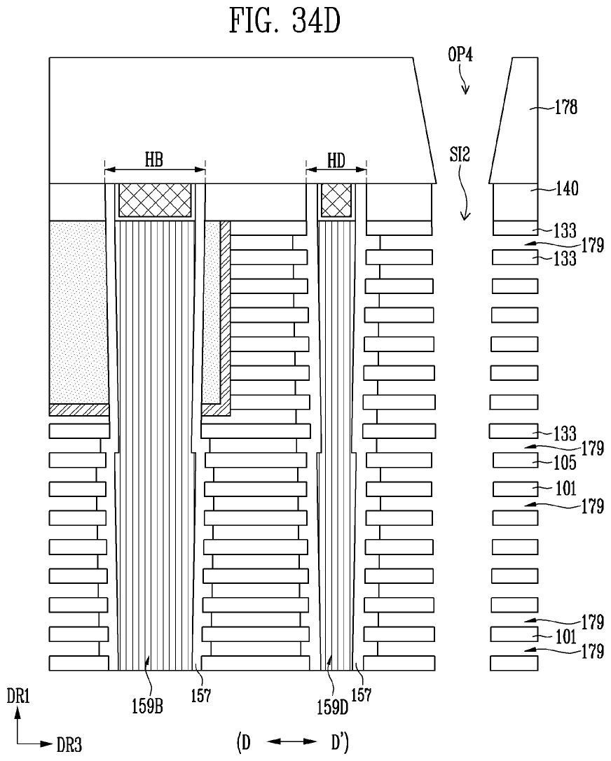

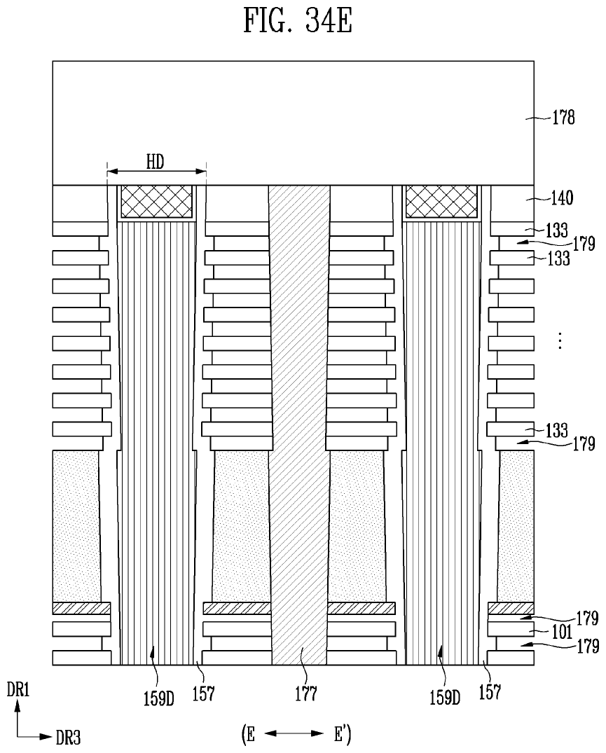

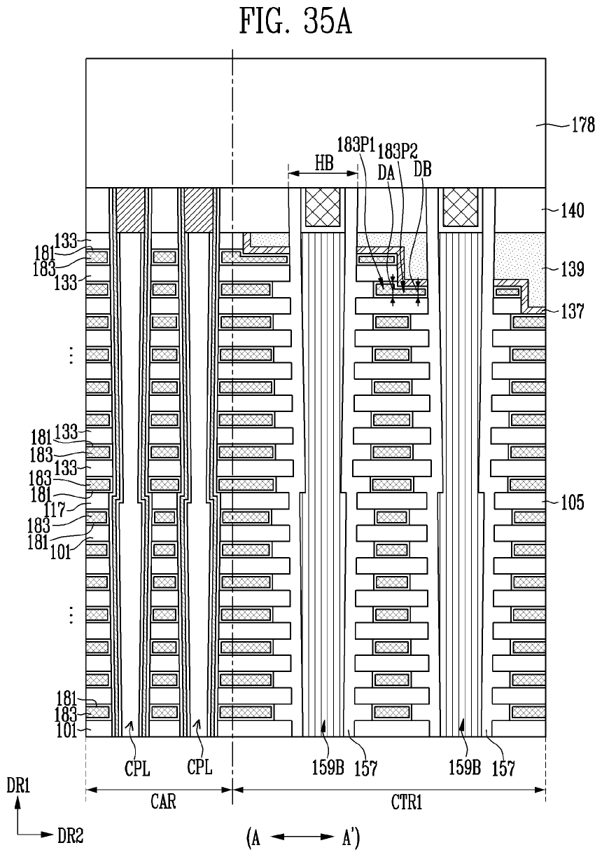

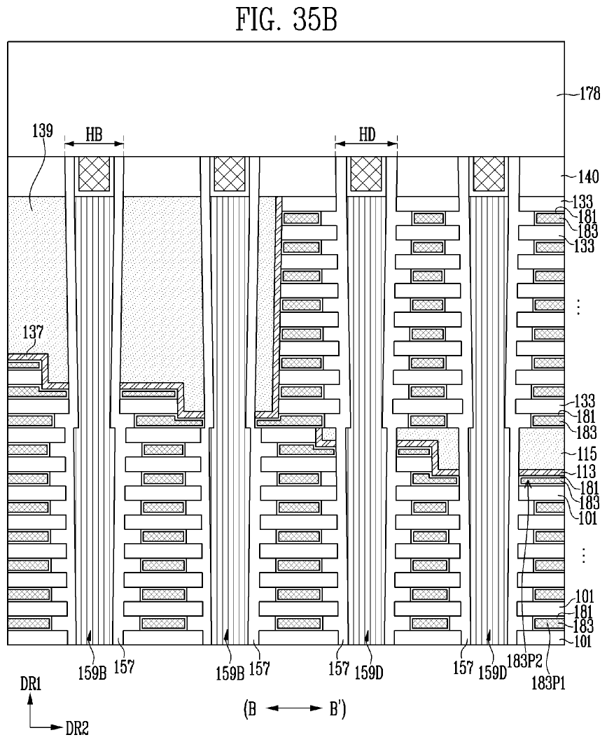

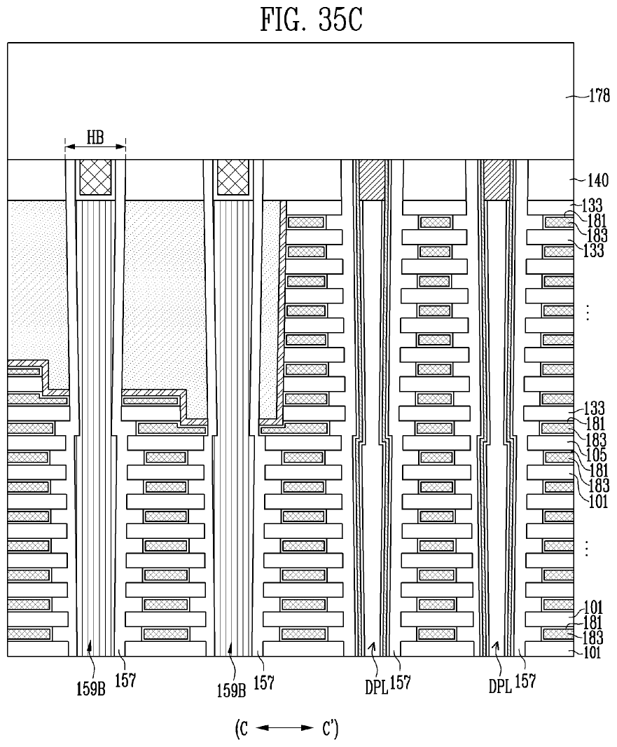

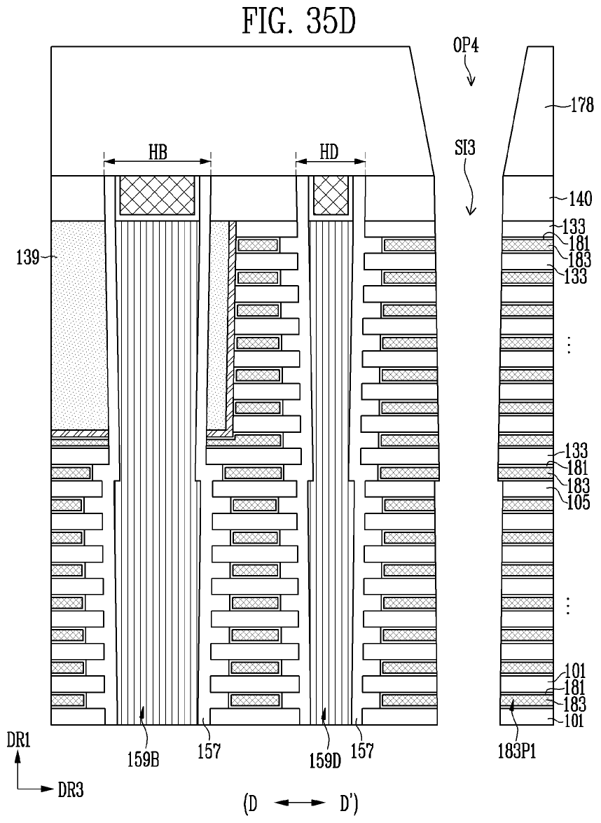

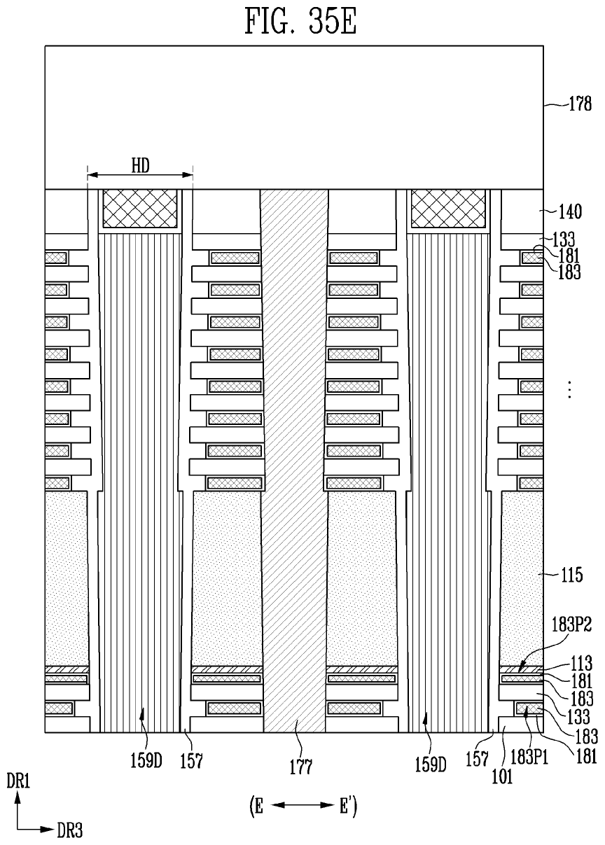

FIGS. 34A, 34B, 34C, 34D, 34E, 35A, 35B, 35C, 35D, and 35E are sectional views illustrating a process of replacing the plurality of lower second material layers, the plurality of upper second material layers, and the pad pattern with a conductor.

Referring to FIGS. 34A to 34E, a fourth mask pattern 178 having a fourth opening OP4 may be formed on the first horizontal insulating layer 140. The fourth mask pattern 178 may block the sacrificial structures 159B and 159D inside the first contact hole HB and the second contact hole HD among the plurality of secondary sacrificial structures 159B, 159D, and 159C shown in FIGS. 31A to 31E, the cell plug CPL, the dummy plug DPL, and the first vertical structure 173. The fourth opening OP4 may expose a sacrificial structure G1 inside the second slit and a sacrificial structure F1 inside the third slit SI3 among the plurality of primary sacrificial structures A1, B1, C1, D1, E1, F1, and G1 shown in FIGS. 20 and 21A to 21D.

Subsequently, the second slit and the third slit SI3 may be opened by removing the sacrificial structures F1 and G1 among the plurality of primary sacrificial structures A1, B1, C1, D1, E1, F1, and G1 shown in FIGS. 20 and 21A to 21D through the fourth opening OP4.

Subsequently, the plurality of lower second material layers 103, the plurality of upper second material layers 131, and the plurality of pad patterns 155P1 and 155P2, which are shown in FIGS. 31A to 31E, may be removed through the second slit (a region in which G1 shown in FIG. 20 is removed) and the third slit SI3. Accordingly, a plurality of gate regions 179 may be opened. The dummy plug DPL and the sacrificial structures 159B and 159D inside the first contact hole HB and the second contact hole HD may be used as a support structure for maintaining a gap of each of the plurality of gate regions 179.

While the plurality of lower second material layers 103, the plurality of upper second material layers 131, and the plurality of pad patterns 155P1 and 155P2, which are shown in FIGS. 31A to 31E, are removed, the first filling insulating layer 115 and the second filling insulating layer 139 may be protected by the first barrier insulating layer 113 and the second barrier insulating layer 137. Accordingly, the first filling insulating layer 115 and the second filling insulating layer 139 may be spaced apart from the plurality of gate regions 179 by the first barrier insulating layer 113 and the second barrier insulating layer 137. Thus, although the first filling insulating layer 115 and the second filling insulating layer 139 include the same element as the plurality of lower second material layers 103 and the plurality of upper second material layers 131, the first filling insulating layer 115 and the second filling insulating layer 139 may be prevented or mitigated from being damaged by an etching material introduced from the plurality of gate regions 179.

For example, when the first barrier insulating layer 113 and the second barrier insulating layer 137 are excluded, a portion of the first filling insulating layer 115 and a portion of the second filling insulating layer 139, which are adjacent to the plurality of gate regions 179, may be lost by an etching material for etching the plurality of lower second material layers 103, the plurality of upper second material layers 131, and the plurality of pad patterns 155P1 and 155P2, which are shown in FIGS. 31A to 31E. There may occur a defect that the plurality of gate regions 179 are connected to each other by the lost portion of the first filling insulating layer 115 and the lost portion of the second filling insulating layer 139. In the embodiment of the present disclosure, loss of the first filling insulating layer 115 and the second filling insulating layer 139 is prevented or mitigated through the first barrier insulating layer 113 and the second barrier layer 137, so that the defect that the plurality of gate regions 179 are connected to each other may be prevented or mitigated in advance.

Referring to FIGS. 35A to 35E, a second blocking insulating layer 181 may be formed along a surface of each of the plurality of gate regions 179 shown in FIGS. 34A to 34E. The second blocking insulating layer 181 may be formed to open the plurality of gate regions 179. Subsequently, a conductor 183 may be formed inside each of the plurality of gate regions 179. The second blocking insulating layer 181 and the conductor 183 may be introduced into the plurality of gate regions 179 shown in FIGS. 34A to 34E through the second slit (the region in which GI shown in FIG. 20 is removed) and the third slit SI3. A conductor 183 disposed in one of the plurality of gate regions 179 may be isolated from a conductor 183 disposed in another of the plurality of gate regions 179. The conductor 183 disposed in each gate region 179 may include a first part 183P1 and a second part 183P2. The first part 183P1 of the conductor 183 is a part disposed in one of regions in which the plurality of lower second material layers 103 and the plurality of upper second material layer 131, which are shown in FIG. 31A to 31E, are removed, and may have a first thickness DA. The second part 183P2 of the conductor 183 is a part disposed in one of regions in which the plurality of pad patterns 155P1 and 155P2 shown in FIGS. 31A to 31E are removed, and may have a second thickness DB. The second thickness DB may be different from the first thickness DA. Although a series of manufacturing processes shown in drawings is illustrated based on an embodiment in which the second thickness DB is smaller than the first thickness DA, the embodiment of the present disclosure is not limited thereto. For example, a manufacturing process may be changed such that the second thickness DB is defined to be thicker than the first thickness DA.

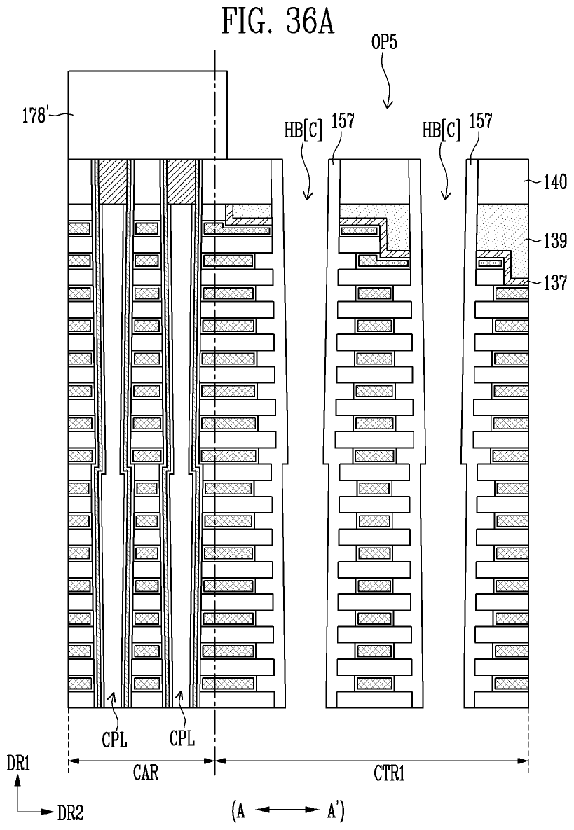

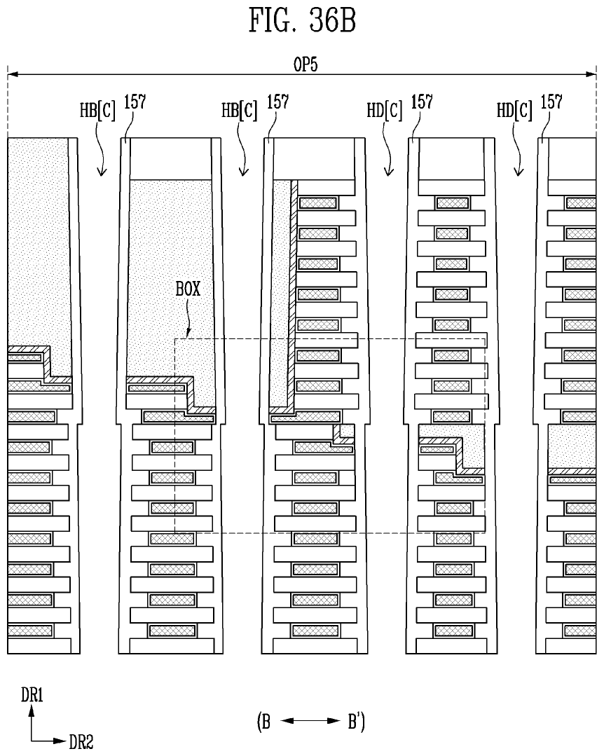

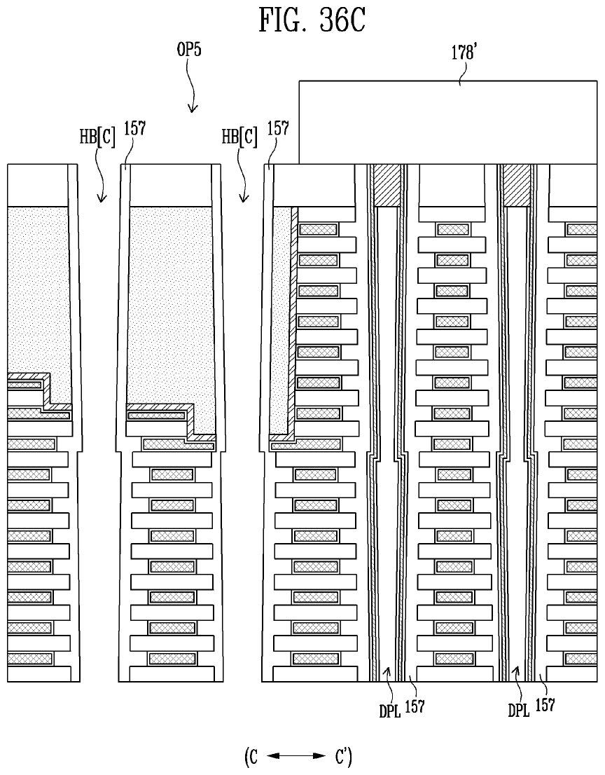

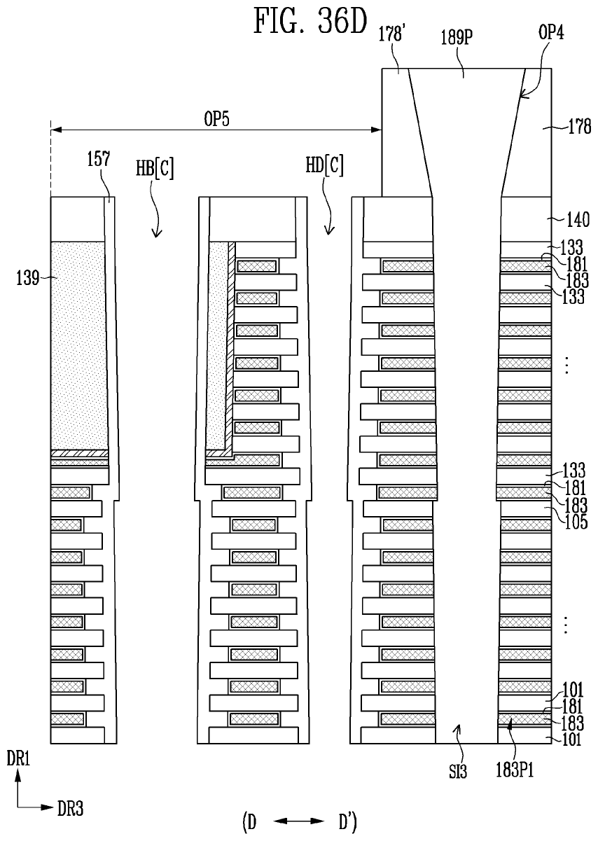

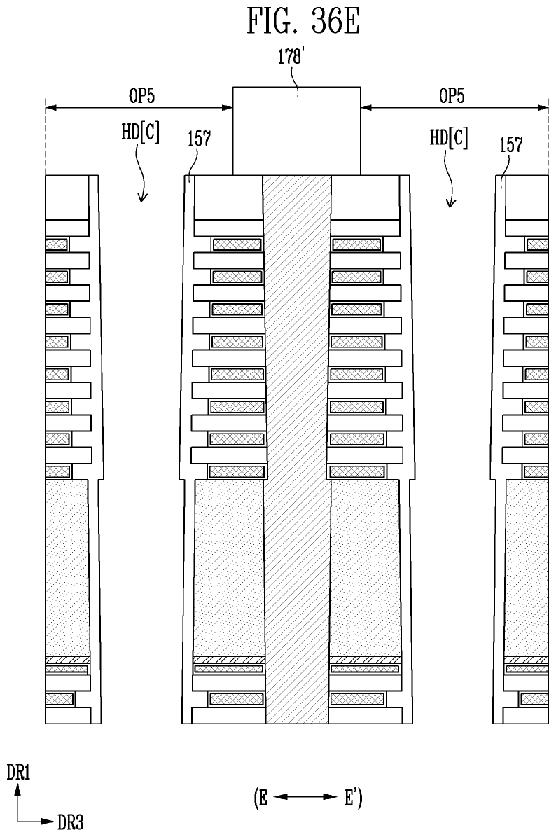

FIGS. 36A, 36B, 36C, 36D, and 36E are sectional views illustrating a process of removing some of the plurality of primary sacrificial structures.

Referring to FIGS. 36A to 36E, in a state in which the fourth mask pattern 178 shown in FIGS. 35A to 35E remains, a preliminary vertical structure 189P may be formed, which fills the fourth opening OP4, the second slit (the region in which G1 shown in FIG. 20 is removed), and the third slit SI3. The preliminary vertical structure 189P may be formed of a material for the second vertical structure 189 described with reference to FIG. 6D.

Subsequently, a surface of the preliminary vertical structure 189P may be planarized. A thickness of the fourth mask pattern 178 shown in FIG. 35A to 35E may be decreased. Subsequently, a fifth opening OP5 may be formed in a fourth mask pattern 178′ having the decreased thickness. The fifth opening OP5 may expose the sacrificial structures 159B and 159D inside the first contact holes HB and the second contact hole HD, which are shown in FIGS. 35A to 35E. The cell plug CPL, the dummy plug DPL, and the sacrificial structure 159C inside the dummy hole HC may be blocked by the fourth mask pattern 178′ having the decreased thickness.

Subsequently, the sacrificial structures 159B and 159D inside the first contact holes HB and the second contact hole HD, which are shown in FIGS. 35A to 35E, may be removed through the fifth opening OP5. Accordingly, a central region HB[C] of the first contact hole and a central region HD[C] of the second contact hole may be exposed, and the insulating layer 157 may be exposed through each of the central region HB[C] of the first contact hole and the central region HD[C] of the second contact hole.

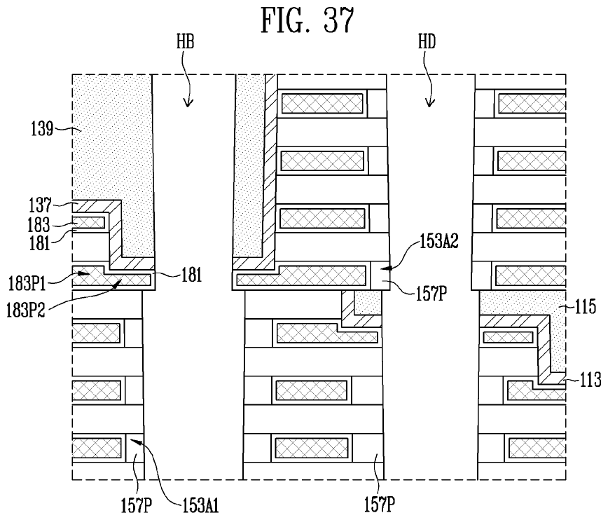

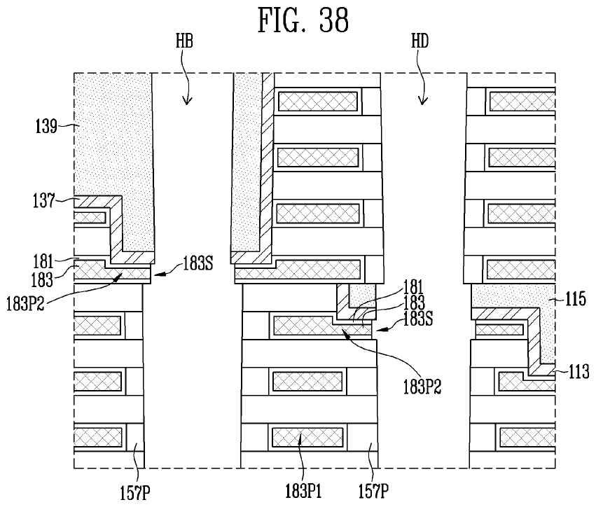

FIGS. 37 and 38 are sectional views illustrating a process of exposing the second part of the conductor. FIGS. 37 and 38 are enlarged sectional views of a boxed region BOX shown in FIG. 36B.

Referring to FIG. 37, a portion of the insulating layer 157 shown in FIGS. 36A to 36E may be removed through the central region HB[C] of the first contact hole and the central region HD[C] of the second contact hole, which are shown in FIGS. 36A to 36E. Accordingly, the first contact hole HB and the second contact hole HD may be opened. A portion of the second blocking insulating layer 181 extending along the second part 183P2 of the conductor 183 may be exposed through the first contact hole HB and the second contact hole HD. The insulating layer 157 shown in FIGS. 36A to 36E may be isolated into a plurality of contact insulating patterns 157P. The plurality of contact insulating patterns 157P may remain in the first recess region 153A1 and the third recess region 153A2.

Referring to FIG. 38, a portion of the second blocking insulating layer 181 shown in FIG. 37 may be removed through the first contact hole HB and the second contact hole HD. Accordingly, the second part 183P2 of the conductor 183 may be exposed. In an embodiment, a sidewall 183S of the second part 183P2, which faces a contact hole corresponding thereto among the first and second contact holes HB and HD, may be exposed. Subsequently, the first conductive gate contact 191A and the second conductive gate contact 191B, which are shown in FIGS. 6A to 6E, may be respectively formed inside the first contact hole HB and the second contact hole DH. In a process of forming the first conductive gate contact 191A and the second conductive gate contact 191B, a portion of the preliminary vertical stack structure 189P shown in FIGS. 36A to 36E and the fourth mask pattern 178′ may be removed.

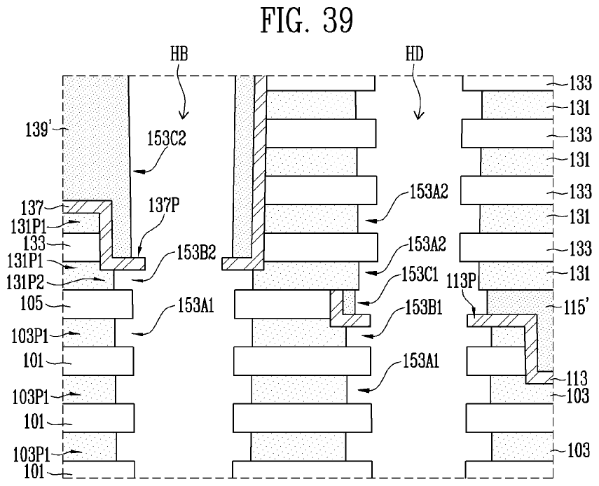

FIGS. 39, 40, 41, and 42 are sectional views illustrating a manufacturing method of a semiconductor memory device in accordance with an embodiment of the present disclosure. FIGS. 39, 40, 41, and 42 are sectional views illustrating a process continued after the process described with reference to FIGS. 22A to 22E, and are enlarged sectional views of the boxed region BOX shown in FIG. 22B. However, a first filling insulating layer 115′ and a second filling insulating layer 139, which are shown in FIGS. 39, 40, 41, and 42, may be formed of a property a high similarity with respect to the plurality of upper second material layers 131 and the plurality of lower second material layers 103, as compared with the first filling insulating layer 115 and the second filling insulating layer 139, which are shown in FIGS. 22A to 22E.

Referring to FIG. 39, a portion of each of the plurality of upper second material layers 131 and the plurality of lower second material layers 103 may be removed through the first contact hole HB, the second contact hole HD, and the dummy hole HC shown in FIG. 22C. Accordingly, as described with reference to FIG. 24, the first to fourth recess regions 153A1, 153B1, 153A2, and 153B2 may be defined between the plurality of first interlayer insulating layers 101, the first interposition insulating layer 105, and the plurality of second interlayer insulating layers 133.

During an etching process for forming the first to fourth recess regions 153A1, 153B1, 153A2, and 153B2, a fifth recess region 153C1 and a sixth recess region 153C2 may be defined by etching a portion of each of the first filling insulating layer 115′ and the second filling insulating layer 139′. The fifth recess region 153C1 may be defined as a region in which a portion of the first filling insulating layer 115′ is removed, and the sixth recess region 153C2 may be defined as a region in which a portion of the second filling insulating layer 139′ is removed.

Through the above-described process, the first barrier insulating layer 113 may include a protrusion part 113P further protruding toward the second contact hole HD than the first filling insulating layer 115′ between the second recess region 153B1 and the fifth recess region 153C1. The second barrier insulating layer 137 may include a protrusion part 137P further protruding toward the first contact hole HB than the second filling insulating layer 139′ between the fourth recess region 153B2 and the sixth recess region 153C2.

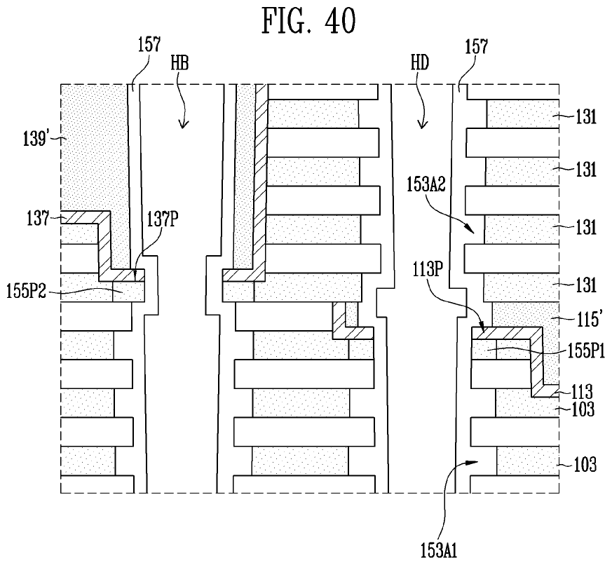

Referring to FIG. 40, as described with reference to FIGS. 24 and 25, the pad pattern 155P1 inside the second recess region 153B1 shown in FIG. 39 and the pad pattern 155P2 inside the fourth recess region 153B2 shown in FIG. 39 may be formed.

Subsequently, as described with reference to FIG. 26, the insulating layer 157 may be formed along the sidewall of each of the first contact hole HB, the second contact hole HD, and the dummy hole HC shown in FIG. 22C. The insulating layer 157 may be formed to fill the first recess region 153A1 and the third recess region 153A2. The insulating layer 157 may have an inflection point at each of the protrusion part 113P of the first barrier insulating layer 113 and the protrusion part 137P of the second barrier insulating layer 137.

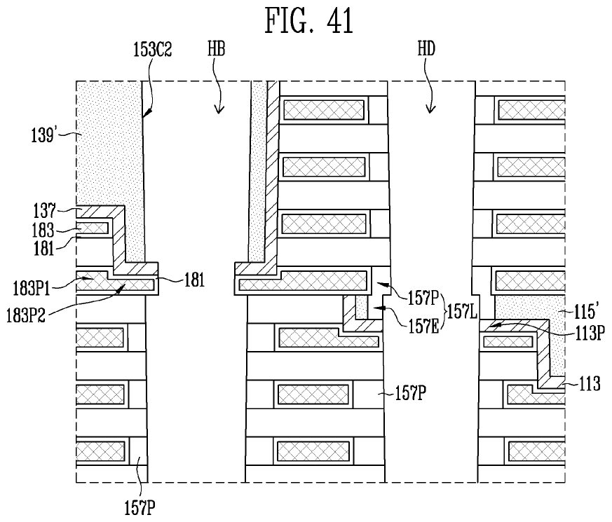

Referring to FIG. 41, the processes described above with reference to FIGS. 27A to 27E, 28A to 28E, 29A, 29B, 30A, 30B, 31A to 31E, 32, 33, 34A to 34E, 35A to 35E, and 36A to 36E may be performed. Accordingly, each of the plurality of lower second material layers 113 and the plurality of upper second material layer 131, which are shown in FIG. 40, may be replaced with the conductor 183 including the first part 183P1 and the second part 183P2 and the blocking insulating layer 181 extending along the surface of the conductor 183.

Subsequently, the insulating layer 157 shown in FIG. 40 may be etched such that a portion of the second blocking insulating layer 181 extending along the second part 183P2 of the conductor 183 is exposed through the first contact hole HB and the second contact hole HD. The sixth recess region 153C2 may be opened.

The insulating layer may remain as a plurality of contact insulating patterns 157P and an extension part 157E of the insulating pattern. The extension part 157E of the insulating pattern may be a pattern extending onto a sidewall of the first filling insulating layer 115′ from a contact insulating pattern 157P overlapping with the protrusion part 113P of the first barrier insulating layer 113 among the plurality of contact insulating patterns 157P. The contact insulating pattern 157P and the extension part 157E of the insulating pattern may be integrated to form a connection pattern 157L.

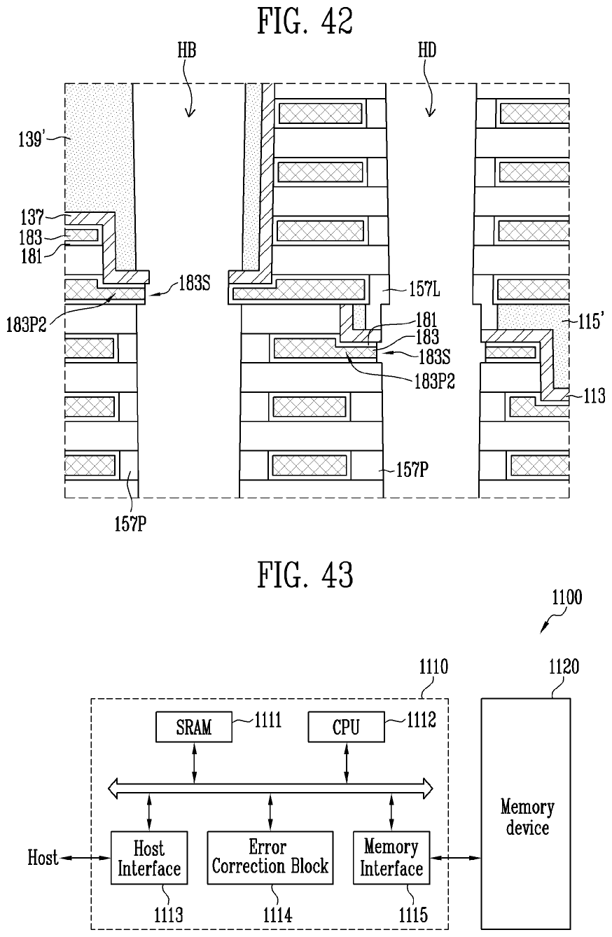

Referring to FIG. 42, a portion of the second blocking insulating layer 181 shown in FIG. 41 may be removed through the first contact hole HB and the second contact hole HD. Accordingly, the second part 183P2 of the conductor 183 may be exposed. In an embodiment, the sidewall 183S of the second part 183P2, which faces a contact hole corresponding thereto among the first and second contact holes HB and HD, may be exposed. Subsequently, the first conductive gate contact 191A′ and the second conductive gate contact 191B′, which are shown in FIG. 8, may be respectively formed inside the first contact hole HB and the second contact hole HD.

FIG. 43 is a block diagram illustrating a configuration of a memory system in accordance with an embodiment of the present disclosure.

Referring to FIG. 43, the memory system 1100 includes a memory device 1120 and a memory controller 1110.

The memory device 1120 may be a multi-chip package configured with a plurality of flash memory chips. The memory device 1120 may include a stack structure including a contact region with a stepped structure, a stepped groove having a sidewall formed of the stepped structure of the stack structure, a barrier insulating layer extending along a surface of a stepped structure, a filling insulating layer formed on the barrier insulating layer inside the stepped groove, and a conductive gate contact penetrating the stepped structure of the stack structure while penetrating the filling insulating layer and the barrier insulating layer.

The memory controller 1110 controls the memory device 1120, and may include a Static Random Access Memory (SRAM) 1111, a Central Processing Unit (CPU) 1112, a host interface 1113, an error correction block 1114, and a memory interface 1115. The SRAM 1111 is used as an operation memory of the CPU 1112, the CPU 1112 performs overall control operations for data exchange of the memory controller 1110, and the host interface 1113 includes a data exchange protocol for a host connected with the memory system 1100. The error correction block 1114 detects an error included in a data read from the memory device 1120, and corrects the detected error. The memory interface 1115 interfaces with the memory device 1120. The memory controller 1110 may further include a Read Only Memory (ROM) for storing code data for interfacing with the host, and the like.

The memory system 1100 configured as described above may be a memory card or a Solid State Disk (SSD), in which the memory device 1120 is combined with the controller 1110. For example, when the memory system 1100 is an SSD, the memory controller 1100 may communicated with the outside (e.g., the host) through one of various interface protocols, such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA (SATA) protocol, a Parallel-ATA (PATA) protocol, a Small Computer System Interface (SCSI) protocol, an Enhanced Small Disk Interface (ESDI) protocol, and an Integrated Drive Electronics (IDE) protocol.

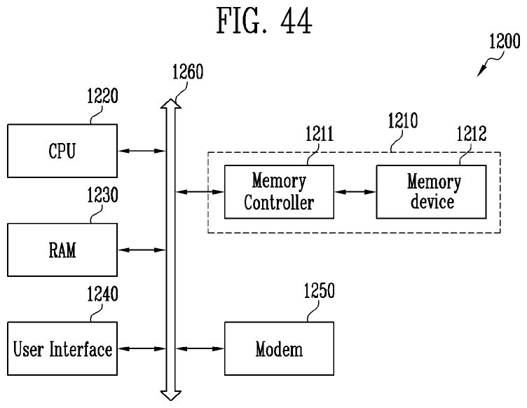

FIG. 44 is a block diagram illustrating a configuration of a computing system in accordance with an embodiment of the present disclosure.

Referring to FIG. 44, the computing system 1200 may include a CPU 1220, a random access memory (RAM) 1230, a user interface 1240, a modem 1250, and a memory system 1210, which are electrically connected to a system bus 1260. When the computing system 1200 is a mobile device, a battery for supplying an operation voltage to the computing system 1200 may be further included, and an application chip set, an image processor, a mobile DRAM, and the like may be further included.

The memory system 1210 may be configured with a memory device 1212 and a memory controller 1211.

The memory device 1212 may be configured same to the memory device 1120 described above with reference to FIG. 43.

In accordance with an embodiment, a filling insulating layer and a barrier insulating layer, which are disposed in a groove of a stack structure, may be designed by considering material layers of the stack structure. Accordingly, in an embodiment, although a contact hole penetrating the filling insulating layer and the barrier insulating layer is formed through a process of forming a channel hole penetrating the stack structure, a difference between an etching amount inside the channel hole and an etching amount inside the contact hole may be reduced, so that the stability of a manufacturing process of the semiconductor memory device may be improved.

What is claimed is:

1. A semiconductor memory device comprising:
a stack structure including a cell array region and a contact region with a stepped structure, the contact region extending from the cell array region;
a channel structure extending in the cell array region of the stack structure;
a memory layer between the channel structure and the stack structure;
a groove defined in the contact region of the stack structure, the groove including a first sidewall defined by the stepped structure of the stack structure, a second sidewall facing the first sidewall, and a third sidewall between the first sidewall and the second sidewall;
a filling insulating layer inside the groove;
a barrier insulating layer disposed between the filling insulating layer and the stack structure, the barrier insulating layer being formed of a material different from a material of the filling insulating layer, the barrier insulating layer extending along the first sidewall, the second sidewall, and the third sidewall of the groove and a bottom surface of the filling insulating layer; and
at least one conductive gate contact penetrating the filling insulating layer, the barrier insulating layer, and the stepped structure of the stack structure.

2. The semiconductor memory device of claim 1, wherein the stack structure forms a common plane with each of the first sidewall, the second sidewall, and the third sidewall of the groove.

3. The semiconductor memory device of claim 1, wherein the stack structure includes a plurality of interlayer insulating layers and a plurality of conductive patterns, which are alternately stacked in a length direction of the channel structure,
wherein each of the conductive patterns includes a first part surrounding the channel structure and a second part extending from the first part to form the stepped structure, and
wherein a thickness of the second part is different from a thickness of the first part.

4. The semiconductor memory device of claim 3, wherein the plurality of conductive patterns include a contact-conductive pattern in contact with the conductive gate contact and a separation-conductive pattern spaced apart from the conductive gate contact.

5. The semiconductor memory device of claim 4, wherein the conductive gate contact is connected to the second part of the contact-conductive pattern.

6. The semiconductor memory device of claim 4, further comprising a contact insulating pattern disposed between the separation-conductive pattern and the conductive gate contact.

7. The semiconductor memory device of claim 4, wherein the separation-conductive pattern is disposed at at least one level among levels upper and lower than the contact-conductive pattern.

8. The semiconductor memory device of claim 1, wherein the filling insulating layer is formed of a material different from a material of the stack structure.

9. The semiconductor memory device of claim 1, wherein the filling insulating layer includes a higher content of at least one of nitrogen and silicon as compared with the barrier insulating layer.

10. The semiconductor memory device of claim 9, wherein the barrier insulating layer includes a higher content of oxygen as compared with the filling insulating layer.

11. The semiconductor memory device of claim 1,
wherein the filling insulating layer is formed of a SiOₓN_{y} or a SiₓO_{y},
wherein x is equal to zero and x is less than y for the SiOₓN_{y}, and
wherein x is greater than y for the SiₓO_{y}.

12. The semiconductor memory device of claim 1, further comprising a first slit penetrating the filling insulating layer while facing the third sidewall.

13. The semiconductor memory device of claim 11, wherein the first slit includes a sidewall forming a common plane with the filling insulating layer.

14. The semiconductor memory device of claim 1, further comprising:
a dummy hole penetrating a portion of the stack structure, which extends along the third sidewall of the groove;
an insulating layer extending along a sidewall of the dummy hole; and
a dummy plug disposed inside the dummy hole.

15. The semiconductor memory device of claim 14, wherein the stack structure includes a plurality of interlayer insulating layers and a plurality of conductive patterns, which are alternately stacked in a length direction of the channel structure,
wherein the plurality of interlayer insulating layers includes an upper insulating layer and a lower insulating layer, which are adjacent to each other in the length direction of the channel structure, and
wherein the insulating layer protrudes to a space between the upper insulating layer and the lower insulating layer.

16. The semiconductor memory device of claim 1, wherein the barrier insulating layer further protrudes toward the conductive gate contact than the filling insulating layer.

17. The semiconductor memory device of claim 1, further comprising:
a peripheral circuit structure disposed under the stack structure;
a plurality of interconnections between the stack structure and the peripheral circuit structure; and
a source layer disposed between the plurality of interconnections and the stack structure, the source layer being in contact with the channel structure.

18. The semiconductor memory device of claim 1, further comprising:
a peripheral circuit structure disposed under the stack structure;
a plurality of first interconnections disposed between the stack structure and the peripheral circuit structure;
a plurality of second interconnections disposed between the plurality of first interconnections and the peripheral circuit structure; and
a first conductive bonding pad and a second conductive bonding pad disposed between the plurality of first interconnections and the plurality of second interconnections, the first conductive bonding pad and the second conductive bonding pad being bonded to each other.

19. A semiconductor memory device comprising:
a lower stack structure including a plurality of first interlayer insulating layers and a plurality of first conductive patterns, which are alternately stacked in a first direction;
a channel structure extending in the lower stack structure;
a memory layer between the channel structure and the lower stack structure;
a first stepped groove spaced apart from the channel structure, the first stepped groove penetrating the lower stack structure;
a first barrier insulating layer covering a surface of the first stepped groove;
a first filling insulating layer disposed inside the first stepped groove, the first filling insulating layer being formed on the first barrier insulating layer;
an upper stack structure including a plurality of second conductive patterns and a plurality of second interlayer insulating layers, which are alternately stacked on the lower stack structure in the first direction, wherein the channel structure and the memory extend in the upper stack structure;
a second stepped groove spaced apart from the channel structure, the second stepped groove penetrating the upper stack structure;
a second barrier insulating layer covering a surface of the second stepped groove;
a second filling insulating layer disposed inside the second stepped groove, the second filling insulating layer being formed on the second barrier insulating layer;
a first conductive gate contact penetrating the second filling insulating layer, the second barrier layer, and the lower stack structure; and
a second conductive gate contact penetrating the upper stack structure, the first filling insulating layer, and the first barrier insulating layer.

20. The semiconductor memory device of claim 19, wherein the second stepped groove and the first conductive gate contact are disposed between the channel structure and the first stepped groove.

21. The semiconductor memory device of claim 19, wherein the first stepped groove includes a first sidewall with a stepped structure, a second sidewall facing the first sidewall, and a third sidewall between the first sidewall and the second sidewall, and
wherein the first barrier insulating layer extends along the first sidewall, the second sidewall, and the third sidewall of the first stepped groove.

22. The semiconductor memory device of claim 21, wherein each of the plurality of first conductive patterns includes a first part surrounding the channel structure and a second part extending from the first part to form the stepped structure of the first stepped groove, and
wherein a thickness of the second part is different from a thickness of the first part.

23. The semiconductor memory device of claim 22, wherein the plurality of first conductive patterns include a contact-conductive pattern connected to the second conductive gate contact and a separation-conductive pattern spaced apart from the second conductive gate contact, and
wherein the second part of the contact-conductive pattern is in contact with the second conductive gate contact.

24. The semiconductor memory device of claim 23, further comprising a contact insulating pattern disposed between the separation-conductive pattern and the second conductive gate contact.

25. The semiconductor memory device of claim 19, wherein the second stepped groove includes a first sidewall with a stepped structure, a second sidewall facing the first sidewall, and a third sidewall between the first sidewall and the second sidewall, and
wherein the second barrier insulating layer extends along the first sidewall, the second sidewall, and the third sidewall of the second stepped groove.

26. The semiconductor memory device of claim 25, wherein each of the plurality of second conductive patterns includes a first part surrounding the channel structure and a second part extending from the first part to form the stepped structure of the second stepped groove, and
wherein a thickness of the second part is different from a thickness of the first part.

27. The semiconductor memory device of claim 26, wherein the plurality of second conductive patterns include a contact-conductive pattern connected to the first conductive gate contact and a separation-conductive pattern spaced apart from the first conductive gate contact, and
wherein the second part of the contact-conductive pattern is connected to the first conductive gate contact.

28. The semiconductor memory device of claim 27, further comprising a plurality of contact insulating patterns disposed between the separation-conductive pattern among the plurality of second conductive patterns and the first conductive gate contact and between the plurality of first conductive patterns and the first conductive gate contact.

29. The semiconductor memory device of claim 19, wherein each of the first filling insulating layer and the second filling insulating layer includes a higher content of at least one of nitrogen and silicon as compared with the first barrier insulating layer, the second barrier insulating layer, the plurality of first interlayer insulating layers, and the plurality of second interlayer insulating layers.

30. The semiconductor memory device of claim 19, wherein each of the first filling insulating layer and the second filling insulating layer includes a SiOₓN_{y} or a SiₓO_{y},
wherein x is equal to zero and x is less than y for the SiOₓN_{y}, and
wherein x is greater than y for the SiₓO_{y}.

31. A method of manufacturing a semiconductor memory device, the method comprising:
forming a preliminary stack structure including a plurality of first material layers and a plurality of second material layers, which are alternately stacked in a first direction, the preliminary stack structure including a cell array region and a contact region extending from the cell array region;
etching the contact region of the preliminary stack structure such that a groove is formed, wherein the groove includes a first sidewall with a stepped structure, a second sidewall facing the first sidewall, and third and fourth sidewalls which are disposed between the first sidewall and the second sidewall and face each other;
forming a barrier insulating layer continuously extending along the first sidewall, the second sidewall, the third sidewall, and the fourth sidewall of the groove;
forming a filling insulating layer inside the groove; and
forming a slit, a channel hole, and a contact hole by using an etching material for etching the plurality of first material layers and the plurality of second material layers, wherein the slit penetrates the cell array region of the preliminary stack structure and extends to the contact region of the preliminary stack structure, the channel hole penetrates the cell array region of the preliminary stack structure, and the contact hole penetrates the filling insulating layer, the barrier insulating layer, and the stepped structure of the groove.

32. The method of claim 31, wherein the barrier insulating layer includes the same element as a material forming the plurality of first material layers, and
the filling insulating layer includes the same element as a material forming the plurality of second material layers.

33. The method of claim 31, wherein the filling insulating layer and the plurality of second material layers include a higher content of at least one of nitrogen and silicon as compared with the barrier insulating layer and the plurality of first material layers.

34. The method of claim 33, wherein the barrier insulating layer and the plurality of first material layers include a higher content of oxygen as compared with the filling insulating layer and the plurality of second material layers.

35. The method of claim 31, wherein the filling insulating layer includes a SiOₓN_{y} or a SiₓO_{y},
wherein x is equal to zero and x is less than y for the SiOₓN_{y}, and
wherein x is greater than y for the SiₓO_{y}.

36. The method of claim 31, wherein the barrier insulating layer is formed of substantially the same material as the plurality of first material layers.

37. The method of claim 31, wherein the filling insulating layer is formed of substantially the same material as the plurality of second material layers.

38. The method of claim 31, wherein each of the plurality of second material layers includes a first part and a second part extending from the first part, and
wherein the second part forms the stepped structure with a thickness different from a thickness of the first part.

39. The method of claim 38, further comprising:
forming a plurality of primary sacrificial structures inside the channel hole and the contact hole;
opening the contact hole by removing a sacrificial structure inside the contact hole among the plurality of primary sacrificial structures;
replacing a portion of a second material layer of a target layer disposed at an intersection portion of the contact hole and the stepped structure among the plurality of second material layers with a pad pattern through the contact hole;
forming a recess region by etching a portion of the other second material layer except the second material layer of the target layer among the plurality of second material layers through the contact hole;
forming an insulating layer filling the recess region, the insulating layer extending along a sidewall of the contact hole; and
forming a secondary sacrificial structure in a central region of the contact hole.

40. The method of claim 39, further comprising:
opening the channel hole by removing a sacrificial structure inside the channel hole among the plurality of primary sacrificial structures; and
forming a channel structure having a sidewall surrounded by a memory layer inside the channel hole.

41. The method of claim 39, further comprising:
opening the slit by removing a sacrificial structure inside the slit among the plurality of primary sacrificial structures; and
replacing each of the plurality of second material layers and the pad patterns with a conductor through the slit,
wherein the conductor includes a first part with which each of the plurality of second material layers is replaced and a second part with which the pad pattern is replaced.

42. The method of claim 41, further comprising:
removing the secondary sacrificial structure such that the central region of the contact hole is opened;
etching the insulating layer such that the second part of the conductor is exposed and such that the insulating layer remains as a contact insulating pattern inside the recess region; and
forming a conductive gate contact inside the contact hole to be in contact with the second part of the conductor.

43. The method of claim 31, wherein, while the slit, the channel hole, and the contact hole are formed, a dummy hole is formed, which penetrates a portion of the contact region of the preliminary stack structure, which is adjacent to the groove, through the etching material.

44. The method of claim 43, further comprising:
forming a plurality of primary sacrificial structures inside each of the channel hole and the dummy hole;
opening the dummy hole by removing a sacrificial structure inside the dummy hole among the plurality of primary sacrificial structures;
forming a recess region by etching a portion of each of the plurality of second material layers through the dummy hole;
forming an insulating layer filling the recess region, the insulating layer extending along a sidewall of the dummy hole;
forming a second sacrificial structure in a central region of the dummy hole, which is exposed by the insulating layer;
opening the channel hole by removing a sacrificial structure inside the channel hole among the plurality of primary sacrificial structures;
opening the central region of the dummy hole by removing the secondary sacrificial structure; and
forming a channel structure having a sidewall surrounded by a memory layer inside each of the channel hole and the central region of the dummy hole.
